(19) United States
(12) Patent Application Publication
(10) Pub. No.: US 2025/0253272 A1
(43) Pub. Date: Aug. 7, 2025

(54) SIGNAL TRANSMISSION DEVICE

(71) Applicant: ROHM CO., LTD., Kyoto-shi (JP)

(72) Inventors: Ryohei UMENO, Kyoto-shi (JP); Taro NISHIOKA, Kyoto-shi (JP); Takahiro NEGORO, Kyoto-shi (JP)

(21) Appl. No.: 19/091,349

(22) Filed: Mar. 26, 2025

Related U.S. Application Data
(63) Continuation of application No. PCT/JP2023/034561, filed on Sep. 22, 2023.

(30) Foreign Application Priority Data
Sep. 29, 2022 (JP) 2022-156995

(51) Int. Cl. H01L 23/66; H01L 23/535; H01L 23/538; H03K 17/687; H03K 19/0185

(52) U.S. Cl. CPC H01L 23/66; H01L 23/535; H01L 23/5384; H01L 23/5386; H03K 17/687; H03K 19/018557; H01L 2223/6611; H01L 2223/6616

(57) ABSTRACT

A signal transmission device includes a first chip including a first transformer, a second chip, first terminals, second terminals, third terminals, inter-chip wires, and first terminal wires. The inter-chip wires separately connect the first chip to the second chip. The inter-chip wires separately connect the first chip to the third chip. The first terminal wires separately connect the first chip to the first terminals. The inter-chip wires are formed from a material including gold. The first terminal wires are formed from a material including copper or aluminum.

### CROSS-REFERENCE TO RELATED APPLICATIONS

This application is a continuation of, and claims the benefit of priority from International Application No. PCT/JP2023/034561, filed on Sep. 22, 2023, which claims the benefit of priority from Japanese Patent Application No. 2022-156995, filed on Sep. 29, 2022, the entire contents of each of which are incorporated herein by reference.

### BACKGROUND

### 1. Field

The present disclosure relates to a signal transmission device.

### 2. Description of Related Art

Japanese Laid-Open Patent Publication No. 2016-207714 discloses an example of a signal transmission device that includes a first die pad, a second die pad separated from the first die pad, a first chip and a transformer chip mounted on the first die pad, a second chip mounted on the second die pad, and an encapsulation resin encapsulating the die pads and the chips. In such a signal transmission device, the first chip and the transformer chip are electrically connected by some wires, and the transformer chip and the second chip are electrically connected by other wires.

### BRIEF DESCRIPTION OF THE DRAWINGS

FIG. 1 is a perspective view showing a first embodiment of a signal transmission device.

FIG. 2 is a bottom view of the signal transmission device shown in FIG. 1.

FIG. 3 is a schematic plan view showing the internal structure of the signal transmission device shown in FIG. 1.

FIG. 4 is a schematic cross-sectional view of the signal transmission device taken along line F4-F4 shown in FIG. 3.

FIG. 5 is an enlarged view of FIG. 3 including a first die pad.

FIG. 6 is a schematic cross-sectional view showing a first inner terminal portion of a first terminal.

FIG. 7 is an enlarged view of FIG. 3 including a second die pad and a third die pad.

FIG. 8 is a schematic cross-sectional view showing a second inner terminal portion of a second terminal.

FIG. 9 is a circuit diagram showing the signal transmission device of the first embodiment.

FIG. 10 is a schematic plan view showing an example of the internal structure of a first chip in the signal transmission device of the first embodiment.

FIG. 11 is an enlarged plan view of a transformer region shown in FIG. 10.

FIG. 12 is a schematic plan view showing an example of the internal structure of the first chip at a position differing from that of FIG. 10 in the thickness-wise direction of the first chip.

FIG. 13 is an enlarged plan view of the transformer region shown in FIG. 11.

FIG. 14 is a cross-sectional view showing the cross-sectional structure of the first chip taken along line F14-F14 in FIG. 10.

FIG. 15 is an enlarged view showing a portion of the first chip shown in FIG. 14.

FIG. 16 is an enlarged view of a conductive wire of a first front coil in the first chip shown in FIG. 15.

FIG. 17 is an enlarged view of a conductive wire of a first back coil in the first chip shown in FIG. 15.

FIG. 18 is a cross-sectional partial view showing a cross-sectional structure of a circuit region of the first chip.

FIG. 19 is an enlarged view of FIG. 18 including a first via.

FIG. 20 is an enlarged plan view including a first die pad in a second embodiment of a signal transmission device.

FIG. 21 is an enlarged plan view including a first die pad in a third embodiment of a signal transmission device.

FIG. 22 is an enlarged perspective view including a second bonding portion of a first terminal wire shown in FIG. 21.

FIG. 23 is a schematic plan view showing the internal structure of a fourth embodiment of a signal transmission device.

FIG. 24 is a schematic cross-sectional view showing a first chip and a first die pad in a fifth embodiment of a signal transmission device.

FIG. 25 is a schematic cross-sectional view of a first chip and a first die pad taken in a direction differing from that of FIG. 24.

FIG. 26 is a schematic cross-sectional view of a second chip and a second die pad.

FIG. 27 is a schematic cross-sectional view of the second chip and the second die pad taken in a direction differing from that shown in FIG. 26.

FIG. 28 is a schematic cross-sectional view of a third chip and a third die pad.

FIG. 29 is a schematic cross-sectional view of the third chip and the third die pad taken in a direction differing from that of FIG. 28.

FIG. 30 is a schematic cross-sectional view showing an exemplary step for manufacturing the signal transmission device of the fifth embodiment.

FIG. 31 is a schematic cross-sectional view showing an exemplary step for manufacturing the signal transmission device subsequent to FIG. 30.

FIG. 32 is a schematic cross-sectional view showing an exemplary step for manufacturing the signal transmission device subsequent to FIG. 31.

FIG. 33 is a schematic cross-sectional view showing an exemplary step for manufacturing the signal transmission device subsequent to FIG. 32.

FIG. 34 is a schematic cross-sectional view showing an example of the cross-sectional structure including a first transformer of a first chip in a sixth embodiment of a signal transmission device.

FIG. 35 is an enlarged cross-sectional view including a portion of a first transformer shown in FIG. 34.

FIG. 36 is a schematic cross-sectional view showing an exemplary step for manufacturing the signal transmission device of the sixth embodiment.

FIG. 37 is a schematic cross-sectional view showing an exemplary step for manufacturing the signal transmission device subsequent to FIG. 36.

FIG. 38 is a schematic cross-sectional view showing an exemplary step for manufacturing the signal transmission device subsequent to FIG. 37.

FIG. 39 is a cross-sectional partial view showing a cross-sectional structure including a first transformer of a first chip in a seventh embodiment of a signal transmission device.

FIG. 40 is an enlarged cross-sectional view including a portion of a first front coil in a first transformer of a first chip in an eighth embodiment of a signal transmission device.

FIG. 41 is a schematic cross-sectional view showing an exemplary step for manufacturing the signal transmission device of the eighth embodiment.

FIG. 42 is a schematic cross-sectional view showing an exemplary step for manufacturing the signal transmission device subsequent to FIG. 41.

FIG. 43 is a schematic cross-sectional view showing an exemplary step for manufacturing the signal transmission device subsequent to FIG. 42.

FIG. 44 is a schematic cross-sectional view showing an exemplary step for manufacturing the signal transmission device subsequent to FIG. 43.

FIG. 45 is a schematic cross-sectional view showing an exemplary step for manufacturing the signal transmission device subsequent to FIG. 44.

FIG. 46 is a schematic cross-sectional view showing an exemplary step for manufacturing the signal transmission device subsequent to FIG. 45.

FIG. 47 is an enlarged cross-sectional view including a portion of a first front coil in a first transformer of a first chip in a ninth embodiment of a signal transmission device.

FIG. 48 is a schematic cross-sectional view showing an exemplary step for manufacturing the signal transmission device of the ninth embodiment.

FIG. 49 is a schematic cross-sectional view showing an exemplary step for manufacturing the signal transmission device subsequent to FIG. 48.

FIG. 50 is a schematic cross-sectional view showing an exemplary step for manufacturing the signal transmission device subsequent to FIG. 49.

FIG. 51 is a schematic cross-sectional view showing an exemplary step for manufacturing the signal transmission device subsequent to FIG. 50.

FIG. 52 is a schematic cross-sectional view showing an exemplary step for manufacturing the signal transmission device subsequent to FIG. 51.

FIG. 53 is a schematic plan view showing an example of the internal structure of a first chip in a modified example of a signal transmission device.

FIG. 54 is a schematic plan view showing an example of the internal structure of the first chip at a position differing from that of FIG. 53 in the thickness-wise direction of the first chip.

FIG. 55 is an enlarged plan view including a first die pad in a modified example of a signal transmission device.

FIG. 56 is an enlarged plan view showing a second die pad, a third die pad, and their surrounding in a modified example of a signal transmission device.

### DETAILED DESCRIPTION

Embodiments of a signal transmission device according to the present disclosure will now be described with reference to the drawings. In the drawings, elements may not be drawn to scale for simplicity and clarity of illustration. To facilitate understanding, hatching lines may not be shown in the cross-sectional drawings. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

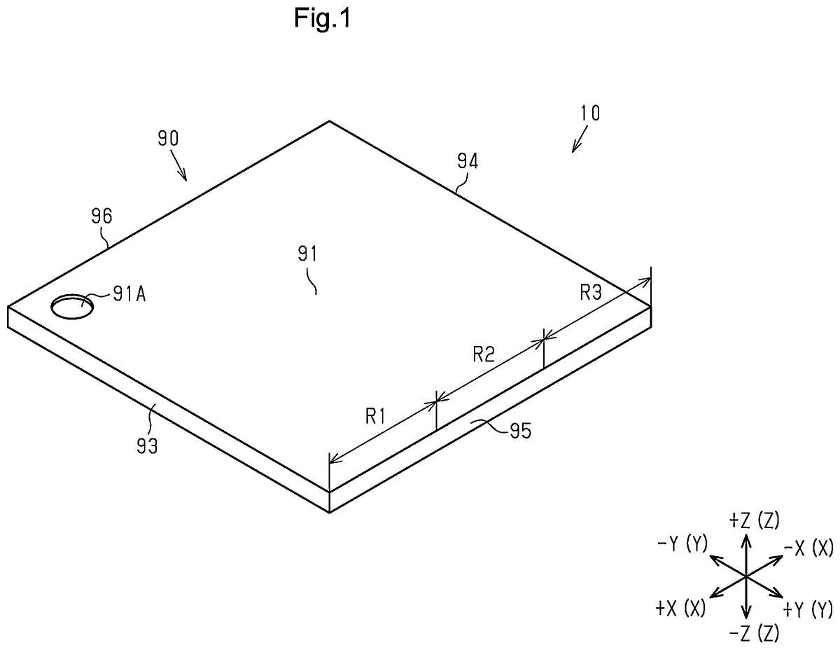

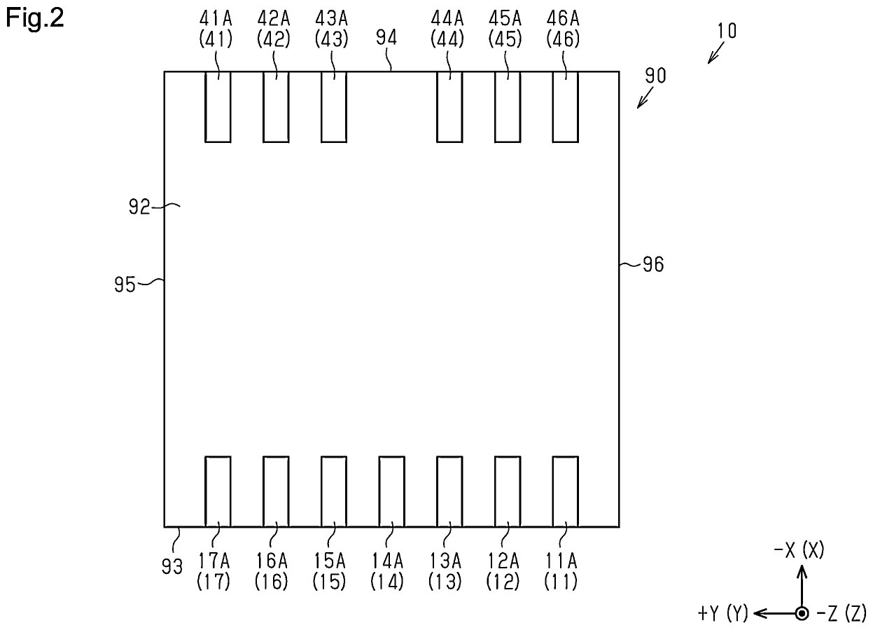

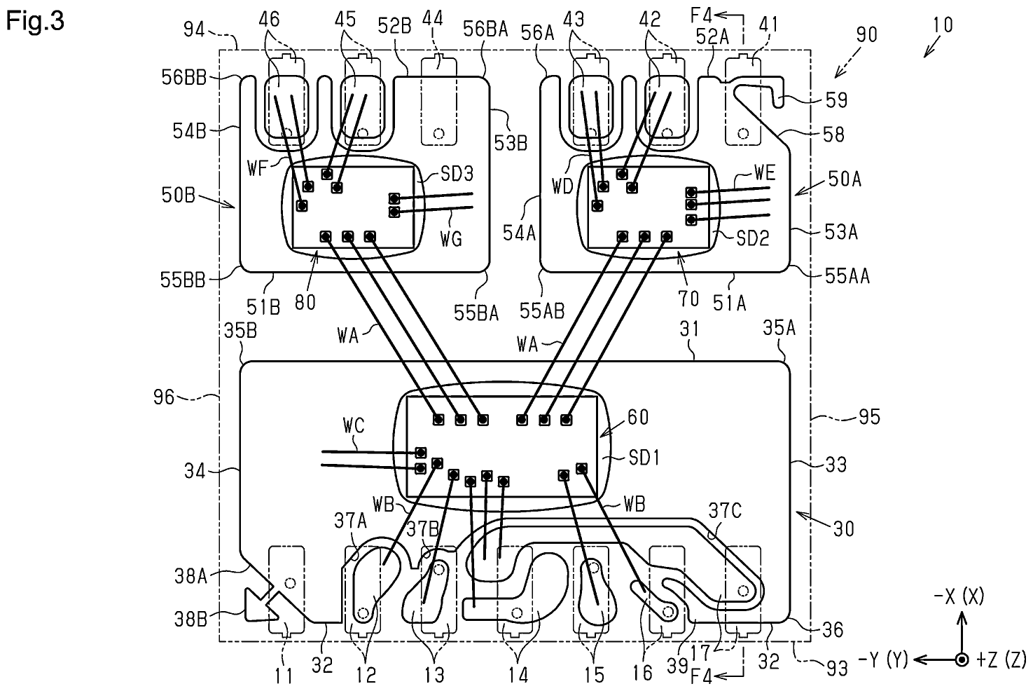

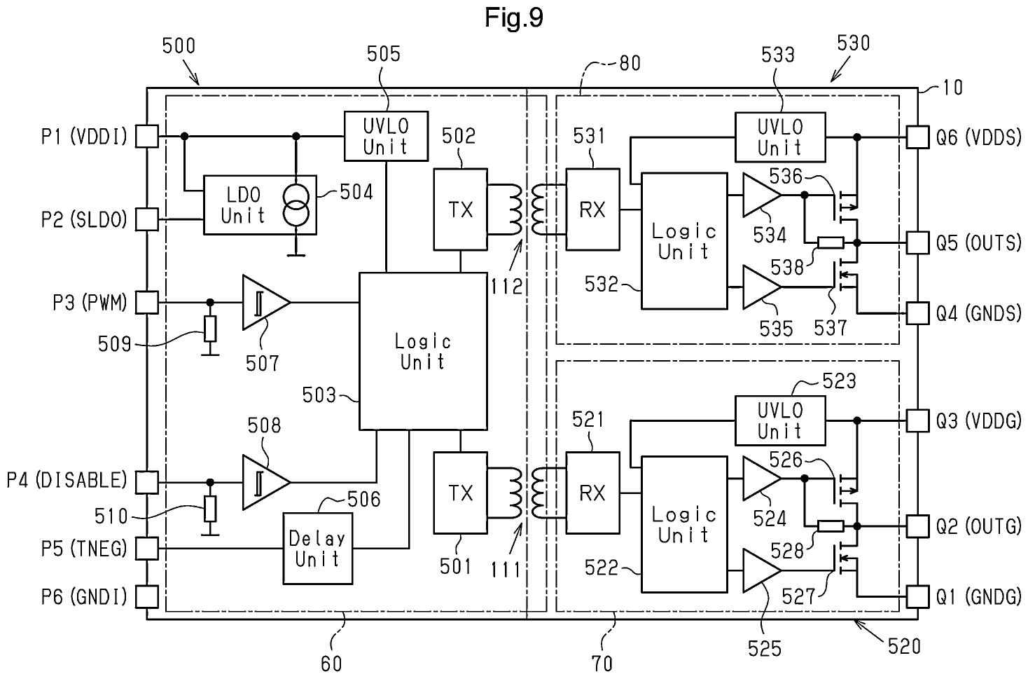

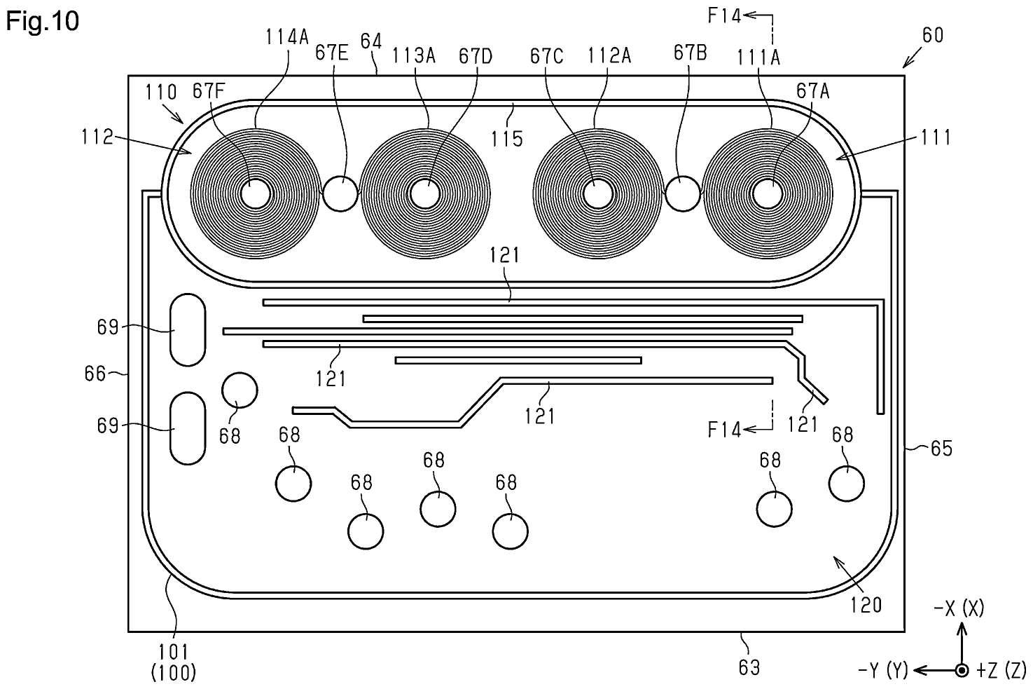

A first embodiment of a signal transmission device 10 will now be described with reference to FIGS. 1 to 19. FIGS. 1 and 2 show external structures of the signal transmission device 10. FIGS. 3 to 8 show internal structures of the signal transmission device 10. FIG. 9 shows the circuit configuration of the signal transmission device 10. FIGS. 10 to 19 show internal structures of a first chip 60 of the signal transmission device 10, which will be described later.

### External Structure of Signal Transmission Device

FIG. 1 is a perspective view showing the structure of the signal transmission device 10 at the front side. FIG. 2 is a plan view showing the structure of the signal transmission device 10 at the back side.

As shown in FIGS. 1 and 2, the signal transmission device 10 has the structure of a small outline non-lead package (SON). The package structure of the signal transmission device 10 may be changed in any manner and may be, for example, quad flat non-lead package (QFN).

The signal transmission device 10 includes multiple (seven in the first embodiment) first terminals 11 to 17, multiple (three in the first embodiment) second terminals 41 to 43, multiple (three in the first embodiment) third terminals 44 to 46, and an encapsulation resin 90 encapsulating the first to third terminals. As shown in FIG. 2, the first terminals 11 to 17, the second terminals 41 to 43, and the third terminals 44 to 46 are exposed from an encapsulation back surface 92 of the encapsulation resin 90, which will be described later.

As shown in FIG. 1, the encapsulation resin 90 has the form of a rectangular plate. In the present specification, the thickness-wise direction of the encapsulation resin 90 is referred to as “Z-direction”. Two directions that are orthogonal to each other and to the Z-direction are referred to as “X-direction” and “Y-direction.” The Z-direction includes “+Z-direction” defining the upward direction and “−Z-direction” defining the downward direction. As shown in FIG. 1, the X-direction includes “+X-direction” defining the frontward direction and “−X-direction” defining the backward direction. As shown in FIG. 1, the Y-direction includes “+Y-direction” defining the rightward direction and “−Y-direction” defining the leftward direction. In the present specification, “plan view” refers to a view of the signal transmission device 10 taken in the thickness-wise direction of the encapsulation resin 90. Unless otherwise specified, the plan view refers to a view of the signal transmission device 10 taken from the +Z-direction.

In plan view, the encapsulation resin 90 is, for example, substantially square. In an example, the dimension (thickness) of the encapsulation resin 90 in the Z-direction is less than or equal to one-third of the dimension of the encapsulation resin 90 in each of the X-direction and the Y-direction. In an example, the dimension (thickness) of the encapsulation resin 90 in the Z-direction is less than or equal to one-fourth of the dimension of the encapsulation resin 90 in each of the X-direction and the Y-direction. In an example, the dimension (thickness) of the encapsulation resin 90 in the Z-direction is greater than or equal to one-fifth of the dimension of the encapsulation resin 90 in each of the X-direction and the Y-direction. In an example, in plan view, the dimension of the encapsulation resin 90 in the X-direction is approximately 5 mm. The dimension of the encapsulation resin 90 in the Y-direction is approximately 5 mm. The dimension (thickness) of the encapsulation resin 90 in the Z-direction is 1.06 mm at the maximum.

As shown in FIGS. 1 and 2, the encapsulation resin 90 includes an encapsulation front surface 91 and an encapsulation back surface 92 facing opposite directions in the Z-direction. The encapsulation front surface 91 faces in the +Z-direction. The encapsulation back surface 92 faces in the −Z-direction. The Z-direction corresponds to a “third direction that is orthogonal to the first direction and the second direction.”

The encapsulation resin 90 includes first to fourth encapsulation side surfaces 93 to 96 joining the encapsulation front surface 91 and the encapsulation back surface 92. The first encapsulation side surface 93 and the second encapsulation side surface 94 define two end surfaces of the encapsulation resin 90 in the X-direction. The third encapsulation side surface 95 and the fourth encapsulation side surface 96 define two end surfaces of the encapsulation resin 90 in the Y-direction. The first encapsulation side surface 93 faces in the +X-direction. The second encapsulation side surface 94 faces in the −X-direction. The third encapsulation side surface 95 faces in the +Y-direction. The fourth encapsulation side surface 96 faces in the −Y-direction.

As shown in FIG. 1, the encapsulation front surface 91 includes a recess 91A. The recess 91A is circular in plan view. The recess 91A is recessed from the encapsulation front surface 91 in a curved manner. The recess 91A is formed in the encapsulation front surface 91 in the vicinity of the first encapsulation side surface 93 and the fourth encapsulation side surface 96. The recess 91A is used to distinguish the first terminals 11 to 17 from the second terminals 41 to 43 and the third terminals 44 to 46.

The encapsulation resin 90 is formed by, for example, transfer molding. In an example, the third encapsulation side surface 95 includes a mark (not shown) formed by the gate of molds. The mark is formed when a resin portion located at the gate of the molds is cut apart from the encapsulation resin 90. The mark is formed in, for example, the center of the third encapsulation side surface 95 in the Z-direction. In an example, as shown in FIG. 1, the third encapsulation side surface 95 is divided into three regions R1 to R3 in the X-direction. The regions R1 to R3 have the same size. The region R1 is a region of the third encapsulation side surface 95 in the vicinity of the first encapsulation side surface 93. The region R3 is a region of the third encapsulation side surface 95 in the vicinity of the second encapsulation side surface 94. The region R2 is located between the region R1 and the region R3 in the X-direction. The mark may be located in the region R1. The mark may be located in the region R2. The mark may be located in the region R3.

Each of the encapsulation front surface 91, the encapsulation back surface 92, and the first to fourth encapsulation side surfaces 93 to 96 of the encapsulation resin 90 has a surface roughness Rz of, for example, 5 μm or greater and 20 μm or less. In the first embodiment, the surface roughness Rz over the entirety of the encapsulation front surface 91 and the encapsulation back surface 92 is, for example, 5 μm or greater and 20 μm or less. Also, the surface roughness Rz of the first to fourth encapsulation side surfaces 93 to 96 is, for example, entirely 5 μm or greater and 20 μm or less. The surface roughness Rz may be expressed as the sum of the height of the maximum peak and the depth of the maximum valley in a contour curve having a reference length. In an example, surface roughening is performed on the encapsulation front surface 91, the encapsulation back surface 92, and the first to fourth encapsulation side surfaces 93 to 96 to obtain the surface roughness Rz of 5 μm or greater and 20 μm or less. An example of the surface roughening is shot blasting.

In an example, the surface roughness Rz of each of the encapsulation front surface 91, the encapsulation back surface 92, and the first to fourth encapsulation side surfaces 93 to 96 is greater than or equal to 8 μm. In an example, the surface roughness Rz of each of the encapsulation front surface 91, the encapsulation back surface 92, and the first to fourth encapsulation side surfaces 93 to 96 is 8 μm or greater and 20 μm or less. In an example, the surface roughness Rz of the encapsulation front surface 91, the encapsulation back surface 92, and the first to fourth encapsulation side surfaces 93 to 96 may be greater than the surface roughness Rz of the surface defining the recess 91A.

In the first embodiment, the surface roughness Rz of each of the encapsulation front surface 91, the encapsulation back surface 92, and the first to fourth encapsulation side surfaces 93 to 96 is 5 μm or greater and 20 μm or less. However, there is no limit to such a configuration. In an example, the surface roughness Rz of each of the third encapsulation side surface 95 and the fourth encapsulation side surface 96 may be less than 5 μm or greater than 20 μm. In an example, the surface roughness Rz of each of the first encapsulation side surface 93 and the second encapsulation side surface 94 may be less than 5 μm or greater than 20 μm. In an example, the surface roughness Rz of each of the first to fourth encapsulation side surfaces 93 to 96 may be less than 5 μm or greater than 20 μm. In an example, the surface roughness Rz of the encapsulation front surface 91 may be less than 5 μm or greater than 20 μm. That is, the surface roughness Rz of at least the encapsulation back surface 92 may be 5 μm or greater and 20 μm or less.

The encapsulation resin 90 is formed from an insulating material. An example of the insulating material is a black epoxy resin. The encapsulation resin 90 includes sulfur (S) as an additive. The encapsulation resin 90 including sulfur increases the adhesion force to a first die pad 30, a second die pad 50A, and a third die pad 50B, which will be described later. However, when the encapsulation resin 90 includes sulfur and the signal transmission device 10 includes a copper-based component, the copper-based component may corrode due to sulfidation. Thus, the concentration of sulfur added to the encapsulation resin 90 is set taking into consideration the balance between limitation of the sulfidation corrosion and increase in the adhesion force of the encapsulation resin 90 with the first die pad 30, the second die pad 50A, and the third die pad 50B. In an example, the concentration of sulfur added to the encapsulation resin 90 is set to 300 μg/g or less.

As shown in FIG. 2, the first terminals 11 to 17, the second terminals 41 to 43, and the third terminals 44 to 46 respectively include first external electrodes 11A to 17A, second external electrodes 41A to 43A, and third external electrodes 44A to 46A exposed from the encapsulation back surface 92. The first external electrodes 11A to 17A are exposed from the encapsulation back surface 92 in the vicinity of the first encapsulation side surface 93. The second external electrodes 41A to 43A and the third external electrodes 44A to 46A are exposed from the encapsulation back surface 92 in the vicinity of the second encapsulation side surface 94.

The first external electrodes 11A to 17A are located at the same position in the X-direction and spaced apart from each other in the Y-direction. The first external electrodes 11A to 17A are arranged in the order of the first external electrodes 11A, 12A, 13A, 14A, 15A, 16A, and 17A from the fourth encapsulation side surface 96 toward the third encapsulation side surface 95.

The second external electrodes 41A to 43A are located at the same position in the X-direction and spaced apart from each other in the Y-direction. The second external electrodes 41A to 43A are arranged in the order of the second external electrodes 41A, 42A, and 43A from the third encapsulation side surface 95 toward the fourth encapsulation side surface 96.

The third external electrodes 44A to 46A are arranged at the same position in the X-direction and spaced apart from each other in the Y-direction. The third external electrodes 44A to 46A are arranged in the order of the third external electrodes 44A, 45A, and 46A from the third encapsulation side surface 95 toward the fourth encapsulation side surface 96.

In plan view, the first external electrodes 11A to 17A, the second external electrodes 41A to 43A, and the third external electrodes 44A to 46A are each rectangular so that the long sides extend in the X-direction and the short sides extend in the Y-direction. In an example, the first external electrodes 11A to 17A, the second external electrodes 41A to 43A, and the third external electrodes 44A to 46A are equal in size. The first external electrodes 11A to 17A, the second external electrodes 41A to 43A, and the third external electrodes 44A to 46A each have a dimension in the X-direction that is, for example, approximately 0.75 mm, and a dimension in the Y-direction that is, for example, approximately 0.3 mm.

In an example, the pitch of the first external electrodes 11A to 17A is equal to the pitch of the second external electrodes 41A to 43A. The pitch of the first external electrodes 11A to 17A is equal to the pitch of the third external electrodes 44A to 46A. The pitch of the second external electrodes 41A to 43A is equal to the pitch of the third external electrodes 44A to 46A. The pitch of the first external electrodes 11A to 17A, the pitch of the second external electrodes 41A to 43A, and the pitch of the third external electrodes 44A to 46A are each, for example, approximately 0.65 mm. The pitch of the first external electrodes 11A to 17A is defined by the distance between the centers of two adjacent ones of the first external electrodes 11A to 17A. The pitch of the second external electrodes 41A to 43A is defined by the distance between the centers of two of the second external electrodes 41A to 43A located adjacent to each other in the Y-direction. The pitch of the third external electrodes 44A to 46A is defined by the distance between the centers of two of the third external electrodes 44A to 46A located adjacent to each other in the Y-direction.

The distance between the second external electrode 43A and the third external electrode 44A in the Y-direction is greater than the pitch of the first external electrodes 11A to 17A, the pitch of the second external electrodes 41A to 43A, and the pitch of the third external electrodes 44A to 46A.

### Internal Structure of Signal Transmission Device

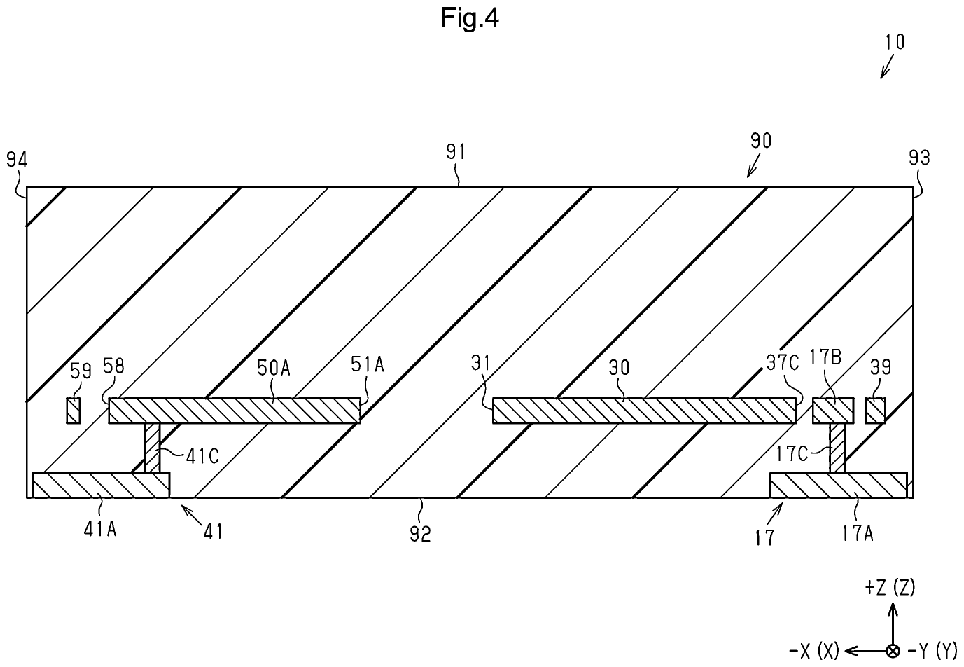

FIG. 3 shows an internal structure of the entirety of the signal transmission device 10. FIG. 4 is a schematic view showing a cross-sectional structure of the signal transmission device 10. In FIGS. 3, 5, and 7, the encapsulation resin 90 is indicated by double-dashed lines to facilitate understanding of the drawings.

As shown in FIG. 3, the signal transmission device 10 includes the first die pad 30, the second die pad 50A, the third die pad 50B, the first chip 60 mounted on the first die pad 30, a second chip 70 mounted on the second die pad 50A, and a third chip 80 mounted on the third die pad 50B. The encapsulation resin 90 encapsulates the first die pad 30, the second die pad 50A, the third die pad 50B, the first chip 60, the second chip 70, and the third chip 80.

The first die pad 30 is located closer to the first encapsulation side surface 93 than the center, in the X-direction, of the encapsulation resin 90 is. The first chip 60 mounted on the first die pad 30 is flat and has a thickness-wise direction conforming to the Z-direction. In plan view, the first chip 60 is rectangular such that the short sides extend in the X-direction and the long sides extend in the Y-direction. The first chip 60 is mounted on the first die pad 30 by a first conductive bonding material SD1. More specifically, the first chip 60 is die-bonded onto the first die pad 30.

The second die pad 50A and the third die pad 50B are spaced apart from the first die pad 30 and located closer in the X-direction to the second encapsulation side surface 94 than the first die pad 30 is. That is, the X-direction refers to the direction in which the first die pad 30, the second die pad 50A, and the third die pad 50B are arranged. The second die pad 50A and the third die pad 50B are located closer to the second encapsulation side surface 94 than the center, in the X-direction, of the encapsulation resin 90 is. The second die pad 50A and the third die pad 50B are opposed to the first die pad 30 in the X-direction. In other words, the first die pad 30 is sized so as to be opposed to the second die pad 50A and the third die pad 50B in the Y-direction. The X-direction corresponds to a “first direction.”

The second die pad 50A and the third die pad 50B are spaced apart from each other in the Y-direction. That is, in the first embodiment, the Y-direction refers to the direction in which the second die pad 50A and the third die pad 50B are arranged. The second die pad 50A is located closer to the third encapsulation side surface 95 than the third die pad 50B is. The second die pad 50A is located closer to the third encapsulation side surface 95 than the center, in the Y-direction, of the encapsulation resin 90 is. The third die pad 50B is located closer to the fourth encapsulation side surface 96 than the center, in the Y-direction, of the encapsulation resin 90 is. The Y-direction corresponds to a “second direction.”

The second chip 70 mounted on the second die pad 50A is flat. In plan view, the second chip 70 is rectangular such that the short sides extend in the X-direction and the long sides extend in the Y-direction. The second chip 70 is smaller than the first chip 60 in the X-direction. The second chip 70 is smaller than the first chip 60 in the Y-direction. The second chip 70 is mounted on the second die pad 50A by a second conductive bonding material SD2. More specifically, the second chip 70 is die-bonded onto the second die pad 50A.

The second chip 70 is arranged on the second die pad 50A in the vicinity of the third die pad 50B. As viewed in the X-direction, the second chip 70 is located closer to the third encapsulation side surface 95 than the first chip 60 is. In the example shown in FIG. 3, as viewed in the X-direction, the second chip 70 partially overlaps the first chip 60.

The third chip 80 mounted on the third die pad 50B is flat. In plan view, the third chip 80 is rectangular such that the short sides extend in the X-direction and the long sides extend in the Y-direction. The third chip 80 is smaller than the first chip 60 in the X-direction. The third chip 80 is smaller than the first chip 60 in the Y-direction. In an example, the third chip 80 and the second chip 70 have the same size in the X-direction and the Y-direction. The third chip 80 is mounted on the third die pad 50B by a third conductive bonding material SD3. More specifically, the third chip 80 is die-bonded onto the third die pad 50B. The first to third conductive bonding materials SD1 to SD3 each include, for example, a solder paste or a silver paste.

The third chip 80 is arranged on the third die pad 50B in the vicinity of the fourth encapsulation side surface 96. As viewed in the X-direction, the third chip 80 is located closer to the fourth encapsulation side surface 96 than the first chip 60 is. In the example shown in FIG. 3, as viewed in the X-direction, the third chip 80 partially overlaps the first chip 60.

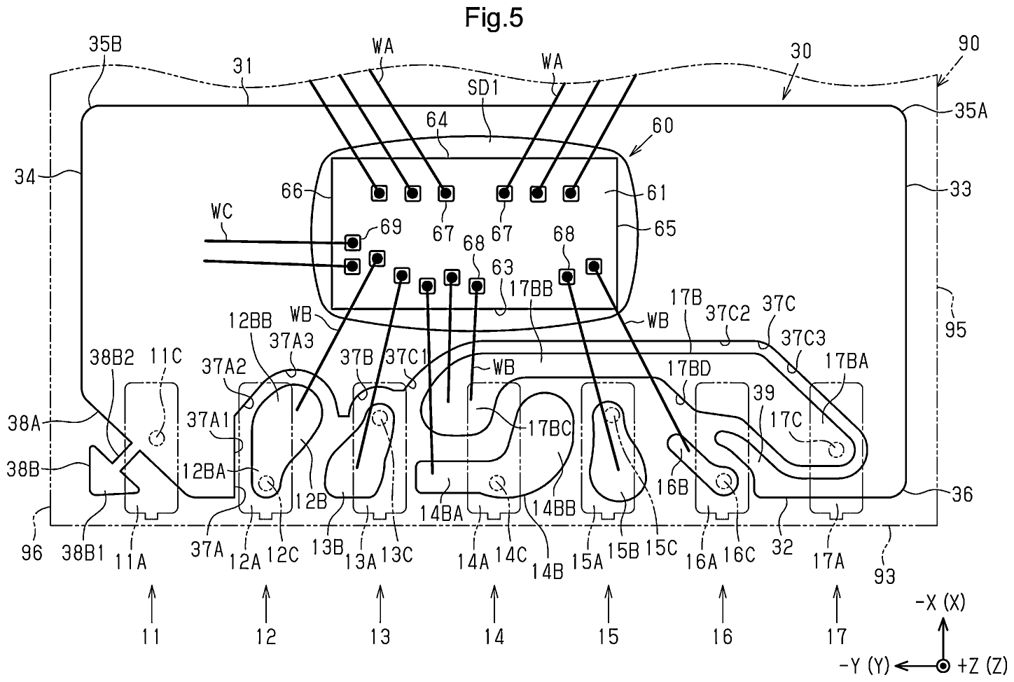

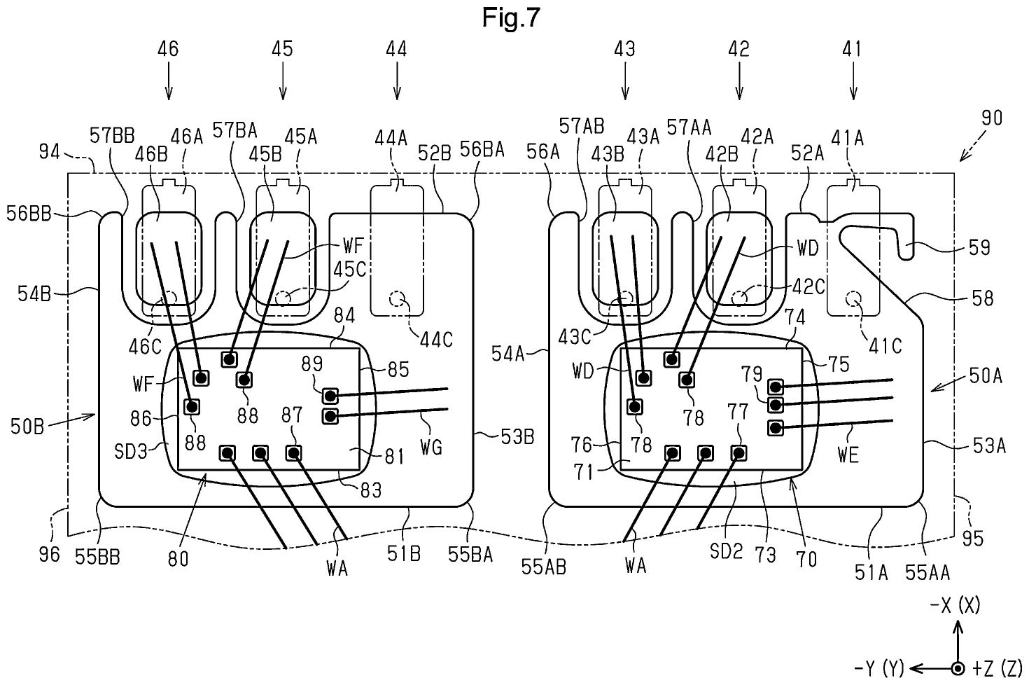

As shown in FIGS. 5 and 7, the signal transmission device 10 includes first inner terminal portions 12B to 17B, second inner terminal portions 42B and 43B, and third inner terminal portions 45B and 46B. The encapsulation resin 90 encapsulates the first inner terminal portions 12B to 17B, the second inner terminal portions 42B and 43B, and the third inner terminal portions 45B and 46B. The first inner terminal portions 12B to 17B form portions of the first terminals 12 to 17. That is, the first terminals 12 to 17 include the first inner terminal portions 12B to 17B. The second inner terminal portions 42B and 43B form portions of the second terminals 42 and 43. That is, the second terminals 42 and 43 include the second inner terminal portions 42B and 43B. The third inner terminal portions 45B and 46B form portions of the third terminals 45 and 46. That is, the third terminals 45 and 46 include the third inner terminal portions 45B and 46B.

As shown in FIG. 3, in plan view, the first terminals 11 to 17 are arranged at a side of the first chip 60 opposite from the second chip 70 and the third chip 80 in the X-direction. In the first embodiment, in plan view, the first terminals 11 to 17 are located closer, in the X-direction, to the first encapsulation side surface 93 than the first chip 60 is.

In plan view, the second terminals 41 to 43 are arranged at a side of the second chip 70 opposite from the first chip 60 in the X-direction. In other words, in plan view, the second terminals 41 to 43 and the first die pad 30 are arranged at opposite sides of the second chip 70 in the X-direction. In the first embodiment, in plan view, the second terminals 41 to 43 are located closer to the second encapsulation side surface 94 than the second chip 70 is.

In plan view, the third terminals 44 to 46 are arranged at a side of the third chip 80 opposite from the first chip 60 in the X-direction. In other words, in plan view, the third terminals 44 to 46 and the first die pad 30 are arranged at opposite sides of the third chip 80 in the X-direction. In the first embodiment, in plan view, the third terminals 44 to 46 are located closer to the second encapsulation side surface 94 than the third chip 80 is.

As shown in FIG. 4, the first terminal 17 has a structure in which the first external electrode 17A is connected to the first inner terminal portion 17B by a first via 17C. The first inner terminal portion 17B is spaced apart from the first external electrode 17A toward the encapsulation front surface 91. The first inner terminal portion 17B and the first die pad 30 are located at the same position in the Z-direction. The first via 17C is arranged between the first external electrode 17A and the first inner terminal portion 17B in the Z-direction. As shown in FIG. 5, the first terminals 12 to 16 have the same structure as the first terminal 17. More specifically, the first terminals 12 to 16 have a structure in which the first external electrodes 12A to 16A are connected to the first inner terminal portions 12B to 16B by first vias 12C to 16C, respectively.

The first terminal 11 includes a first via 11C connecting the first external electrode 11A and the first die pad 30. That is, the first terminal 11 includes the first external electrode 11A and the first via 11C. Thus, the first terminal 11 is electrically connected to the first die pad 30.

As viewed in the X-direction, the first external electrodes 11A and 12A are located closer to the fourth encapsulation side surface 96 than the first chip 60 is. In other words, as viewed in the X-direction, the first external electrodes 11A and 12A are located between the first chip 60 and the fourth encapsulation side surface 96. As viewed in the X-direction, the first external electrodes 13A to 15A overlap the first chip 60. As viewed in the X-direction, the first external electrodes 16A and 17A are located closer to the third encapsulation side surface 95 than the first chip 60 is. In other words, as viewed in the X-direction, the first external electrodes 16A and 17A are located between the first chip 60 and the third encapsulation side surface 95.

As shown in FIG. 4, the second terminal 41 includes a second via 41C connecting the second external electrode 41A and the second die pad 50A. That is, the second terminal 41 includes the second external electrode 41A and the second via 41C. Thus, the second terminal 41 is electrically connected to the second die pad 50A.

As shown in FIG. 7, the second terminals 42 and 43 have a structure in which the second external electrodes 42A and 43A are connected to the second inner terminal portions 42B and 43B by second vias 42C and 43C, respectively. The second inner terminal portions 42B and 43B are spaced apart from the second external electrodes 42A and 43A toward the encapsulation front surface 91 (refer to FIG. 4). In an example, the second inner terminal portions 42B and 43B and the second die pad 50A are located at the same position in the Z-direction. In an example, the second inner terminal portions 42B and 43B and the first inner terminal portions 12B to 17B are located at the same position in the Z-direction.

As viewed in the X-direction, the second external electrode 41A is located closer to the third encapsulation side surface 95 than the second chip 70 is. In other words, as viewed in the X-direction, the second external electrode 41A is located between the second chip 70 and the third encapsulation side surface 95 in the Y-direction. As viewed in the X-direction, the second external electrodes 42A and 43A overlap the second chip 70.

The third terminal 44 includes a third via 44C connecting the third external electrode 44A and the third die pad 50B. That is, the third terminal 44 includes the third external electrode 44A and the third via 44C. Thus, the third terminal 44 is electrically connected to the third die pad 50B.

The third terminals 45 and 46 have a structure in which the third external electrodes 45A and 46A are connected to the third inner terminal portions 45B and 46B by third vias 45C and 46C, respectively. The third inner terminal portions 45B and 46B are spaced apart from the third external electrodes 45A and 46A toward the encapsulation front surface 91. In an example, the third inner terminal portions 45B and 46B and the third die pad 50B are located at the same position in the Z-direction. In an example, the third inner terminal portions 45B and 46B are located at the same position as the first inner terminal portions 12B to 17B in the Z-direction.

As viewed in the X-direction, the third external electrode 44A is located closer to the third encapsulation side surface 95 than the third chip 80 is. As viewed in the X-direction, the third external electrodes 45A and 46A overlap the third chip 80.

The planar structure of the first die pad 30 and the first terminals 11 to 17 will now be described in detail.

As shown in FIG. 5, the first die pad 30 is formed on most of the region between the third encapsulation side surface 95 and the fourth encapsulation side surface 96 in the Y-direction. The first die pad 30 includes a first distal surface 31, a first basal surface 32, a first side surface 33, and a second side surface 34. The first distal surface 31 is one of the opposite surfaces of the first die pad 30 in the X-direction located closest to the second encapsulation side surface 94 (refer to FIG. 3). The first basal surface 32 is one of the opposite surfaces of the first die pad 30 in the X-direction located closest to the first encapsulation side surface 93. The first side surface 33 is one of the opposite surfaces of the first die pad 30 in the Y-direction located closest to the third encapsulation side surface 95 (refer to FIG. 3). The second side surface 34 is one of the opposite surfaces of the first die pad 30 in the Y-direction located closest to the fourth encapsulation side surface 96 (refer to FIG. 3). The first distal surface 31 is opposed to the second die pad 50A and the third die pad 50B (refer to FIG. 3) in the X-direction and extends in the Y-direction in plan view. The length of the first distal surface 31 in the Y-direction is greater than the length of the first basal surface 32 in the Y-direction. The first side surface 33 and the second side surface 34 extend in the X-direction in plan view.

The first die pad 30 further includes a first distal curved surface 35A, a second distal curved surface 35B, and a basal curved surface 36.

The first distal curved surface 35A is formed between the first distal surface 31 and the first side surface 33. The first distal curved surface 35A includes a portion rounded between the first distal surface 31 and the first side surface 33. The second distal curved surface 35B is formed between the first distal surface 31 and the second side surface 34. The second distal curved surface 35B includes a portion rounded between the first distal surface 31 and the second side surface 34. In an example, in plan view, the first distal curved surface 35A is equal in arc length to the second distal curved surface 35B. In other words, in an example, in plan view, the first distal curved surface 35A is equal in radius of curvature to the second distal curved surface 35B.

The basal curved surface 36 is formed between the first basal surface 32 and the first side surface 33. The basal curved surface 36 includes a portion rounded between the first basal surface 32 and the first side surface 33. In the first embodiment, in plan view, the first distal curved surface 35A and the second distal curved surface 35B are equal in arc length to the basal curved surface 36. In other words, in plan view, the first distal curved surface 35A and the second distal curved surface 35B are equal in radius of curvature to the basal curved surface 36.

The first die pad 30 further includes a first depression 37A receiving the first inner terminal portion 12B, a second depression 37B receiving the first inner terminal portion 13B, and a third depression 37C receiving the first inner terminal portions 14B to 17B. The first to third depressions 37A to 37C are open toward the first encapsulation side surface 93.

In plan view, the first depression 37A is located between the first external electrode 11A and the first external electrode 13A in the Y-direction. The first depression 37A overlaps the first external electrode 12A in plan view. The corner of the first external electrode 12A located in the vicinity of the fourth encapsulation side surface 96 and the first chip 60 overlaps the first die pad 30 in plan view.

The first depression 37A includes a first surface 37A1 extending from the first basal surface 32 in the X-direction, a second surface 37A2 being an inclined surface extending from the first surface 37A1 toward the first chip 60, and a concave surface 37A3 joined to the second surface 37A2.

In plan view, the first surface 37A1 is located closer to the first external electrode 11A than the first external electrode 12A is. In plan view, the distance between the first external electrode 12A and the first surface 37A1 in the Y-direction is less than the distance between the first external electrode 11A and the first surface 37A1 in the Y-direction.

In plan view, the second surface 37A2 is located closer to the first inner terminal portion 12B than the above-described corner of the first external electrode 12A is. The second surface 37A2 is inclined toward the first side surface 33 as the second surface 37A2 extends from the first basal surface 32 toward the first distal surface 31.

In plan view, the concave surface 37A3 is located closer to the first external electrode 13A than the first external electrode 12A is. The concave surface 37A3 does not overlap the first external electrode 12A in plan view.

The first inner terminal portion 12B has a shape generally conforms to the shape of the first depression 37A in plan view. The first inner terminal portion 12B includes a distal surface opposed to the concave surface 37A3. The distal surface includes a convex surface conforming to the shape of the concave surface 37A3.

In plan view, the first inner terminal portion 12B includes a via connector 12BA overlapping the first external electrode 12A and connected to the first via 11C and a wire connector 12BB extending from the via connector 12BA toward the first chip 60.

The via connector 12BA includes an end of the first inner terminal portion 12B located toward the first encapsulation side surface 93. The via connector 12BA is connected to a portion of the first external electrode 12A located closer to the first encapsulation side surface 93 than the center, in the X-direction, of the first external electrode 12A is.

The wire connector 12BB extends diagonally toward the third encapsulation side surface 95 in a direction from the first basal surface 32 toward the first distal surface 31. In other words, the wire connector 12BB extends from the via connector 12BA toward the first chip 60. In plan view, the wire connector 12BB includes an extension extending out of the first external electrode 12A toward the first external electrode 13A. In other words, the extension extends out of the first external electrode 12A toward the first chip 60 in plan view. The wire connector 12BB includes a distal surface of the first inner terminal portion 12B opposed to the concave surface 37A3.

The first via 12C connects the via connector 12BA and the first external electrode 12A. Thus, the first via 12C is connected to a portion of the first external electrode 12A located closer to the first encapsulation side surface 93 than the center, in the X-direction, of the first external electrode 12A is.

In plan view, the second depression 37B is located between the first external electrode 12A and the first external electrode 14A in the Y-direction. In plan view, the second depression 37B overlaps the first external electrode 13A. In plan view, the second depression 37B overlaps a portion of the first external electrode 13A located closer to the first chip 60 than the center, in the X-direction, of the first external electrode 13A is. The end of the first external electrode 13A located toward the first chip 60 in the X-direction overlaps the first die pad 30 in plan view. A portion of the second depression 37B located in the vicinity of the first depression 37A includes a concave surface.

The first inner terminal portion 13B includes a distal surface opposed to the second depression 37B. The distal surface includes a convex surface conforming to the shape of the concave surface of the second depression 37B.

In plan view, the first inner terminal portion 13B extends diagonally toward the third encapsulation side surface 95 in a direction from the first basal surface 32 toward the first distal surface 31. The first inner terminal portion 13B has a width that increases from an end located at the first distal surface 31 toward an end located at the first basal surface 32. The width of the first inner terminal portion 13B is defined by the dimension of the first inner terminal portion 13B in a direction orthogonal to the direction in which the first inner terminal portion 13B extends in plan view.

In plan view, the first inner terminal portion 13B includes an extension extending out of the first external electrode 13A toward the first external electrode 12A. As viewed in the X-direction, the extension extends out of the second depression 37B toward the first inner terminal portion 12B. Thus, as viewed in the X-direction, the extension of the first inner terminal portion 13B partially overlaps the first depression 37A. The extension of the first inner terminal portion 13B is located closer to the first encapsulation side surface 93 than the extension of the first inner terminal portion 12B is.

The first via 13C connects the first external electrode 13A to an end of the first inner terminal portion 13B received in the second depression 37B. The first via 13C is connected to a portion of the first external electrode 13A located closer to the first chip 60 than the center, in the X-direction, of the first external electrode 13A is.

In plan view, the third depression 37C is located closer to the third encapsulation side surface 95 than the first external electrode 13A is. The third depression 37C includes a concave surface 37C1 extending from the second depression 37B toward the first chip 60, a bottom surface 37C2 extending from the concave surface 37C1 in the Y-direction, and an inclined surface 37C3 joined to the bottom surface 37C2.

The concave surface 37C1 is joined to the second depression 37B and has a larger radius of curvature than the concave surface 37A3 of the first depression 37A. The concave surface 37C1 is curved toward the third encapsulation side surface 95 as the concave surface 37C1 extends from the second depression 37B toward the first chip 60.

The bottom surface 37C2 extends over the first external electrodes 14A to 16A in the Y-direction. In plan view, the bottom surface 37C2 is located closer to the first chip 60 than the first external electrodes 14A to 16A are.

In the Y-direction, the inclined surface 37C3 is located closer to the third encapsulation side surface 95 than the first external electrode 16A is. The inclined surface 37C3 is inclined toward the third encapsulation side surface 95 as the inclined surface 37C3 extends from the bottom surface 37C2 toward the first basal surface 32. The inclined surface 37C3 extends across the first external electrode 17A in plan view. A portion of the first external electrode 17A located in the vicinity of the first distal surface 31 and the first side surface 33 overlaps the first die pad 30 in plan view.

In plan view, the first inner terminal portion 17B is formed in substantially the entire third depression 37C in the Y-direction. In plan view, the first inner terminal portion 17B includes a side surface conforming to the shape of the third depression 37C. More specifically, the first inner terminal portion 17B includes a first side surface including a convex surface extending along the concave surface 37C1, a second side surface extending along the bottom surface 37C2 in the Y-direction, and a third side surface extending along the inclined surface 37C3. In plan view, the first inner terminal portion 17B extends from the first external electrode 17A to a position closer to the first external electrode 13A than the first external electrode 14A is. In plan view, the first inner terminal portion 17B is located closer to the third encapsulation side surface 95 than the first external electrode 13A is.

The first inner terminal portion 17B includes an inclined portion 17BA, an extension 17BB, and a wire connector 17BC.

The inclined portion 17BA is formed by a portion of the first inner terminal portion 17B located closer, in the X-direction, to the third encapsulation side surface 95 than the first external electrode 16A is. The inclined portion 17BA extends diagonally toward the third encapsulation side surface 95 in a direction from the first distal surface 31 toward the first basal surface 32. The inclined portion 17BA includes an overlapping part overlapping the first external electrode 17A in plan view. The inclined portion 17BA includes the third side surface.

The extension 17BB extends from the inclined portion 17BA toward the fourth encapsulation side surface 96 in the Y-direction. In plan view, the portion of the extension 17BB located in the vicinity of the inclined portion 17BA overlaps a portion of the first external electrode 16A located closer to the first distal surface 31 than the center, in the X-direction, of the first external electrode 16A is. In plan view, the extension 17BB is located closer to the first distal surface 31 than the first external electrode 15A is. The extension 17BB includes the above-described second side surface.

A depression 17BD is arranged in a portion of the extension 17BB located in the vicinity of the first encapsulation side surface 93. The depression 17BD is located closer, in the Y-direction, to the fourth encapsulation side surface 96 than the first external electrode 16A is. The depression 17BD is recessed toward the first chip 60 from a portion of the extension 17BB located in the vicinity of the first encapsulation side surface 93.

The wire connector 17BC is formed of a portion of the first inner terminal portion 17B located closer to the fourth encapsulation side surface 96 than the depression 17BD is. In plan view, the wire connector 17BC includes a portion overlapping the first external electrode 14A. The wire connector 17BC extends from the extension 17BB toward the first encapsulation side surface 93. The wire connector 17BC extends diagonally toward the fourth encapsulation side surface 96 so that the first encapsulation side surface 93 becomes closer. In an example, the direction in which the wire connector 17BC extends and the X-direction form an acute angle of, for example, greater than 0° and less than or equal to 30°.

The first via 17C connects the overlapping part of the inclined portion 17BA to the first external electrode 17A. The first via 17C is connected to an end of the overlapping part of the inclined portion 17BA located toward the third encapsulation side surface 95. The first via 17C is connected to the center of the first external electrode 17A in the X-direction.

The first inner terminal portions 14B to 16B are spaced apart from the first inner terminal portion 17B toward the first encapsulation side surface 93.

The first inner terminal portion 14B overlaps the wire connector 17BC and the depression 17BD as viewed in the X-direction. The first inner terminal portion 14B is partially received in the depression 17BD.

In plan view, the first inner terminal portion 14B includes a first terminal portion 14BA extending in the Y-direction and a second terminal portion 14BB extending from the first terminal portion 14BA toward the first chip 60.

In plan view, the first terminal portion 14BA is located closer to the first encapsulation side surface 93 than the center, in the X-direction, of the first external electrode 14A is. In plan view, the first terminal portion 14BA includes a distal surface located closer to the first external electrode 14A than the first external electrode 13A is. The distal surface of the first terminal portion 14BA defines an end surface of the first terminal portion 14BA in the Y-direction. The first terminal portion 14BA includes an overlapping part overlapping the first external electrode 14A and an extension extending out of the first external electrode 14A toward the first external electrode 13A.

The second terminal portion 14BB extends diagonally toward the third encapsulation side surface 95 from the first basal surface 32 toward the first distal surface 31. In plan view, the second terminal portion 14BB is located closer to the first external electrode 14A than the first external electrode 15A is. The second terminal portion 14BB includes an overlapping part overlapping the first external electrode 14A and an extension extending out of the first external electrode 14A toward the first external electrode 15A. In the second terminal portion 14BB, the extension is greater in area than the overlapping part in plan view.

The first via 14C connects the first external electrode 14A to an end of the first terminal portion 14BA located toward the second terminal portion 14BB. The first via 14C is connected to a portion of the first external electrode 14A located closer to the first encapsulation side surface 93 than the center, in the X-direction, of the first external electrode 14A is.

The first inner terminal portion 15B overlaps the depression 17BD as viewed in the X-direction. The first inner terminal portion 15B is partially received in the depression 17BD. The first inner terminal portion 15B includes a distal surface opposed to the depression 17BD. The distal surface includes a convex surface projecting toward the depression 17BD. The convex surface defines a side surface opposed to the first die pad 30.

In plan view, the first inner terminal portion 15B extends diagonally toward the fourth encapsulation side surface 96 in a direction from the first basal surface 32 toward the first distal surface 31. The first inner terminal portion 15B has a width that increases from an end located at the first distal surface 31 toward an end located at the first basal surface 32. The width of the first inner terminal portion 15B is defined by the dimension of the first inner terminal portion 15B in a direction orthogonal to the direction in which the first inner terminal portion 15B extends in plan view. In plan view, the first inner terminal portion 15B includes an extension extending out of the first external electrode 15A toward the first external electrode 16A.

The first via 15C connects the first external electrode 15A to the end of the first inner terminal portion 15B that is received in the depression 17BD. The first via 15C is connected to a portion of the first external electrode 15A located closer to the first chip 60 than the center, in the X-direction, of the first external electrode 15A is.

In plan view, the first inner terminal portion 16B is located closer to the first encapsulation side surface 93 than the center, in the X-direction, of the first external electrode 16A is. The first inner terminal portion 16B is located closer to the first encapsulation side surface 93 than the depression 17BD is. As viewed in the X-direction, the first inner terminal portion 16B overlaps an end of the extension 17BB located toward the inclined portion 17BA. As viewed in the X-direction, the first inner terminal portion 16B includes a distal end that overlaps the depression 17BD. The first inner terminal portion 16B includes a distal surface opposed to the first chip 60. Thus, the distal surface of the first inner terminal portion 16B defines a side surface opposed to the first die pad 30. The distal surface of the first inner terminal portion 16B includes a convex surface projecting toward the depression 17BD.

In plan view, the first inner terminal portion 16B extends diagonally toward the fourth encapsulation side surface 96 in a direction from the first basal surface 32 toward the first distal surface 31. In the first embodiment, in plan view, the acute angle formed by the X-direction and the direction in which the first inner terminal portion 16B extends is greater than the acute angle formed by the X-direction and the direction in which the first inner terminal portion 15B extends. In an example, the acute angle formed by the X-direction and the direction in which the first inner terminal portion 16B extends is 30° or greater and 50° or less. In the example shown in FIG. 5, the acute angle formed by the X-direction and the direction in which the first inner terminal portion 16B extends is 40°.

In plan view, the first inner terminal portion 16B includes an overlapping part overlapping the first external electrode 16A and an extension extending out of the first external electrode 16A toward the first external electrode 15A. The extension includes the distal surface of the first inner terminal portion 16B.

The first via 16C connects the first external electrode 16A to an end of the first inner terminal portion 16B located toward the first encapsulation side surface 93. The first via 16C is connected to a portion of the first external electrode 16A located closer to the first encapsulation side surface 93 than the center, in the X-direction, of the first external electrode 16A is.

The first die pad 30 further includes a cover 39 surrounding a portion of the third depression 37C located in the vicinity of the third encapsulation side surface 95 from the first encapsulation side surface 93.

The cover 39 extends toward the fourth encapsulation side surface 96 from a corner of the first die pad 30 located in the vicinity of the first encapsulation side surface 93 and the third encapsulation side surface 95. In plan view, the cover 39 and the inclined surface 37C3 of the third depression 37C surround the inclined portion 17BA of the first inner terminal portion 17B. Thus, the cover 39 is partially located between the inclined portion 17BA and the first inner terminal portion 16B.

The first die pad 30 further includes an inclined surface 38A formed between the first basal surface 32 and the second side surface 34 and a projection 38B projecting from the inclined surface 38A in plan view.

The inclined surface 38A is inclined toward the second side surface 34 as the inclined surface 38A extends from the first basal surface 32 toward the first distal surface 31. The inclined surface 38A extends across the first external electrode 11A in plan view. Thus, the first external electrode 11A includes a portion overlapping the first die pad 30 in plan view.

The first via 11C connects the first external electrode 11A to a portion of the first die pad 30 overlapping the first external electrode 11A. The first via 11C is connected to a portion of the first external electrode 11A located closer to the first distal surface 31 than the center, in the X-direction, of the first external electrode 11A is.

The projection 38B extends in a direction orthogonal to the inclined surface 38A in plan view. The projection 38B is triangular in plan view and includes a separation portion 38B1 separated from the inclined surface 38A and a connector 38B2 connecting the separation portion 38B1 and the inclined surface 38A. In plan view, the separation portion 38B1 includes an extension extending out of the first external electrode 11A toward the fourth encapsulation side surface 96.

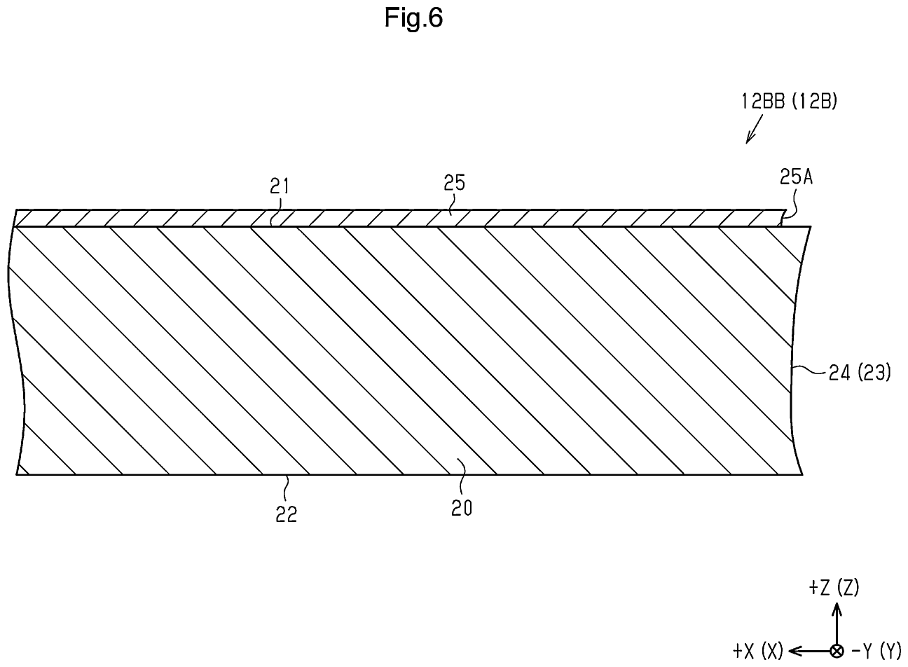

The cross-sectional structure of the first inner terminal portions 12B to 17B will now be described in detail. FIG. 6 shows a cross-sectional structure of the wire connector 12BB of the first inner terminal portion 12B. The cross-sectional structure of the first inner terminal portions 13B to 17B is the same as the cross-sectional structure of the wire connector 12BB and thus will not be shown and described in detail.

As shown in FIG. 6, the wire connector 12BB includes an inner terminal body 20. The inner terminal body 20 includes an inner terminal front surface 21, an inner terminal back surface 22 opposite to the inner terminal front surface 21, and an inner terminal side surface 23 joining the inner terminal front surface 21 and the inner terminal back surface 22. The inner terminal side surface 23 includes a distal surface 24 facing the first depression 37A of the first die pad 30 (refer to FIG. 5). The inner terminal front surface 21, which is located at a side where a first terminal wire WB (described later) is bonded, faces the same direction as the encapsulation front surface 91 (refer to FIG. 4).

In the cross-sectional view of FIG. 6, the distal surface 24 is recessed away from the first die pad 30. The distal surface 24 is recessed toward the center, in the Z-direction, of the distal surface 24 from both of the ends located at the inner terminal front surface 21 and at the inner terminal back surface 22. In an example, the deepest position of the distal surface 24 is approximately one-third of the thickness of the wire connector 12BB from the inner terminal back surface 22. The shape of the distal surface 24 in the cross-sectional view of FIG. 6 may be changed in any manner.

A plating layer 25 is formed the inner terminal front surface 21. The plating layer 25 is formed from a material including, for example, silver. The plating layer 25 is formed on substantially the entirety of the inner terminal front surface 21 of the wire connector 12BB. The thickness of the 25 is less than the thickness of the inner terminal body 20 of the wire connector 12BB.

The plating layer 25 includes an end surface 25A located toward the distal surface 24. The end surface 25A is located closer to the via connector 12BA (refer to FIG. 5) than an edge of the inner terminal front surface 21 located toward the distal surface 24 is. That is, the plating layer 25 does not cover the end surface of the inner terminal front surface 21 located toward the distal surface 24. Thus, the end of the inner terminal front surface 21 including the edge located toward the distal surface 24 is in contact with the encapsulation resin 90 (refer to FIG. 1).

The end surface 25A of the plating layer 25 is inclined so as to be located farther from the edge of the inner terminal front surface 21 located toward the distal surface 24 as the end surface 25A extends from the front surface toward the back surface of the plating layer 25. In an example, the distance in the X-direction between the back surface of the plating layer 25 and the edge of the inner terminal front surface 21 located toward the distal surface 24 is, for example, greater than or equal to the thickness of the plating layer 25. The distance in the X-direction between the back surface of the plating layer 25 and the edge of the inner terminal front surface 21 located toward the distal surface 24 may be changed in any manner.

The plating layer 25 does not cover the distal surface 24 of the wire connector 12BB. Thus, the distal surface 24 is in contact with the encapsulation resin 90 (refer to FIG. 4). Although not shown, the plating layer 25 does not cover the inner terminal side surface 23 other than the distal surface 24. Thus, the inner terminal side surface 23 is in contact with the encapsulation resin 90.

The planar structure of the second die pad 50A and the second terminals 41 to 43 will now be described in detail.

As shown in FIG. 7, the second die pad 50A includes a second distal surface 51A, a second basal surface 52A, a third side surface 53A, and a fourth side surface 54A. The second distal surface 51A is one of the opposite surfaces of the second die pad 50A in the X-direction located closest to the first encapsulation side surface 93 (refer to FIG. 3). The second basal surface 52A is one of the opposite surfaces of the second die pad 50A in the X-direction located closest to the second encapsulation side surface 94. The third side surface 53A is one of the opposite surfaces of the second die pad 50A in the Y-direction located closest to the third encapsulation side surface 95. The fourth side surface 54A is one of the opposite surfaces of the second die pad 50A in the Y-direction located closest to the fourth encapsulation side surface 96. The second distal surface 51A is opposed to the first die pad 30 (refer to FIG. 3) in the X-direction and extends in the Y-direction in plan view. The third side surface 53A and the fourth side surface 54A extend in the X-direction in plan view.

The second die pad 50A further includes a third distal curved surface 55AA, a fourth distal curved surface 55AB, and a basal curved surface 56A.

The third distal curved surface 55AA is formed between the second distal surface 51A and the third side surface 53A. The third distal curved surface 55AA includes a portion rounded between the second distal surface 51A and the third side surface 53A. The fourth distal curved surface 55AB is formed between the second distal surface 51A and the fourth side surface 54A. The fourth distal curved surface 55AB includes a portion rounded between the second distal surface 51A and the fourth side surface 54A. In an example, in plan view, the third distal curved surface 55AA is equal in arc length to the fourth distal curved surface 55AB. In other words, in an example, in plan view, the third distal curved surface 55AA is equal in radius of curvature to the fourth distal curved surface 55AB.

In an example, in plan view, the third distal curved surface 55AA and the fourth distal curved surface 55AB are equal in arc length to the first distal curved surface 35A and the second distal curved surface 35B. In plan view, the third distal curved surface 55AA and the fourth distal curved surface 55AB are equal in radius of curvature to the first distal curved surface 35A and the second distal curved surface 35B.

The basal curved surface 56A is formed between the second basal surface 52A and the fourth side surface 54A. The basal curved surface 56A includes a portion rounded between the second basal surface 52A and the fourth side surface 54A. In the first embodiment, in plan view, the third distal curved surface 55AA and the sixth distal curved surface 55BB are equal in arc length to the basal curved surface 56A. In other words, in plan view, the third distal curved surface 55AA and the fourth distal curved surface 55AB are equal in radius of curvature to the basal curved surface 56A.

The second die pad 50A further includes a first depression 57AA and a second depression 57AB. The first depression 57AA and the second depression 57AB are located at the same position in the X-direction and separated from each other in the Y-direction. As viewed in the X-direction, the first depression 57AA and the second depression 57AB overlap the second chip 70. In plan view, the first depression 57AA and the second depression 57AB are located closer to the fourth side surface 54A than the second external electrode 41A is. The second depression 57AB is located closer to the fourth side surface 54A than the first depression 57AA is. In plan view, the first depression 57AA and the second depression 57AB are located closer to the second encapsulation side surface 94 than the second chip 70 is.

The first depression 57AA and the second depression 57AB are open toward the second encapsulation side surface 94. The first depression 57AA and the second depression 57AB each include two side surfaces extending from the second basal surface 52A toward the second distal surface 51A in the X-direction and a concave surface arranged between the side surfaces and recessed toward the second distal surface 51A.

In plan view, the second terminal 42 is received in the first depression 57AA.

In plan view, the second external electrode 42A of the second terminal 42 includes a projection projecting from the first depression 57AA toward the second encapsulation side surface 94.

In plan view, the second inner terminal portion 42B of the second terminal 42 is accommodated in the first depression 57AA. Thus, in plan view, the second inner terminal portion 42B overlaps the second external electrode 42A. The second inner terminal portion 42B is rectangular in plan view so that the long sides extend in the X-direction and the short sides extend in the Y-direction. The four corners of the second inner terminal portion 42B each include a curved surface.

The second via 42C connects the second external electrode 42A to an end of the second inner terminal portion 42B located toward the second chip 70 in the X-direction. The second via 42C is connected to an end of the second external electrode 42A located toward the second chip 70.

In plan view, the second terminal 43 is received in the second depression 57AB.

In plan view, the second external electrode 43A of the second terminal 43 includes a projection projecting from the second depression 57AB toward the second encapsulation side surface 94.

In plan view, the second inner terminal portion 43B of the second terminal 43 is accommodated in the second depression 57AB. Thus, in plan view, the second inner terminal portion 43B overlaps the second external electrode 43A. The second inner terminal portion 43B is rectangular in plan view so that the long sides extend in the X-direction and the short sides extend in the Y-direction. The four corners of the second inner terminal portion 43B each include a curved surface. In the example shown in FIG. 7, in plan view, the second inner terminal portion 43B is identical in shape to the second inner terminal portion 42B.

The second via 43C connects the second external electrode 43A to an end of the second inner terminal portion 43B located toward the second chip 70 in the X-direction. The second via 43C is connected to an end of the second external electrode 43A located toward the second chip 70.

The second die pad 50A further includes an inclined surface 58 and a projection 59.

The inclined surface 58 and the projection 59 are located closer to the third side surface 53A than the first depression 57AA is. The inclined surface 58 is obtained by cutting away the corner of the second die pad 50A located in the vicinity of the second encapsulation side surface 94 and the third encapsulation side surface 95. The inclined surface 58 is located between the second basal surface 52A and the third side surface 53A. The inclined surface 58 is inclined toward the third encapsulation side surface 95 as the inclined surface 58 extends from the second basal surface 52A toward the second distal surface 51A.

The inclined surface 58 includes a portion overlapping the second external electrode 41A in plan view. Thus, in plan view, the second external electrode 41A includes a portion overlapping the second die pad 50A.

In plan view, the second via 41C is located closer to the second distal surface 51A than the inclined surface 58 is. The second via 41C connects the second external electrode 41A to a portion of the second die pad 50A overlapping the second external electrode 41A. The second via 41C is connected to an end of the second external electrode 41A located toward the second distal surface 51A.

In plan view, the projection 59 extends from the inclined surface 58 toward the third encapsulation side surface 95. The projection 59 is L-shaped in plan view. The end of the projection 59 located in the vicinity of the third encapsulation side surface 95 extends in the X-direction toward the second distal surface 51A. In plan view, the projection 59 includes an overlapping portion overlapping the second external electrode 41A and an extension extending out of the second external electrode 41A toward the third encapsulation side surface 95.

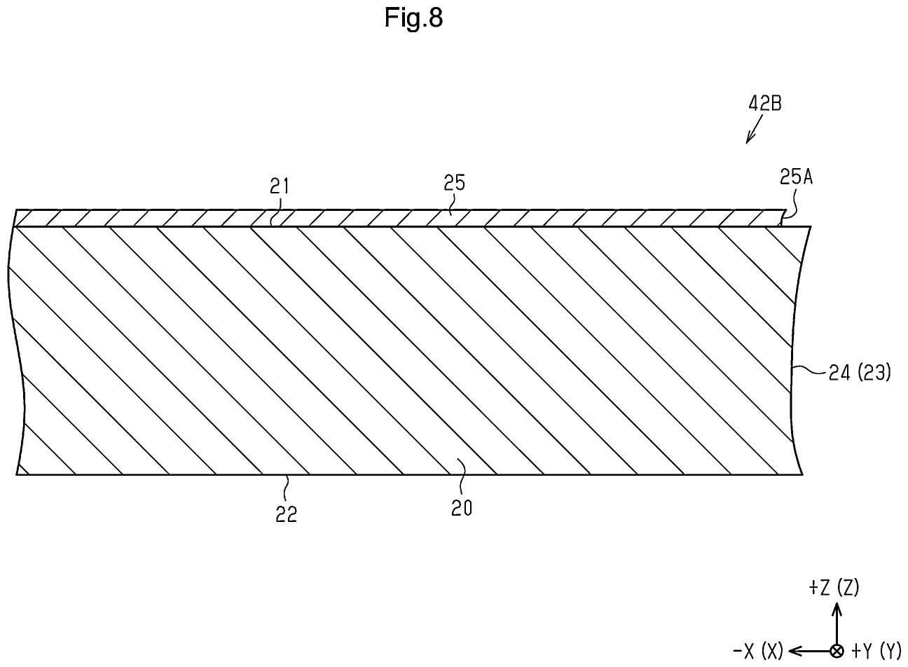

The cross-sectional structure of the second inner terminal portions 42B and 43B will now be described in detail. FIG. 8 shows a cross-sectional structure of the second inner terminal portion 42B. The cross-sectional structure of the second inner terminal portion 43B is the same as the cross-sectional structure of the second inner terminal portion 42B and thus will not be described in detail. For the sake of convenience, the same reference characters are given to those elements of the second inner terminal portion 42B that are the same as the corresponding elements of the wire connector 12BB of the first inner terminal portion 12B shown in FIG. 6.

As shown in FIG. 8, the inner terminal body 20 of the second inner terminal portion 42B includes an inner terminal front surface 21, an inner terminal back surface 22 opposite to the inner terminal front surface 21, and an inner terminal side surface 23 joining the inner terminal front surface 21 and the inner terminal back surface 22. The inner terminal front surface 21 of the second inner terminal portion 42B faces the same direction as the inner terminal front surface 21 of the first inner terminal portion 12B (refer to FIG. 6). The inner terminal back surface 22 of the second inner terminal portion 42B faces the same direction as the inner terminal back surface 22 of the first inner terminal portion 12B (refer to FIG. 6).

In the cross-sectional view of FIG. 8, the distal surface 24 is opposed to the bottom surface of the first depression 57AA of the second die pad 50A (refer to FIG. 7) in the X-direction. The distal surface 24 is recessed away from the bottom surface of the first depression 57AA. The distal surface 24 is recessed toward the center, in the Z-direction, of the distal surface 24 from both of the ends located at the inner terminal front surface 21 and at the inner terminal back surface 22. In an example, the deepest position of the distal surface 24 is approximately one-third of the thickness of the second inner terminal portion 42B from the inner terminal back surface 22. The shape of the distal surface 24 in the cross-sectional view of FIG. 8 may be changed in any manner.

A plating layer 25 is formed the inner terminal front surface 21. The plating layer 25 is formed from a material including, for example, silver. In an example, the plating layer 25 is formed from the same material as the plating layer 25 of the wire connector 12BB (refer to FIG. 6). The plating layer 25 is formed on substantially the entirety of the inner terminal front surface 21. The thickness of the plating layer 25 is less than the thickness of the inner terminal body 20 of the second inner terminal portion 42B. In an example, the plating layer 25 of the second inner terminal portion 42B is equal in thickness to the plating layer 25 of the wire connector 12BB. When the difference in thickness between the plating layer 25 of the second inner terminal portion 42B and the plating layer 25 of the wire connector 12BB is, for example, within 20% of the thickness of the plating layer 25 of the second inner terminal portion 42B, it is considered that the plating layer 25 of the second inner terminal portion 42B is equal in thickness to the plating layer 25 of the wire connector 12BB.

The plating layer 25 includes an end surface 25A located toward the distal surface 24 of the second inner terminal portion 42B. In plan view, the end surface 25A is located closer to the second via 42C (refer to FIG. 7) than an edge of the inner terminal front surface 21 located toward the distal surface 24 is. That is, the plating layer 25 does not cover the edge of the inner terminal front surface 21 located toward the distal surface 24. Thus, the end of the inner terminal front surface 21 including the edge located toward the distal surface 24 is in contact with the encapsulation resin 90 (refer to FIG. 1).

In the cross-sectional view of FIG. 8, the end surface 25A of the plating layer 25 is inclined so as to be located farther from the end surface of the inner terminal front surface 21 located toward the distal surface 24 as the end surface 25A extends from the front surface toward the back surface of the plating layer 25. The distance in the X-direction between the back surface of the plating layer 25 and the edge of the inner terminal front surface 21 located toward the distal surface 24 is, for example, greater than or equal to the thickness of the plating layer 25. The distance in the X-direction between the back surface of the plating layer 25 and the edge of the inner terminal front surface 21 located toward the distal surface 24 may be changed in any manner.

The plating layer 25 does not cover the distal surface 24 of the second inner terminal portion 42B. Thus, the distal surface 24 is in contact with the encapsulation resin 90. Although not shown, the plating layer 25 does not cover the inner terminal side surface 23 other than the distal surface 24. Thus, the inner terminal side surface 23 is in contact with the encapsulation resin 90.

The planar structure of the third die pad 50B and the third terminals 44 to 46 will now be described in detail.

As shown in FIG. 7, the third die pad 50B includes a third distal surface 51B, a third basal surface 52B, a fifth side surface 53B, and a sixth side surface 54B. The third distal surface 51B is one of the opposite surfaces of the third die pad 50B in the X-direction located closest to the first encapsulation side surface 93 (refer to FIG. 3). The third basal surface 52B is one of the opposite surfaces of the third die pad 50B in the X-direction that is closest to the second encapsulation side surface 94. The fifth side surface 53B is one of the opposite surfaces of the third die pad 50B in the Y-direction located closest to the third encapsulation side surface 95. The sixth side surface 54B is one of the opposite surfaces of the third die pad 50B in the Y-direction located closest to the fourth encapsulation side surface 96. The third distal surface 51B is opposed to the first die pad 30 (refer to FIG. 3) in the X-direction and extends in the Y-direction in plan view. In plan view, the fifth side surface 53B and the sixth side surface 54B extend in the X-direction.

The third die pad 50B further includes a fifth distal curved surface 55BA, a sixth distal curved surface 55BB, and basal curved surfaces 56BA and 56BB.

The fifth distal curved surface 55BA is formed between the third distal surface 51B and the fifth side surface 53B. The fifth distal curved surface 55BA includes a portion rounded between the third distal surface 51B and the fifth side surface 53B. The sixth distal curved surface 55BB is formed between the third distal surface 51B and the sixth side surface 54B. The sixth distal curved surface 55BB includes a portion rounded between the third distal surface 51B and the sixth side surface 54B. In an example, in plan view, the fifth distal curved surface 55BA is equal in arc length to the sixth distal curved surface 55BB. In an example, in plan view, the fifth distal curved surface 55BA is equal in radius of curvature to the sixth distal curved surface 55BB.

In an example, in plan view, the fifth distal curved surface 55BA and the sixth distal curved surface 55BB are equal in arc length to the first distal curved surface 35A and the second distal curved surface 35B. In plan view, the fifth distal curved surface 55BA and the sixth distal curved surface 55BB are equal in radius of curvature to the first distal curved surface 35A and the second distal curved surface 35B.

In an example, in plan view, the fifth distal curved surface 55BA and the sixth distal curved surface 55BB are equal in arc length to the third distal curved surface 55AA and the fourth distal curved surface 55AB. In plan view, the fifth distal curved surface 55BA and the sixth distal curved surface 55BB are equal in radius of curvature to the third distal curved surface 55AA and the fourth distal curved surface 55AB.

The basal curved surface 56BA is formed between the third basal surface 52B and the fifth side surface 53B. The basal curved surface 56BB is formed between the third basal surface 52B and the sixth side surface 54B. The basal curved surface 56BA includes a portion rounded between the second basal surface 52A and the fifth side surface 53B. The basal curved surface 56BB includes a portion rounded between the second basal surface 52A and the sixth side surface 54B. In the first embodiment, in plan view, the fifth distal curved surface 55BA and the sixth distal curved surface 55BB are equal in arc length to the basal curved surfaces 56BA and 56BB. In other words, in plan view, the fifth distal curved surface 55BA and the sixth distal curved surface 55BB are equal in radius of curvature to the basal curved surfaces 56BA and 56BB.

The third die pad 50B further includes a third depression 57BA and a fourth depression 57BB. The third depression 57BA and the fourth depression 57BB are located at the same position in the X-direction and separated from each other in the Y-direction. As viewed in the X-direction, the third depression 57BA and the fourth depression 57BB overlap the second chip 70. In plan view, the third depression 57BA and the fourth depression 57BB are located closer to the sixth side surface 54B than the third external electrode 44A is. The fourth depression 57BB is located closer to the sixth side surface 54B than the third depression 57BA is. In plan view, the third depression 57BA and the fourth depression 57BB are located closer to the second encapsulation side surface 94 than the third chip 80 is.

The third depression 57BA and the fourth depression 57BB are open toward the second encapsulation side surface 94. The third depression 57BA and the fourth depression 57BB each include two side surfaces extending from the third basal surface 52B toward the third distal surface 51B in the X-direction and a concave surface arranged between the two side surfaces and recessed toward the third distal surface 51B.

In plan view, the third terminal 45 is received in the third depression 57BA.

In plan view, the third external electrode 45A of the third terminal 45 includes a projection projecting from the third depression 57BA toward the second encapsulation side surface 94.

In plan view, the third inner terminal portion 45B of the third terminal 45 is accommodated in the third depression 57BA. Thus, in plan view, the third inner terminal portion 45B overlaps the third external electrode 45A. The third inner terminal portion 45B is rectangular in plan view so that the long sides extend in the X-direction and the short sides extend in the Y-direction. The four corners of the third inner terminal portion 45B each include a curved surface.

The third via 45C connects the third external electrode 45A to an end of the third inner terminal portion 45B located toward the third chip 80 in the X-direction. The third via 45C is connected to an end of the third external electrode 45A located toward the second chip 70.

In plan view, the third terminal 46 is received in the fourth depression 57BB.

In plan view, the third external electrode 46A of the third terminal 46 includes a projection projecting from the fourth depression 57BB toward the second encapsulation side surface 94.

In plan view, the third inner terminal portion 46B of the third terminal 46 is accommodated in the fourth depression 57B. Thus, in plan view, the third inner terminal portion 46B overlaps the third external electrode 46A. The third inner terminal portion 46B is rectangular in plan view so that the long sides extend in the X-direction and the short sides extend in the Y-direction. The four corners of the third inner terminal portion 46B each include a curved surface. In the example shown in FIG. 7, in plan view, the third inner terminal portion 46B is identical in shape to the third inner terminal portion 46B.

The third via 46C connects the third external electrode 46A to an end of the third inner terminal portion 46B located toward the third chip 80 in the X-direction. The third via 46C is connected to an end of the third external electrode 46A located toward the second chip 70.

In plan view, the third die pad 50B includes a portion overlapping the third external electrode 44A. In plan view, the third external electrode 44A includes a portion projecting from the third die pad 50B toward the second encapsulation side surface 94.

The third via 44C connects the third external electrode 44A to a portion of the third die pad 50B overlapping the third external electrode 44A. The third via 44C is connected to an end of the third external electrode 44A located toward the third distal surface 51B.

The cross-sectional structure of the third inner terminal portions 45B and 46B is the same as that of the second inner terminal portions 42B and 43B shown in FIG. 8. Thus, the cross-sectional structure of the third inner terminal portions 45B and 46B will not be described.

Structures of the first chip 60, the second chip 70, and the third chip 80 will now be described.

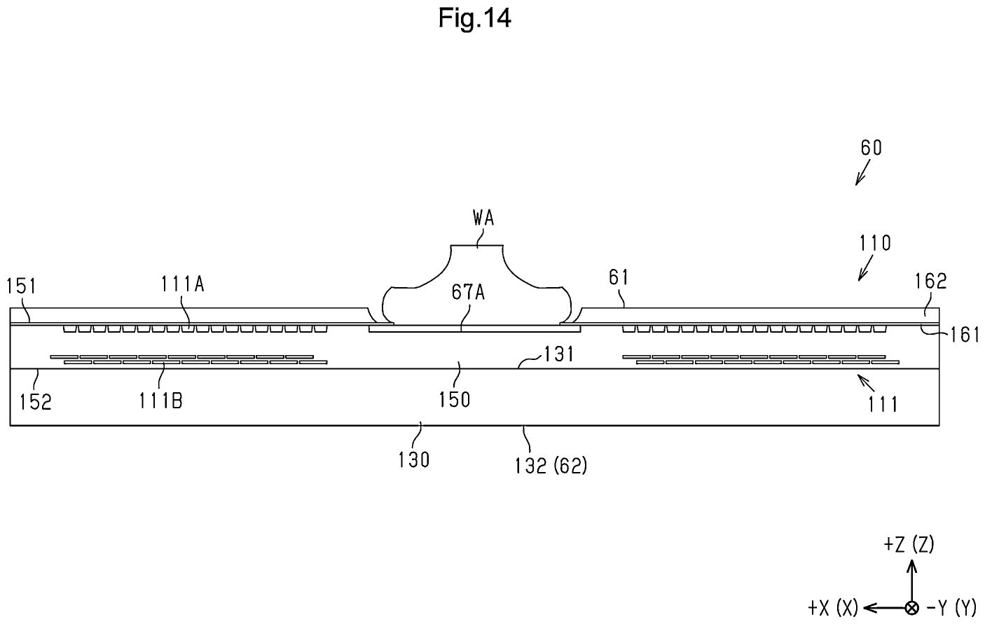

As shown in FIG. 5, the first chip 60 mounted on the first die pad 30 includes a chip front surface 61, a chip back surface 62 (refer to FIG. 14) facing an opposite direction of the chip front surface 61 in the Z-direction, and first to fourth chip side surfaces 63 to 66 joining the chip front surface 61 and the chip back surface 62.

With respect to the first chip 60, the chip front surface 61 faces away from the first die pad 30, and the chip back surface 62 faces toward the first die pad 30.

In plan view, the first chip side surface 63 and the second chip side surface 64 define two end surfaces of the first chip 60 in the X-direction. The first chip side surface 63 is a chip side surface of the first chip 60 at which the first terminals 11 to 17 are arranged. The second chip side surface 64 is a chip side surface of the first chip 60 at which the second chip 70 and the third chip 80 (refer to FIG. 7) are arranged. In plan view, the third chip side surface 65 and the fourth chip side surface 66 define two end surfaces of the first chip 60 in the Y-direction. The third chip side surface 65 is located toward the third encapsulation side surface 95 of the encapsulation resin 90. The fourth chip side surface 66 is located toward the fourth encapsulation side surface 96.

The first chip 60 includes multiple (in the first embodiment, six) first electrode pads 67, multiple (in the first embodiment, seven) second electrode pads 68, and multiple (in the first embodiment, two) third electrode pads 69. The first electrode pads 67, the second electrode pads 68, and the third electrode pads 69 are exposed from the chip front surface 61. The number of second electrode pads 68 and the number of third electrode pads 69 may be changed in any manner.

The first electrode pads 67, the second electrode pads 68, and the third electrode pads 69 may each include at least one of titanium (Ti), titanium nitride (TiN), copper (Cu), aluminum (Al), and tungsten (W). In an example, the first electrode pads 67, the second electrode pads 68, and the third electrode pads 69 each have a layered structure of titanium and copper. The material of one or two types of the first electrode pads 67, the second electrode pads 68, and the third electrode pads 69 may differ from that of the other types of the electrode pads.

In another example, the first electrode pads 67, the second electrode pads 68, and the third electrode pads 69 each include aluminum. In this case, the first electrode pads 67, the second electrode pads 68, and the third electrode pads 69 exposed from the chip front surface 61 each have a thickness of 2 μm or greater. The thickness of each of the first electrode pads 67, the second electrode pads 68, and the third electrode pads 69 may be changed in any manner.

The first electrode pads 67 are electrically connected to the second chip 70 and the third chip 80. In plan view, the first electrode pads 67 are located closer to the second chip side surface 64 than the center, in the X-direction, of the chip front surface 61 is. The first electrode pads 67 are located at the same position in the X-direction and separated from each other in the Y-direction. The first electrode pads 67 can be divided into three first electrode pads 67 electrically connected to the second chip 70 and three first electrode pads 67 electrically connected to the third chip 80. The three first electrode pads 67 electrically connected to the second chip 70 are arranged on the chip front surface 61 in the vicinity of the third chip side surface 65. The three first electrode pads 67 electrically connected to the third chip 80 are arranged on the fourth chip side surface 66 in the vicinity of the chip front surface 61.

The second electrode pads 68 are separately electrically connected to the first terminals 12 to 17. In plan view, the second electrode pads 68 are located closer to the first chip side surface 63 than the center, in the X-direction, of the chip front surface 61 is.

The third electrode pads 69 are electrically connected to the first die pad 30. Each third electrode pad 69 has the same potential, that is, a first ground potential, as the first die pad 30. In plan view, the third electrode pads 69 are arranged on an end of the chip front surface 61 located toward the fourth encapsulation side surface 96. In plan view, the third electrode pads 69 are arranged on a portion of the chip front surface 61 toward the first chip side surface 63.

As shown in FIG. 7, the second chip 70 mounted on the second die pad 50A includes a chip front surface 71, a chip back surface (not shown) facing an opposite direction of the chip front surface 71 in the Z-direction, and first to fourth chip side surfaces 73 to 76 joining the chip front surface 71 and the chip back surface.

With respect to the second chip 70, the chip front surface 71 faces away from the second die pad 50A, and the chip back surface faces toward the second die pad 50A.

In plan view, the first chip side surface 73 and the second chip side surface 74 define two end surfaces of the second chip 70 in the X-direction. The first chip side surface 73 is a chip side surface of the second chip 70 at which the first chip 60 (refer to FIG. 5) is arranged. The second chip side surface 74 is a chip side surface of the second chip 70 at which the second terminals 41 to 43 are arranged. In plan view, the third chip side surface 75 and the fourth chip side surface 76 define two end surfaces of the second chip 70 in the Y-direction. The third chip side surface 75 is located toward the third encapsulation side surface 95 of the encapsulation resin 90. The fourth chip side surface 76 is located toward the fourth encapsulation side surface 96.

The second chip 70 includes multiple (in the first embodiment, three) first electrode pads 77, multiple (in the first embodiment, four) second electrode pads 78, and multiple (in the first embodiment, three) third electrode pads 79. The first electrode pads 77, the second electrode pads 78, and the third electrode pads 79 are exposed from the chip front surface 71.

The first electrode pads 77, the second electrode pads 78, and the third electrode pads 79 may each include at least one of titanium, titanium nitride, copper, aluminum, and tungsten. In an example, the first electrode pads 77, the second electrode pads 78, and the third electrode pads 79 each have a layered structure of titanium and copper. The material of one or two types of the first electrode pads 77, the second electrode pads 78, and the third electrode pads 79 may differ from that of the other types of the electrode pads.

In another example, the first electrode pads 77, the second electrode pads 78, and the third electrode pads 79 each include aluminum. In this case, the first electrode pads 77, the second electrode pads 78, and the third electrode pads 79 exposed from the chip front surface 71 each have a thickness of 2 μm or greater. The thickness of each of the first electrode pads 77, the second electrode pads 78, and the third electrode pads 79 may be changed in any manner.

The first electrode pads 77 are separately electrically connected to the three first electrode pads 67 of the first chip 60 that are located in the vicinity of the third chip side surface 65 (refer to FIG. 5). In plan view, the first electrode pads 77 are located closer to the first chip side surface 73 than the center, in the X-direction, of the chip front surface 71 is. The first electrode pads 77 are located at the same position in the X-direction and separated from each other in the Y-direction.

The second electrode pads 78 are separately electrically connected to the second terminals 42 and 43. In plan view, the second electrode pads 78 are located closer to the fourth chip side surface 76 than the center, in the Y-direction, of the chip front surface 71 is.

The third electrode pads 79 are electrically connected to the second die pad 50A. Each third electrode pad 79 has the same potential, that is, the second ground potential, as the second die pad 50A. In plan view, the third electrode pads 79 are arranged on one of the opposite ends of the chip front surface 71 in the Y-direction located closer to the third encapsulation side surface 95. The third electrode pads 79 are located at the same position in the Y-direction and separated from each other in the X-direction.

As shown in FIG. 7, the third chip 80 mounted on the third die pad 50B includes a chip front surface 81, a chip back surface (not shown) facing an opposite direction of the chip front surface 81 in the Z-direction, and first to fourth chip side surfaces 83 to 86 joining the chip front surface 81 and the chip back surface.

With respect to the third chip 80, the chip front surface 81 faces away from the third die pad 50B, and the chip back surface faces toward the third die pad 50B.

In plan view, the first chip side surface 83 and the second chip side surface 84 define two end surfaces of the third chip 80 in the X-direction. The first chip side surface 83 is a chip side surface of the third chip 80 at which the first chip 60 (refer to FIG. 5) is arranged. The second chip side surface 84 is a chip side surface of the third chip 80 at which the third terminals 44 to 46 are arranged. In plan view, the third chip side surface 85 and the fourth chip side surface 86 define two end surfaces of the third chip 80 in the Y-direction. The third chip side surface 85 is located toward the third encapsulation side surface 95 of the encapsulation resin 90. The fourth chip side surface 86 is located toward the fourth encapsulation side surface 96.

The third chip 80 includes multiple (in the first embodiment, three) first electrode pads 87, multiple (in the first embodiment, four) second electrode pads 88, and multiple (in the first embodiment, two) third electrode pads 89. The first electrode pads 87, the second electrode pads 88, and the third electrode pads 89 are exposed from the chip front surface 81.

The first electrode pads 87, the second electrode pads 88, and the third electrode pads 89 may each include at least one of titanium, titanium nitride, copper, aluminum, and tungsten.

In an example, the first electrode pads 87, the second electrode pads 88, and the third electrode pads 89 each have a layered structure of titanium and copper. The material of one or two types of the first electrode pads 87, the second electrode pads 88, and the third electrode pads 89 may differ from that of the other types of the electrode pads.

In another example, the first electrode pads 87, the second electrode pads 88, and the third electrode pads 89 each include aluminum. In this case, the first electrode pads 87, the second electrode pads 88, and the third electrode pads 89 exposed from the chip front surface 81 each have a thickness of 2 μm or greater. The thickness of each of the first electrode pads 87, the second electrode pads 88, and the third electrode pads 89 may be changed in any manner.

The first electrode pads 87 are separately electrically connected to the three first electrode pads 67 of the first chip 60 that are located in the vicinity of the fourth chip side surface 66. In plan view, the first electrode pads 87 are located closer to the first chip side surface 83 than the center, in the X-direction, of the chip front surface 81 is. The first electrode pads 87 are located at the same position in the X-direction and separated from each other in the Y-direction.

The second electrode pads 88 are separately electrically connected to the third terminals 45 and 46. In plan view, the second electrode pads 88 are located closer to the fourth chip side surface 86 than the center, in the Y-direction, of the chip front surface 81 is.

The third electrode pads 89 are electrically connected to the third die pad 50B. Each third electrode pad 89 has the same potential, that is, a third ground potential, as the third die pad 50B. In plan view, the third electrode pads 89 are arranged on one of the opposite ends of the chip front surface 81 in the Y-direction located closer to the third encapsulation side surface 95. The third electrode pads 89 are located at the same position in the Y-direction and separated from each other in the X-direction.

The electrical connection configuration of the first chip 60, the second chip 70, and the third chip 80 will now be described.

As shown in FIG. 3, the signal transmission device 10 includes the inter-chip wires WA separately connecting the first chip 60, the second chip 70, and the third chip 80, the first terminal wires WB separately connecting the first chip 60 to the first terminals 12 to 17, and the first die pad wires WC connecting the first chip 60 to the first die pad 30. The inter-chip wires WA, the first terminal wires WB, and the first die pad wires WC are encapsulated by the encapsulation resin 90.

As shown in FIGS. 5 and 7, the three first electrode pads 67 of the first chip 60 located toward the third chip side surface 65 are separately connected to the first electrode pads 77 of the second chip 70 by the multiple (in the first embodiment, three) inter-chip wires WA. Thus, the first electrode pads 67 are separately electrically connected to the first electrode pads 77. The first electrode pads 77 are located closer to the third encapsulation side surface 95 than the first electrode pads 67 are. Thus, in plan view, the inter-chip wires WA diagonally extend toward the third encapsulation side surface 95 in a direction from the first electrode pads 67 toward the first electrode pads 77. The three inter-chip wires WA are parallel to each other in plan view.

The three first electrode pads 67 of the first chip 60 located toward the fourth chip side surface 66 are separately connected to the first electrode pads 87 of the third chip 80 by multiple (in the first embodiment, three) inter-chip wires WA. Thus, the first electrode pads 67 are separately electrically connected to the first electrode pads 87. The first electrode pads 87 are located closer to the fourth encapsulation side surface 96 than the first electrode pads 67 are. Thus, in plan view, the inter-chip wires WA diagonally extend toward the fourth encapsulation side surface 96 in a direction from the first electrode pads 67 to the first electrode pads 87. The three inter-chip wires WA are parallel to each other in plan view.

As shown in FIG. 5, the second electrode pads 68 of the first chip 60 are separately connected to the first terminals 12 to 17 by multiple (in the first embodiment, seven) first terminal wires WB. Thus, the first chip 60 is separately electrically connected to the first terminals 12 to 17. Each of the first terminals 12 to 16 is separately connected by a single first terminal wire WB to the second electrode pads 68. The first terminal 17 is separately connected by two first terminal wires WB to the second electrode pads 68.

The first terminal wire WB is a bonding wire formed with a wire bonder. In an example, the first terminal wires WB each have a portion bonded to the second electrode pad 68, as a first bonding portion, and a portion bonded to the first terminals 12 to 17, as a second bonding portion. The first terminal wires WB are connected to the first inner terminal portions 12B to 17B of the first terminals 12 to 17.

In plan view, the wire connector 12BB of the first inner terminal portion 12B includes a side surface intersecting the first terminal wire WB that is connected to the wire connector 12BB. The side surface is opposed to the first die pad 30 in plan view. In the first embodiment, the side surface of the wire connector 12BB defines the distal surface of the wire connector 12BB and is opposed to the concave surface 37A3 of the first depression 37A of the first die pad 30 in the Y-direction. The first terminal wire WB is connected to an end of the wire connector 12BB of the first terminal 12 located toward the first chip 60. The first terminal wire WB is connected to an extension of the wire connector 12BB extending out of the first external electrode 12A in plan view. More specifically, in plan view, the first terminal wire WB is connected to a portion of the wire connector 12BB located closer to the first chip 60 than the first external electrode 12A is.

In plan view, the first inner terminal portion 13B includes a side surface intersecting the first terminal wire WB that is connected to the first inner terminal portion 13B. The side surface is opposed to the first die pad 30 in plan view. In the first embodiment, the side surface of the first inner terminal portion 13B defines a distal surface of the first inner terminal portion 13B and is opposed to the second depression 37B of the first die pad 30 in the X-direction. The first terminal wire WB is connected to a portion of the first inner terminal portion 13B of the first terminal 13 located closer to the first encapsulation side surface 93 than the first via 13C is.

In plan view, the first inner terminal portion 14B includes a side surface intersecting the first terminal wire WB that is connected to the first inner terminal portion 14B. The side surface is opposed to the first die pad 30 in plan view. In the first embodiment, the side surface of the first inner terminal portion 14B defines an opposing surface of the first terminal portion 14BA of the first inner terminal portion 14B opposed to the first die pad 30 in the X-direction. The first terminal wire WB is connected to an extension of the first terminal portion 14BA of the first inner terminal portion 14B extending out of the first external electrode 14A in plan view.

In plan view, the first inner terminal portion 15B includes a side surface intersecting the first terminal wire WB that is connected to the first inner terminal portion 15B. The side surface is opposed to the first die pad 30 in plan view. In the first embodiment, the side surface of the first inner terminal portion 15B defines a distal surface of the first inner terminal portion 15B and is opposed to the bottom surface 37C2 of the third depression 37C of the first die pad 30 in the X-direction. The first terminal wire WB is connected to a portion of the first inner terminal portion 15B of the first terminal 15 located closer to the first encapsulation side surface 93 than the first via 15C is.

The first terminal wire WB that is connected to the first inner terminal portion 16B is connected to an extension of the first inner terminal portion 16B extending out of the first external electrode 16A in plan view. In plan view, the first terminal wire WB is connected to the first inner terminal portion 16B located closer to the first chip 60 than the first external electrode 16A is in the direction in which the first terminal wire WB extends.

In plan view, the wire connector 17BC of the first inner terminal portion 17B includes a side surface intersecting the first terminal wire WB that is connected to the wire connector 17BC. The side surface is opposed to the first die pad 30 in plan view. In the first embodiment, the side surface of the wire connector 17BC is opposed to the concave surface 37C1 of the third depression 37C of the first die pad 30 in the X-direction. In plan view, the first terminal wire WB is connected to a portion of the first terminal 17 located closer to the first chip 60 than the first external electrode 17A is.

The third electrode pads 69 of the first chip 60 are separately connected to the first die pad 30 by multiple (in the first embodiment, two) first die pad wires WC. This electrically connects the first chip 60 to the first die pad 30. Thus, the third electrode pads 69 each have the first ground potential. In other words, the third electrode pads 69 are electrically connected to the first terminal 11.

The first die pad wire WC is a bonding wire formed with a wire bonder. In an example, the first die pad wire WC has a portion bonded to the third electrode pad 69, as a first bonding portion, and a portion bonded to the first die pad 30, as a second bonding portion. In the first embodiment, the second bonding portion is formed on a portion of the first die pad 30 located closer to the second side surface 34 than the first chip 60 is.

As shown in FIG. 7, the signal transmission device 10 includes second terminal wires WD separately connecting the second chip 70 to the second terminals 42 and 43 and second die pad wires WE connecting the second chip 70 to the second die pad 50A. The second terminal wires WD and the second die pad wires WE are encapsulated by the encapsulation resin 90.

As shown in FIG. 7, the second electrode pads 78 of the second chip 70 are separately connected to the second terminals 42 and 43 by multiple (in the first embodiment, four) second terminal wires WD. Thus, the second terminals 42 and 43 are separately electrically connected to the second chip 70. Each of the second terminals 42 and 43 is separately connected to the second electrode pads 78 by two second terminal wires WD.

The second terminal wire WD is a bonding wire formed with a wire bonder. In an example, the second terminal wires WD each have a portion bonded to the second electrode pad 78, as a first bonding portion, and a portion bonded to the second terminals 42 and 43, as a second bonding portion. The second terminal wires WD are connected to the second inner terminal portions 42B and 43B of the second terminals 42 and 43.

More specifically, in plan view, the second inner terminal portion 42B includes a side surface intersecting the second terminal wire WD that is connected to the second inner terminal portion 42B. The side surface is opposed to the second die pad 50A in plan view. In the first embodiment, the side surface of the second inner terminal portion 42B defines a distal surface of the second inner terminal portion 42B and is opposed to the concave surface of the first depression 57AA of the second die pad 50A in the X-direction.

The second inner terminal portion 43B includes a side surface intersecting the second terminal wire WD that is connected to the second inner terminal portion 43B. The side surface is opposed to the second die pad 50A in plan view. In the first embodiment, the side surface of the second inner terminal portion 43B defines a distal surface of the second inner terminal portion 43B and is opposed to the concave surface of the second depression 57AB of the second die pad 50A in the X-direction.

The third electrode pads 79 of the second chip 70 are separately connected to the second die pad 50A by multiple (in the first embodiment, three) second die pad wires WE. This electrically connects the second chip 70 to the second die pad 50A. Thus, the third electrode pads 79 of the second chip 70 have the second ground potential. In other words, the third electrode pads 79 are electrically connected to the second terminal 41. The second die pad wire WE is connected to a portion of the second die pad 50A located closer to the third side surface 53A than the second chip 70 is.

As shown in FIG. 7, the signal transmission device 10 includes third terminal wires WF separately connecting the third chip 80 to the third terminals 45 and 46 and third die pad wires WG connecting the third chip 80 to the third die pad 50B. The third terminal wires WF and the third die pad wires WG are encapsulated by the encapsulation resin 90.

The second electrode pads 88 of the third chip 80 and the third terminals 45 and 46 are separately connected by multiple (in the first embodiment, four) third terminal wires WF. This separately electrically connects the third chip 80 to the third terminals 45 and 46. Each of the third terminals 45 and 46 is separately connected to the second electrode pads 88 by two third terminal wires WF.

The third terminal wire WF is a bonding wire formed with a wire bonder. In an example, the third terminal wires WF each have a portion bonded to the second electrode pad 88, as a first bonding portion, and a portion bonded to the third terminals 45 and 46, as a second bonding portion. The third terminal wires WF are connected to the third inner terminal portions 45B and 46B of the third terminals 45 and 46.

More specifically, in plan view, the third inner terminal portion 45B includes a side surface intersecting the third terminal wires WF connected to the third inner terminal portion 45B. The side surface is opposed to the third die pad 50B in plan view. In the first embodiment, the side surface of the third inner terminal portion 45B defines a distal surface of the third inner terminal portion 45B and is opposed to the concave surface of the third depression 57BA of the third die pad 50B in the X-direction.

In plan view, the third inner terminal portion 46B includes a side surface intersecting the third terminal wires WF connected to the third inner terminal portion 46B. The side surface is opposed to the third die pad 50B in plan view. In the first embodiment, the side surface of the third inner terminal portion 46B includes a distal surface of the third inner terminal portion 46B and is opposed to the concave surface of the fourth depression 57BB of the third die pad 50B in the X-direction.

The third electrode pads 89 of the third chip 80 are separately connected to the third die pad 50B by multiple (in the first embodiment, two) third die pad wires WG. This electrically connects the third chip 80 to the third die pad 50B. Thus, the third electrode pads 89 of the third chip 80 have the third ground potential. In other words, the third electrode pads 89 are electrically connected to the third terminal 44. The third die pad wires WG are connected to a portion of the third die pad 50B located closer to the fifth side surface 53B than the third chip 80 is.

Each of the second die pad wires WE and the third die pad wires WG is a bonding wire formed with a wire bonder. In an example, the second die pad wires WE each have a portion bonded to the third electrode pad 79, as a first bonding portion, and a portion bonded to the second die pad 50A, as a second bonding portion. In an example, the third die pad wires WG each have a portion bonded to the third electrode pad 89, as a first bonding portion, and a portion bonded to the third die pad 50B, as a second bonding portion.

Referring to FIG. 3, the material forming the inter-chip wires WA differs from that forming the first terminal wires WB, the first die pad wires WC, the second terminal wires WD, the second die pad wires WE, the third terminal wires WF, and the third die pad wires WG. In an example, the first terminal wires WB, the first die pad wires WC, the second terminal wires WD, the second die pad wires WE, the third terminal wires WF, and the third die pad wires WG are formed from the same material.

The inter-chip wires WA are formed from a material including gold. The first terminal wires WB, the first die pad wires WC, the second terminal wires WD, the second die pad wires WE, the third terminal wires WF, and the third die pad wires WG are formed from a material including copper. In an example, the first terminal wires WB, the first die wires WC, the second terminal wires WD, the second die wires WE, the third terminal wires WF, and the third die pad wires WG include a copper wire having a surface coated with palladium (Pd). Thus, the oxidation resistance and the corrosion resistance are improved as compared to a wire that does not have the structure in which the surface of a copper wire is coated with palladium.

Alternatively, the first terminal wires WB, the first die pad wires WC, the second terminal wires WD, the second die pad wires WE, the third terminal wires WF, and the third die pad wires WG may be formed from a material including aluminum.

### Circuit Configuration of Signal Transmission Device

The circuit configuration of the signal transmission device 10 of the first embodiment will now be described with reference to FIG. 9.

The signal transmission device 10 includes a first circuit 500, a second circuit 520, and a third circuit 530, a first transformer 111, and a second transformer 112. In the first embodiment, the first chip 60 includes the first circuit 500, the first transformer 111, and the second transformer 112. The second chip 70 includes the second circuit 520. The third chip 80 includes the third circuit 530. The first transformer 111 is configured to insulate the first circuit 500 from the second circuit 520 while allowing for transmission of a signal between the first circuit 500 and the second circuit 520. The second transformer 112 is configured to insulate the first circuit 500 from the third circuit 530 while allowing for transmission of a signal between the first circuit 500 and the third circuit 530.

The signal transmission device 10 further includes first terminals P1 to P6, which are external terminals electrically connected to the first circuit 500, and second terminals Q1 to Q6, which are external terminals electrically connected to the second circuit 520 and the third circuit 530.

The first terminal P1 is a power terminal (VDDI). The first terminal P2 is a regulator terminal (SLDO). The first terminal P3 is a signal input terminal (PWM). The first terminal P4 is an unused terminal (DISABLE). The first terminal P5 is a timing adjustment terminal (TNEG). The first terminal P6 is a ground terminal (GNDI). In the first embodiment, the first terminal P1 corresponds to the first terminal 17. The first terminal P2 corresponds to the first terminal 14. The first terminal P3 corresponds to the first terminal 12. The first terminal P4 corresponds to the first terminal 15. The first terminal P5 corresponds to the first terminal 16. The first terminal P6 corresponds to the first terminal 11. In the first embodiment, the first terminal 13 is, for example, a test terminal.

The second terminal Q1 is a ground terminal (GNDG). The second terminal Q2 is an output terminal (OUTG). The second terminal Q3 is a power terminal (VDDG). The second terminal Q4 is a ground terminal (GNDS). The second terminal Q5 is an output terminal (OUTS). The second terminal Q6 is a power terminal (VDDS). In the first embodiment, the second terminal Q1 corresponds to the second terminal 41. The second terminal Q2 corresponds to the second terminal 42. The second terminal Q3 corresponds to the second terminal 43. The second terminal Q4 corresponds to the third terminal 44. The second terminal Q5 corresponds to the third terminal 45. The second terminal Q6 corresponds to the third terminal 46.

The first circuit 500 includes a first transmitter 501, a second transmitter 502, a logic unit 503, a low-dropout (LDO) unit 504, an under voltage lock out (UVLO) unit 505, a delay unit 506, Schmitt triggers 507 and 508, and resistors 509 and 510.

The first terminal P1 is electrically connected to the UVLO unit 505 and the LDO unit 504. The first terminal P2 is electrically connected to the LDO unit 504. The first terminals P3 and P4 are electrically connected to the logic unit 503. The first terminal P5 is electrically connected to the delay unit 506. The LDO unit 504 is electrically connected to the UVLO unit 505. The UVLO unit 505, the delay unit 506, the first transmitter 501, and the second transmitter 502 are electrically connected to the logic unit 503.

The first transmitter 501 is electrically connected to a first coil of the first transformer 111. The first transmitter 501 is configured to receives a PWM signal from the logic unit 503 and transmits the PWM signal to the second circuit 520 through the first transformer 111.

The second transmitter 502 is electrically connected to a first coil of the second transformer 112. The second transmitter 502 is configured to receive a PWM signal from the logic unit 503 and transmit the PWM signal to the third circuit 530 through the second transformer 112.

The logic unit 503 is configured to transmit various types of signals to and from a controller (not shown) provided outside the signal transmission device 10 through the first terminals P3 to P5 and is also configured to transmit various types of signals between the second circuit 520 and the third circuit 530 through the first transmitter 501 and the second transmitter 502.

The Schmitt trigger 507 and the resistor 509 are arranged in a conductive path between the first terminal P3 and the logic unit 503. The Schmitt trigger 507 includes an input terminal electrically connected to the first terminal P3 and an output terminal electrically connected to the logic unit 503. The resistor 509 is, for example, a pull-down resistor. The resistor 509 includes a first terminal electrically connected to the conductive path between the first terminal P3 and the input terminal of the Schmitt trigger 507. The resistor 509 includes a second terminal electrically connected to the first terminal P6.

The Schmitt trigger 508 and the resistor 510 are arranged in the conductive path between the first terminal P4 and the logic unit 503. The input terminal of the Schmitt trigger 508 is electrically connected to the first terminal P4. The output terminal of the Schmitt trigger 508 is electrically connected to the logic unit 503. The resistor 510 is, for example, a pull-down resistor. The resistor 510 includes a first terminal electrically connected to the conductive path between the first terminal P4 and the input terminal of the Schmitt trigger 508. The resistor 510 includes a second terminal electrically connected to the first terminal P6.

The LDO unit 504 is, for example, a shunt regulator and configured to set the voltage between the first terminal P1 and the first terminal P6 to a predetermined reference voltage.

The UVLO unit 505 is configured to stop the operation of the logic unit 503 when the voltage of a control power supply that is electrically connected to the first terminal P1 is less than a threshold voltage. This avoids occurrence of an erroneous operation.

The second circuit 520 includes a first receiver 521, a logic unit 522, a UVLO unit 523, buffer circuits 524 and 525, switching elements 526 and 527, and a resistor 528.

The second terminals Q1 and Q2 are electrically connected to the logic unit 522. The second terminal Q1 is electrically connected to the UVLO unit 523. The UVLO unit 523 and the first receiver 521 are electrically connected to the logic unit 522.

The first receiver 521 is electrically connected to a second coil of the first transformer 111. The first receiver 521 is configured to receive a PWM signal from the first transmitter 501 through the first transformer 111 and output the PWM signal to the logic unit 522.

The UVLO unit 523 is configured to stop the operation of the logic unit 522 when the voltage of a control power supply electrically connected to the second terminal Q3 is less than a threshold voltage. This avoids occurrence of an erroneous operation.

The logic unit 522 is configured to separately control the switching elements 526 and 527. More specifically, the logic unit 522 is separately electrically connected to the gate of each of the switching elements 526 and 527. The buffer circuit 524 is arranged between the logic unit 522 and the gate of the switching element 526. The buffer circuit 524 includes an input terminal electrically connected to the logic unit 522. The buffer circuit 524 includes an output terminal electrically connected to the gate of the switching element 526. The buffer circuit 525 is arranged between the logic unit 522 and the gate of the switching element 527. The buffer circuit 525 includes an input terminal electrically connected to the logic unit 522. The buffer circuit 525 includes an output terminal electrically connected to the gate of the switching element 527.

A p-channel metal-oxide-semiconductor field-effect transistor (MOSFET) is used as the switching element 526. An n-channel MOSFET is used as the switching element 527. The source of the switching element 526 is electrically connected to the second terminal Q3. The drain of the switching element 526 is electrically connected to the drain of the switching element 527. The source of the switching element 527 is electrically connected to the second terminal Q1. A node between the drain of the switching element 526 and the drain of the switching element 527 is electrically connected to the second terminal Q2. The resistor 528 is arranged between the gate and drain of the switching element 526.

The third circuit 530 includes a second receiver 531, a logic unit 532, a UVLO unit 533, buffer circuits 534 and 535, switching elements 536 and 537, and a resistor 538.

The second terminals Q4 and Q5 are electrically connected to the logic unit 532. The second terminal Q6 is electrically connected to the UVLO unit 533. The UVLO unit 533 and the second receiver 531 are electrically connected to the logic unit 532.

The second receiver 531 is electrically connected to a second coil of the second transformer 112. The second receiver 531 is configured to receive a PWM signal from the second transmitter 502 through the second transformer 112 and output the PWM signal to the logic unit 532.

The UVLO unit 533 is configured to stop the operation of the logic unit 532 when the voltage of a control power supply electrically connected to the second terminal Q6 is less than a threshold voltage. This avoids occurrence of an erroneous operation.

The logic unit 532 is configured to separately control the switching elements 536 and 537. More specifically, the logic unit 532 is separately electrically connected to the gate of each of the switching elements 536 and 537. The buffer circuit 534 is provided between the logic unit 532 and the gate of the switching element 536. The buffer circuit 534 includes an input terminal electrically connected to the logic unit 532. The buffer circuit 534 includes an output terminal electrically connected to the gate of the switching element 536. The buffer circuit 535 is provided between the logic unit 532 and the gate of the switching element 537. The buffer circuit 535 includes an input terminal electrically connected to the logic unit 532. The buffer circuit 535 includes an output terminal electrically connected to the gate of the switching element 537.

A p-channel metal-oxide-semiconductor field-effect transistor (MOSFET) is used as the switching element 536. An n-channel MOSFET is used as the switching element 537. The source of the switching element 536 is electrically connected to the second terminal Q6. The drain of the switching element 536 is electrically connected to the drain of the switching element 537. The source of the switching element 537 is electrically connected to the second terminal Q4. A node between the drain of the switching element 536 and the drain of the switching element 537 is electrically connected to the second terminal Q5. The resistor 538 is arranged between the gate and drain of the switching element 536.

### Detailed Structure of First Chip

The structure of the first chip 60, which includes a portion of the circuit configuration of the signal transmission device 10, will now be described in detail with reference to FIGS. 10 to 19.

FIGS. 10 to 13 are each a schematic plan view showing an example of the internal structure of the first chip 60. FIGS. 14 to 19 are each a schematic cross-sectional view showing an example of the internal structure of the first chip 60. In FIG. 14, to facilitate understanding, hatching lines are not shown in the cross-sectional structure of the first chip 60.

### Planar Structure of First Chip

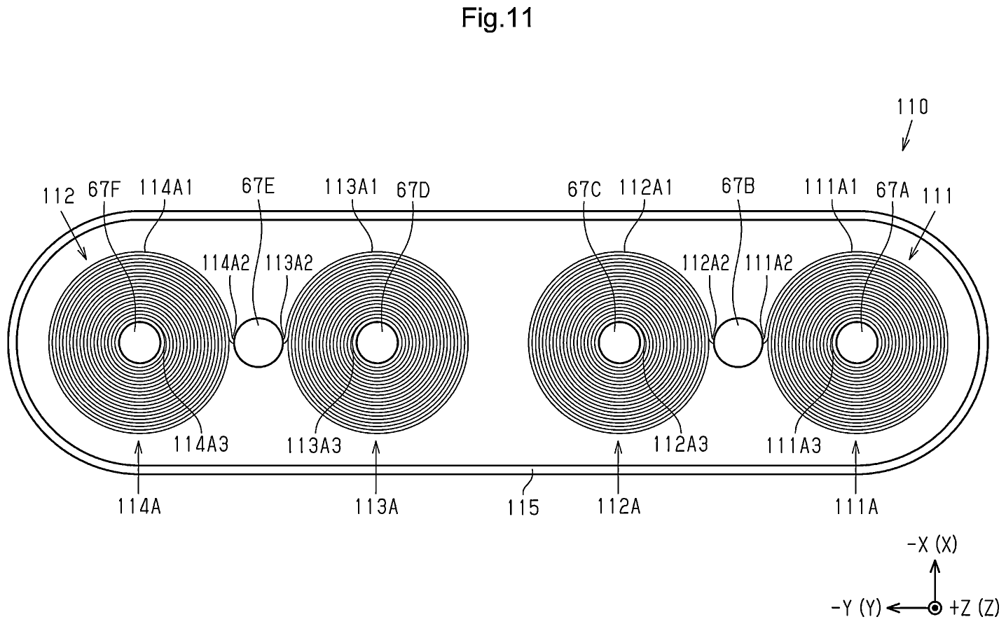

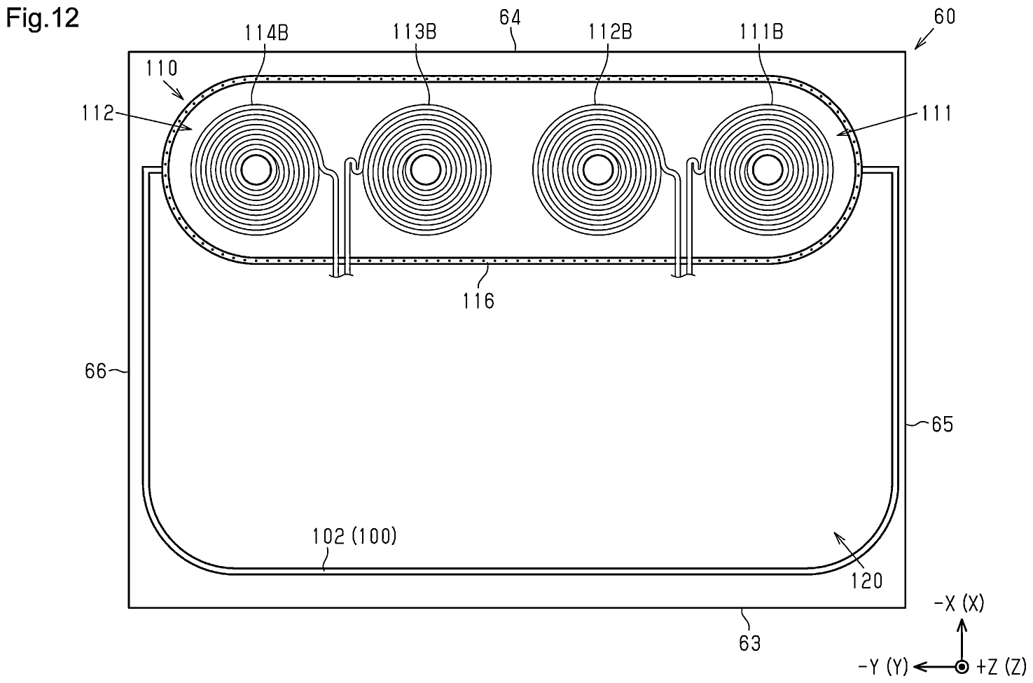

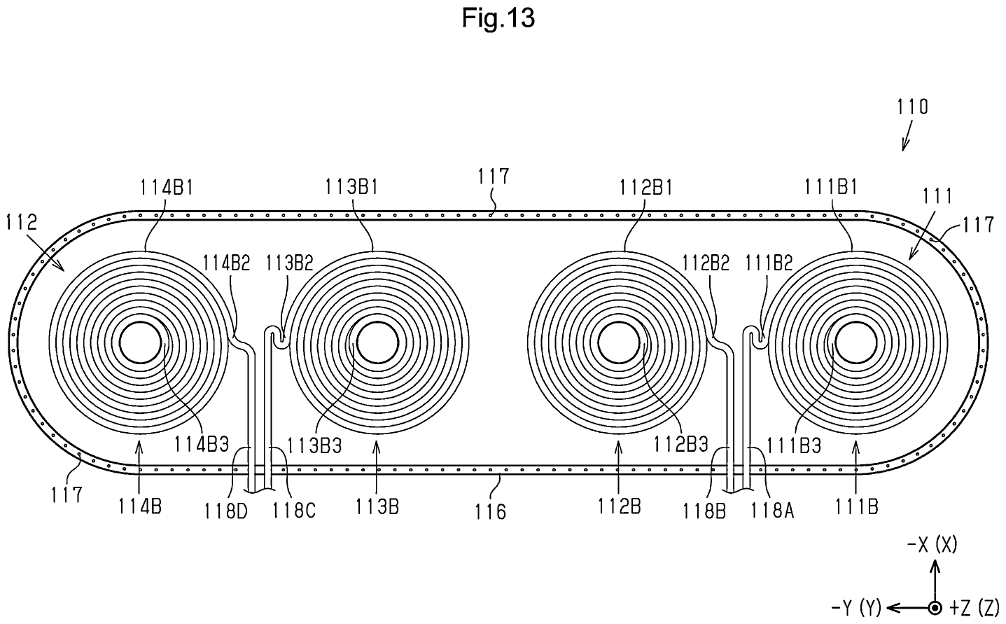

FIG. 10 is a schematic plan view showing an example of the internal structure of the first chip 60 at a position toward the chip front surface 61. FIG. 11 is an enlarged view of an isolation transformer region 110, which is shown in FIG. 10 and will be described later. FIG. 12 is a schematic plan view showing an example of the internal structure of the first chip 60 at a position toward the chip back surface 62. FIG. 13 is an enlarged view of the isolation transformer region 110 shown in FIG. 12.

The first chip 60 includes the isolation transformer region 110, a circuit region 120, and a peripheral guard ring 100. The peripheral guard ring 100 is connected to the isolation transformer region 110 and surrounds the circuit region 120.

The isolation transformer region 110 electrically insulates the circuit region 120 from the second chip 70 while allowing for transmission of a signal between the circuit region 120 and each of the second chip 70 and the third chip 80. In plan view, the isolation transformer region 110 is located closer to the second chip side surface 64 than the center, in the X-direction, of the first chip 60 is. More specifically, in plan view, the isolation transformer region 110 is formed in a region of the first chip 60 located in the vicinity of the second chip 70 and the third chip 80 (refer to FIG. 3). The isolation transformer region 110 extends over substantially the entirety of the first chip 60 in the Y-direction.

Components of the first circuit 500, shown in FIG. 9, excluding the first transformer 111 and the second transformer 112, are formed in the circuit region 120. Such components include the first transmitter 501, the second transmitter 502, the logic unit 503, the LDO unit 504, and the UVLO unit 505. In the description hereafter, the components of the first circuit 500 excluding the first transformer 111 and the second transformer 112 may be referred to as “first functional portions” and “circuit elements.”

The second electrode pads 68 and the third electrode pads 69 are formed in the circuit region 120. The second electrode pads 68 are electrically connected to at least one of the first functional portions and the circuit elements. The third electrode pads 69 are electrically connected to the circuit elements.

The first transformer 111 and the second transformer 112 are formed in the isolation transformer region 110. The first transformer 111 and the second transformer 112 are located at the same position in the X-direction and separated from each other in the Y-direction. In the example shown in FIG. 10, the first transformer 111 is located in the isolation transformer region 110 in the vicinity of the third chip side surface 65. The second transformer 112 is located in the isolation transformer region 110 in the vicinity of the fourth chip side surface 66.

As shown in FIGS. 10 and 12, the first transformer 111 includes a first front coil 111A, a first back coil 111B, a second front coil 112A, and a second back coil 112B. The second transformer 112 includes a third front coil 113A, a third back coil 113B, a fourth front coil 114A, and a fourth back coil 114B.

As shown in FIG. 10, the first to fourth front coils 111A to 114A are located at the same position in the X-direction and separated from each other in the Y-direction. The first to fourth front coils 111A to 114A are arranged in the order of the first front coil 111A, the second front coil 112A, the third front coil 113A, and the fourth front coil 114A from the third chip side surface 65 toward the fourth chip side surface 66.

As shown in FIG. 12, the first to fourth back coils 111B to 114B are located at the same position in the X-direction and separated from each other in the Y-direction. The first to fourth back coils 111B to 114B are arranged in the order of the first back coil 111B, the second back coil 112B, the third back coil 113B, and the fourth back coil 114B from the third chip side surface 65 toward the fourth chip side surface 66.

Although not shown, the first front coil 111A, the second front coil 112A, the third front coil 113A, and the fourth front coil 114A are located at the same position in the Z-direction. The first back coil 111B, the second back coil 112B, the third back coil 113B, and the fourth back coil 114B are located at the same position in the Z-direction.

Each of the first to fourth front coils 111A to 114A and the first to fourth back coils 111B to 114B may include at least one of titanium, titanium nitride, copper, aluminum, and tungsten. In an example, the first to fourth front coils 111A to 114A include copper, and the first to fourth back coils 111B to 114B include aluminum. In an example, the first to fourth front coils 111A to 114A have a layered structure of titanium and copper. The first to fourth back coils 111B to 114B have a layered structure of titanium nitride and aluminum.

As shown in FIG. 10, the first electrode pads 67 are formed in the isolation transformer region 110. The first electrode pads 67 are located at the same position in the X-direction and separated from each other in the Y-direction. The first electrode pads 67 include six first electrode pads 67A to 67F. The first electrode pads 67A to 67F are arranged in the order of the first electrode pads 67A, 67B, 67C, 67D, 67E and 67F from the third chip side surface 65 toward the fourth chip side surface 66.

As shown in FIG. 11, the first front coil 111A includes a first coil portion 111A1, which is spiral in plan view, a first outer coil end 111A2, and a first inner coil end 111A3. The first outer coil end 111A2 defines the outermost circumferential end of the first coil portion 111A1 in the winding direction. The first inner coil end 111A3 defines the innermost circumferential end of the first coil portion 111A1 in the winding direction.

The second front coil 112A includes a second coil portion 112A1, which is spiral in plan view, a second outer coil end 112A2, and a second inner coil end 112A3. The second outer coil end 112A2 defines the outermost circumferential end of the second coil portion 112A1 in the winding direction. The second inner coil end 112A3 defines the innermost circumferential end of the second coil portion 112A1 in the winding direction.

In plan view, the first electrode pad 67A is arranged in an inner space including the winding center of the first coil portion 111A1. In other words, the first electrode pad 67A is located inward from the first coil portion 111A1. The first electrode pad 67A is connected to the first inner coil end 111A3. In other words, the first electrode pad 67A is electrically connected to a first end of the first front coil 111A.

In plan view, the first electrode pad 67B is located between the first front coil 111A and the second front coil 112A in the Y-direction. The first electrode pad 67B is connected to the first outer coil end 111A2 of the first front coil 111A. The first electrode pad 67B is also connected to the second outer coil end 112A2 of the second front coil 112A. In other words, the first electrode pad 67B is electrically connected to a second end of the first front coil 111A and a second end of the second front coil 112A.

In plan view, the first electrode pad 67C is arranged in an inner space including the winding center of the second coil portion 112A1. In other words, the first electrode pad 67C is located inward from the second coil portion 112A1. The first electrode pad 67C is connected to the second inner coil end 112A3. In other words, the first electrode pad 67C is electrically connected to a first end of the second front coil 112A.

The third front coil 113A includes a third coil portion 113A1, which is spiral in plan view, a third outer coil end 113A2, and a third inner coil end 113A3. The third outer coil end 113A2 defines the outermost circumferential end of the third coil portion 113A1 in the winding direction. The third inner coil end 113A3 defines the innermost circumferential end of the third coil portion 113A1 in the winding direction.

The fourth front coil 114A includes a fourth coil portion 114A1, which is spiral in plan view, a fourth outer coil end 114A2, and a fourth inner coil end 114A3. The fourth outer coil end 114A2 defines the outermost circumferential end of the fourth coil portion 114A1 in the winding direction. The fourth inner coil end 114A3 defines the innermost circumferential end of the fourth coil portion 114A1 in the winding direction.

In plan view, the first electrode pad 67D is arranged in an inner space including the winding center of the third coil portion 113A1. In other words, the first electrode pad 67D is located inward from the third coil portion 113A1. The first electrode pad 67D is connected to the third inner coil end 113A3. In other words, the first electrode pad 67D is electrically connected to a first end of the third front coil 113A.

In plan view, the first electrode pad 67E is located between the third front coil 113A and the fourth front coil 114A in the Y-direction. The first electrode pad 67E is connected to the third outer coil end 113A2 of the third front coil 113A. The first electrode pad 67E is connected to the fourth outer coil end 114A2 of the fourth front coil 114A. In other words, the first electrode pad 67E is electrically connected to a second end of the third front coil 113A and a second end of the fourth front coil 114A.

In plan view, the first electrode pad 67F is arranged in an inner space including the winding center of the fourth coil portion 114A1. In other words, the first electrode pad 67F is located inward from the fourth coil portion 114A1. The first electrode pad 67F is connected to the fourth inner coil end 114A3. In other words, the first electrode pad 67F is electrically connected to a first end of the fourth front coil 114A.

In the example shown in FIGS. 10 and 11, the first to fourth front coils 111A to 114A have an equal number of turns. In plan view, the winding direction of the first front coil 111A is opposite to the winding direction of the second front coil 112A. The winding direction of the third front coil 113A is opposite to the winding direction of the fourth front coil 114A. The winding direction of the first front coil 111A is the same as the winding direction of the third front coil 113A. The winding direction of the second front coil 112A is the same as the winding direction of the fourth front coil 114A.

As shown in FIG. 13, the first back coil 111B is opposed to the first front coil 111A (refer to FIG. 11) in the Z-direction. The first back coil 111B includes a first coil portion 111B1, which is spiral in plan view, a first outer coil end 111B2, and a first inner coil end 111B3. The first outer coil end 111B2 defines the outermost circumferential end of the first coil portion 111B1 in the winding direction. The first inner coil end 111B3 defines the innermost circumferential end of the first coil portion 111B1 in the winding direction. The first outer coil end 111B2 is connected to a first interconnect 118A extending in the X-direction. The first interconnect 118A is electrically connected to the first transmitter 501 (refer to FIG. 9) of the circuit region 120 (refer to FIG. 10). The first inner coil end 111B3 is connected to a first wire (not shown). The first wire is electrically connected to the first transmitter 501 of the circuit region 120.

The second back coil 112B is opposed to the second front coil 112A (refer to FIG. 11) in the Z-direction. The second back coil 112B includes a second coil portion 112B1, which is spiral in plan view, a second outer coil end 112B2, and a second inner coil end 112B3. The second outer coil end 112B2 defines the outermost circumferential end of the second coil portion 112B1 in the winding direction. The second inner coil end 112B3 defines the innermost circumferential end of the second coil portion 112B1 in the winding direction. The second outer coil end 112B2 is connected to a second interconnect 118B extending in the X-direction. The second interconnect 118B is located adjacent to the first interconnect 118A in the Y-direction. The second interconnect 118B is located closer to the second back coil 112B than the first interconnect 118A is. The second interconnect 118B is electrically connected to the first transmitter 501 of the circuit region 120. The second inner coil end 112B3 is connected to a second wire (not shown). The second wire is electrically connected to the first transmitter 501 of the circuit region 120.

The third back coil 113B is opposed to the third front coil 113A (refer to FIG. 11) in the Z-direction. The third back coil 113B includes a third coil portion 113B1, which is spiral in plan view, a third outer coil end 113B2, and a third inner coil end 113B3. The third outer coil end 113B2 defines the outermost circumferential end of the third coil portion 113B1 in the winding direction. The third inner coil end 113B3 defines the innermost circumferential end of the third coil portion 113B1 in the winding direction. The third outer coil end 113B2 is connected to a third interconnect 118C extending in the X-direction. The third interconnect 118C is electrically connected to the second transmitter 502 (refer to FIG. 9) of the circuit region 120. The third inner coil end 113B3 is connected to a third wire (not shown). The third wire is electrically connected to the second transmitter 502 of the circuit region 120.

The fourth back coil 114B is opposed to the fourth front coil 114A (refer to FIG. 11) in the Z-direction. The fourth back coil 114B includes a fourth coil portion 114B1, which is spiral in plan view, a fourth outer coil end 114B2, and a fourth inner coil end 114B3. The fourth outer coil end 114B2 defines the outermost circumferential end of the fourth coil portion 114B1 in the winding direction. The fourth inner coil end 114B3 defines the innermost circumferential end of the fourth coil portion 114B1 in the winding direction. The fourth outer coil end 114B2 is connected to a fourth interconnect 118D extending in the X-direction. The fourth interconnect 118D is located adjacent to the third interconnect 118C in the Y-direction. The fourth interconnect 118D is located closer to the fourth back coil 114B than the third interconnect 118C is. The fourth interconnect 118D is electrically connected to the second transmitter 502 of the circuit region 120. The fourth inner coil end 114B3 is connected to a fourth wire (not shown). The fourth wire is electrically connected to the second transmitter 502 of the circuit region 120.

The first to fourth back coils 111B to 114B have an equal number of turns. In plan view, the winding direction of the first back coil 111B is opposite to the winding direction of the second back coil 112B. The winding direction of the third back coil 113B is opposite to the winding direction of the fourth back coil 114B. The winding direction of the first back coil 111B is the same as the winding direction of the third back coil 113B. The winding direction of the second back coil 112B is the same as the winding direction of the fourth back coil 114B. In an example, the first to fourth back coils 111B to 114B are equal in the number of turns to the first to fourth front coils 111A to 114A.

As shown in FIG. 11, in plan view, a front guard ring 115 is formed in the isolation transformer region 110 to surround the first to fourth front coils 111A to 114A and the first electrode pads 67A to 67F. The front guard ring 115 has the form of an athletic track in plan view.

As shown in FIG. 13, in plan view, a back guard ring 116 is formed in the isolation transformer region 110 to surround the first to fourth back coils 111B to 114B. The back guard ring 116 has the form of an athletic track in plan view. The back guard ring 116 is the same in shape and size as the front guard ring 115. In plan view, the back guard ring 116 overlaps the front guard ring 115.

The isolation transformer region 110 includes vias 117 connecting the front guard ring 115 and the back guard ring 116. The vias 117 are arranged to overlap both the front guard ring 115 and the back guard ring 116 in plan view.

As shown in FIG. 10, interconnect layers 121 are arranged in the circuit region 120. The interconnect layers 121 include an interconnect layer that electrically connects the first functional portions and an interconnect layer that electrically connects the functional portions to the first transformer 111 and the second transformer 112 of the isolation transformer region 110. The first functional portions are formed in the circuit region 120 at positions closer, in the Z-direction, to the chip back surface 62 (refer to FIG. 14) than the interconnect layers 121 are. In an example, although not shown in FIG. 12, the first functional portions are located at the same position as the first to fourth back coils 111B to 114B in the Z-direction. The position of the first functional portions in the Z-direction may be changed in any manner.

As shown in FIGS. 10 and 12, the peripheral guard ring 100 includes a front peripheral guard ring 101 and a back peripheral guard ring 102.

As shown in FIG. 10, the front peripheral guard ring 101 is connected to the front guard ring 115. More specifically, the front peripheral guard ring 101 is connected to the two ends of the front guard ring 115 in the Y-direction. The front peripheral guard ring 101 includes a first part extending in the X-direction at a position adjacent to the third chip side surface 65 in the Y-direction in plan view, a second part continuously extending from the first part in the Y-direction at a position adjacent to the first chip side surface 63 in the X-direction, and a third part continuously extending from the second part in the X-direction at a position adjacent to the fourth chip side surface 66 in the Y-direction. The front peripheral guard ring 101 further includes a first connecting part and a second connecting part. The first connecting part extends from the first part toward the front guard ring 115 in the Y-direction and is connected to the front guard ring 115. The second connecting part extends from the third part toward the front guard ring 115 in the Y-direction and is connected to the front guard ring 115. Thus, the front peripheral guard ring 101 is electrically connected to the front guard ring 115.

As shown in FIG. 12, the back peripheral guard ring 102 is connected to the back guard ring 116. More specifically, the back peripheral guard ring 102 is connected to two ends of the back guard ring 116 in the Y-direction. The back peripheral guard ring 102 includes a first part extending in the X-direction at a position adjacent to the third chip side surface 65 in the Y-direction in plan view, a second part continuously extending from the first part in the Y-direction at a position adjacent to the first chip side surface 63 in the X-direction, and a third part continuously extending from the second part in the X-direction at a position adjacent to the fourth chip side surface 66 in the Y-direction. The back peripheral guard ring 102 further includes a first connecting part and a second connecting part. The first connecting part extends from the first part toward the back guard ring 116 in the Y-direction and is connected to the back guard ring 116. The second connecting part extends from the third part toward the back guard ring 116 in the Y-direction and is connected to the back guard ring 116. Thus, the back peripheral guard ring 102 is electrically connected to the back guard ring 116. The back peripheral guard ring 102 is the same as the front peripheral guard ring 101 in shape and size in plan view. The back peripheral guard ring 102 is arranged to overlap the front peripheral guard ring 101 in plan view.

Although not shown, the first chip 60 includes peripheral vias connecting the front peripheral guard ring 101 and the back peripheral guard ring 102. The peripheral vias electrically connect the front peripheral guard ring 101 and the back peripheral guard ring 102. The peripheral vias each extend in the Z-direction.

### Cross-Sectional Structure of First Chip

The cross-sectional structure of the isolation transformer region 110 will now be described as an example of the internal structure of the first chip 60. In the isolation transformer region 110, the first transformer 111 and the second transformer 112 have the same structure. Thus, the structure of the first transformer 111 will be described in detail, and the second transformer 112 will not be described in detail.

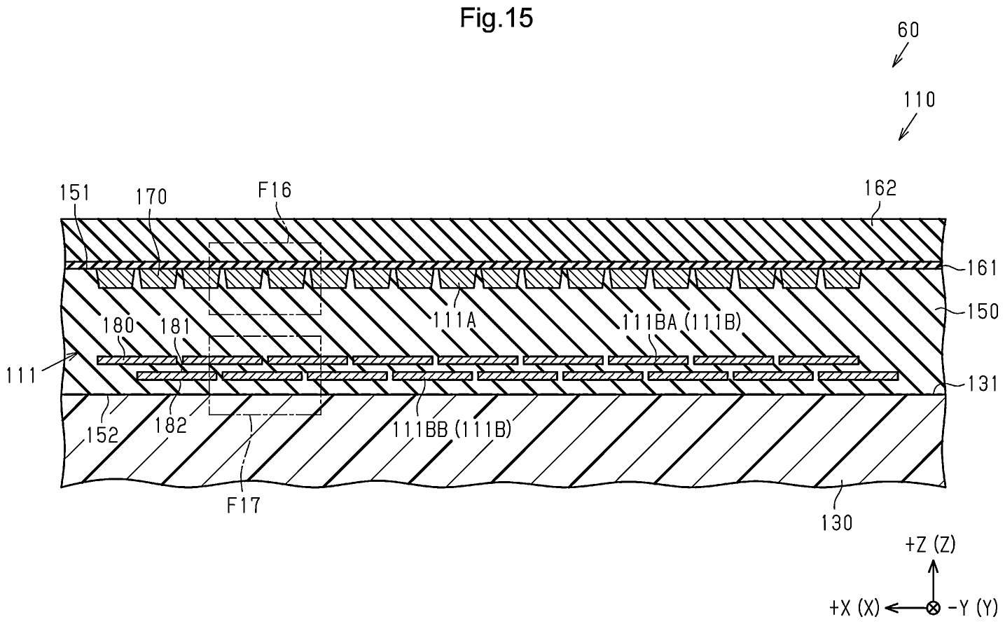

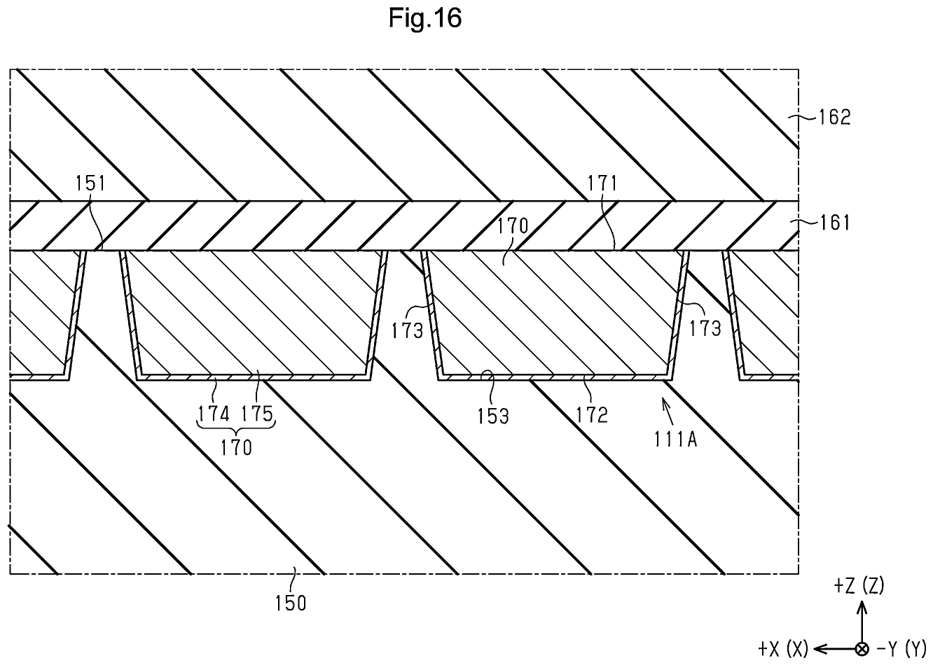

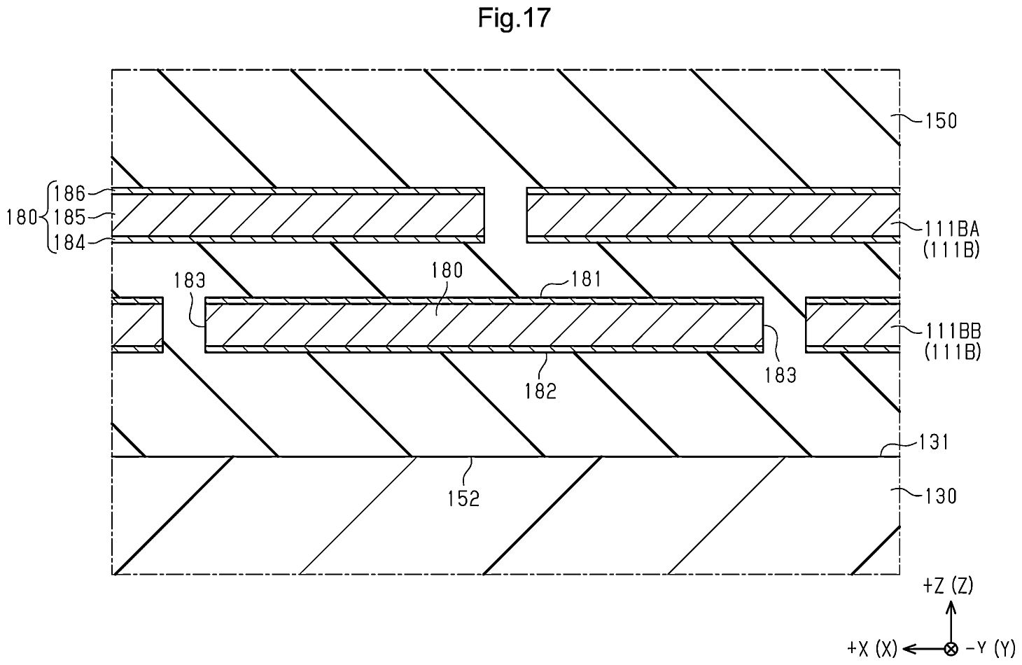

FIG. 14 is a cross-sectional view of a portion of the first transformer 111 taken along line F14-F14 in FIG. 10. FIG. 15 is an enlarged view showing a portion of the first transformer 111 shown in FIG. 14. FIG. 16 is an enlarged view of the first front coil 111A of the first transformer 111 shown in section F16 in FIG. 15. FIG. 17 is an enlarged view of the first back coil 111B of the first transformer 111 shown in section F17 in FIG. 15. To facilitate understanding, hatching lines are not shown in FIG. 14.

As shown in FIG. 14, the first chip 60 includes a substrate 130 and an element insulation layer 150 formed on the substrate 130.

The substrate 130 is formed of, for example, a semiconductor substrate. In the first embodiment, the substrate 130 is a semiconductor substrate formed from a material including silicon (Si). As the semiconductor substrate, a wide-bandgap semiconductor or a compound semiconductor may be used for the substrate 130. The substrate 130 may be an insulating substrate that is formed from a material including glass or an insulating substrate that is formed from a material including ceramics such as alumina instead of a semiconductor substrate.

The wide-bandgap semiconductor is a semiconductor substrate having a band gap that is greater than or equal to 2.0 eV. The wide-bandgap semiconductor may be any one of silicon carbide (SiC), gallium nitride (GaN), and gallium oxide (Ga₂O₃). The compound semiconductor may be a group III-V compound semiconductor. The compound semiconductor may include at least one of aluminum nitride (AlN), indium nitride (InN), gallium nitride, and gallium arsenide (GaAs).

The substrate 130 is flat. The substrate 130 includes a substrate front surface 131 and a substrate back surface 132 opposite to the substrate front surface 131. The substrate back surface 132 defines the chip back surface 62 of the first chip 60.

The element insulation layer 150 is in contact with the substrate front surface 131. In an example, the element insulation layer 150 is formed on the entirety of the substrate front surface 131. In an example, the element insulation layer 150 includes an oxide film formed from a material including silicon oxide (SiO₂). Two or more oxide films may be stacked to form the element insulation layer 150. The material forming the element insulation layer 150 may be changed in any manner.

The element insulation layer 150 includes a layer front surface 151 and a layer back surface 152 opposite to the layer front surface 151. The layer front surface 151 and the substrate front surface 131 face the same direction. The layer back surface 152 and the substrate back surface 132 face the same direction. The layer back surface 152 is in contact with the substrate front surface 131.

The first electrode pads 67A to 67F (not shown in FIG. 14, refer to FIG. 11), a passivation film 161, and a protection film 162 are formed on the element insulation layer 150.

The first electrode pads 67A to 67F are in contact with the layer front surface 151 of the element insulation layer 150. In an example, the first electrode pads 67A to 67F are located at the same position in the Z-direction.

As shown in FIG. 15, the passivation film 161 is configured to protect the element insulation layer 150 and covers the layer front surface 151. The passivation film 161 covers the first electrode pads 67A to 67F. The passivation film 161 includes openings (not shown) partially exposing the first electrode pads 67A to 67F in the Z-direction. The protection film 162 is formed on the passivation film 161. In an example, the passivation film 161 is formed of a single layer of a silicon nitride (SiN) film or a silicon oxynitride (SiON) film. In an example, the passivation film 161 is formed of a layered structure of a silicon oxide film and a silicon nitride film. In this case, the silicon nitride film may be formed on the silicon oxide film. In an example, the passivation film 161 is formed of a layered structure of a silicon oxide film and a silicon oxynitride film. In this case, the silicon oxynitride film may be formed on the silicon oxide film.

The thickness of the passivation film 161 (dimension of the passivation film 161 in the Z-direction) is less than the thickness of the protection film 162 (dimension of the protection film 162 in the Z-direction). In an example, the thickness of the passivation film 161 is less than or equal to one-third of the thickness of the protection film 162. In an example, the thickness of the passivation film 161 is less than or equal to one-fourth of the thickness of the protection film 162. In an example, the thickness of the passivation film 161 is greater than or equal to one-fifth of the thickness of the protection film 162. In the example shown in FIG. 15, the thickness of the passivation film 161 is approximately 1.3 μm.

The protection film 162 is formed on the passivation film 161. The protection film 162 is configured to protect the first chip 60 and is formed from a material including, for example, polyimide (PI). In other words, the protection film 162 is a layer that reduces stress between the encapsulation resin 90 and the element insulation layer 150 and between the encapsulation resin 90 and the substrate 130. The protection film 162 defines the chip front surface 61 of the first chip 60.

The first front coil 111A and the first back coil 111B of the first transformer 111 are spaced apart and opposed to each other in the Z-direction. The element insulation layer 150 is arranged between the first front coil 111A and the first back coil 111B in the Z-direction. The first front coil 111A and the first back coil 111B are arranged on the element insulation layer 150. More specifically, the first back coil 111B is embedded in the element insulation layer 150. The first front coil 111A is arranged closer to the layer front surface 151 of the element insulation layer 150 than the first back coil 111B is. In other words, the first back coil 111B is arranged closer to the layer back surface 152 of the element insulation layer 150 (closer to the substrate 130) than the first front coil 111A is. The first front coil 111A is exposed from the layer front surface 151 of the element insulation layer 150 in the Z-direction. The first front coil 111A is covered by the passivation film 161. The first back coil 111B is spaced apart from the layer back surface 152 of the element insulation layer 150 in the Z-direction. Thus, the first back coil 111B is separated from the substrate 130 in the Z-direction. The element insulation layer 150 is arranged between the first back coil 111B and the substrate 130.

As shown in FIG. 16, the first front coil 111A is embedded in a recess 153 recessed from the layer front surface 151 toward the layer back surface 152 (refer to FIG. 15) of the element insulation layer 150. The recess 153 is spiral in a plan view. A single conductive wire 170 is embedded in the recess 153 to form the first front coil 111A. That is, the first front coil 111A is formed by spirally forming the single conductive wire 170 in plan view.

The conductive wire 170 includes a coil front surface 171, a coil back surface 172 opposite to the coil front surface 171, and two coil side surfaces 173 joining the coil front surface 171 and the coil back surface 172. The coil front surface 171 and the layer front surface 151 of the element insulation layer 150 face the same direction. The coil back surface 172 and the layer back surface 152 face the same direction. The two coil side surfaces 173 are tapered so that the dimension in the X-direction decreases from the coil front surface 171 toward the coil back surface 172. The coil back surface 172 and the two coil side surfaces 173 are in contact with the wall of the recess 153. Thus, the coil back surface 172 and the two coil side surfaces 173 are in contact with the element insulation layer 150. The coil front surface 171 is covered by the passivation film 161.

The conductive wire 170 includes a barrier layer 174 and a metal layer 175 formed on the barrier layer 174.

The barrier layer 174 is formed to contact the wall of the recess 153. The barrier layer 174 is a thin film arranged between the metal layer 175 and the element insulation layer 150. The metal layer 175 fills the recess 153.

The metal layer 175 is formed from a material including, for example, copper. The barrier layer 174, for example, inhibits copper diffusion. The barrier layer 174 may include at least one of titanium, titanium nitride, tantalum (Ta), and tantalum nitride (TaN). The metal layer 175 may include at least one of aluminum, gold (Au), silver, and tungsten (W).

The conductive wire 170 of the first front coil 111A has a thickness that is greater than that of the passivation film 161 and less than that of the protection film 162. The thickness of the conductive wire 170 is greater than that of the first back coil 111B (refer to FIG. 15). In an example, the thickness of the conductive wire 170 is greater than or equal to twice the thickness of the passivation film 161 and less than or equal to three times the thickness of the passivation film 161. In an example, the thickness of the conductive wire 170 is less than or equal to one-half of the thickness of the protection film 162. In an example, the thickness of the conductive wire 170 is greater than or equal to one-third of the thickness of the protection film 162. The thickness of the conductive wire 170 is defined by the distance between the coil front surface 171 and the coil back surface 172 in the Z-direction.

The width (dimension in the X-direction in FIG. 16) of the coil front surface 171 of the conductive wire 170 is greater than the thickness of the conductive wire 170. In an example, the width of the coil front surface 171 is greater than or equal to twice the thickness of the conductive wire 170. In an example, the width of the coil front surface 171 is less than or equal to three times the thickness of the conductive wire 170. In the example of FIG. 16, the width of the coil front surface 171 is approximately 6.8 μm.

In the first front coil 111A, the element insulation layer 150 is arranged between portions of the conductive wire 170 located adjacent to each other in the X-direction. Thus, in the first front coil 111A, the portions of the conductive wire 170 are spaced apart from each other in the X-direction. The distance between adjacent portions of the conductive wire 170 in the X-direction gradually increases from the coil front surface 171 toward the coil back surface 172.

Referring to FIG. 16, the distance between the coil front surfaces 171 of portions of the conductive wire 170 adjacent to each other in the X-direction is defined as the inter-wire distance. The inter-wire distance refers to the minimum distance between portions of the conductive wire 170 adjacent to each other in the X-direction. The inter-wire distance is less than the dimension of the coil front surface 171 in the X-direction. In an example, the inter-wire distance is less than or equal to one-half of the width of the coil front surface 171. In an example, the inter-wire distance is less than or equal to one-third of the width of the coil front surface 171. In an example, the inter-wire distance is less than or equal to one-fourth of the width of the coil front surface 171. In an example, the inter-wire distance is less than or equal to one-fifth of the width of the coil front surface 171. In an example, the inter-wire distance is less than or equal to one-sixth of the width of the coil front surface 171. In an example, the inter-wire distance is greater than or equal to one-seventh of the width of the coil front surface 171. The inter-wire distance is less than the thickness of the conductive wire 170. In an example, the inter-wire distance is less than or equal to one-half of the thickness of the conductive wire 170. In an example, the inter-wire distance is greater than or equal to one-third of the thickness of the conductive wire 170. In the example of FIG. 16, the inter-wire distance is approximately 1 μm.

As shown in FIGS. 15 and 17, the first back coil 111B includes two coil layers 111BA and 111BB. The coil layer 111BA forms a conductive wire located toward the layer front surface 151 of the element insulation layer 150. The coil layer 111BB forms a conductive wire located toward the layer back surface 152. The coil layer 111BA and the coil layer 111BB are separated from each other in the Z-direction. The element insulation layer 150 is arranged between the coil layer 111BA and the coil layer 111BB in the Z-direction. Each of the coil layers 111BA and 111BB includes a conductive wire 180. More specifically, the coil layer 111BA is formed by spirally forming the conductive wire 180 in plan view. The coil layer 111BB is formed by spirally forming the conductive wire 180 in plan view. The number of turns in the first back coil 111B is specified by the sum of the number of turns in the coil layer 111BA and the number of turns in the coil layer 111BB.

As shown in FIG. 15, the coil layer 111BA and the coil layer 111BB are located at different positions in the X-direction. In plan view, the coil layer 111BA partially overlaps the coil layer 111BB. In other words, in plan view, the coil layer 111BA and the coil layer 111BB include portions that do not overlap each other. In the example shown in FIG. 17, the coil layer 111BA is shifted from the coil layer 111BB in the X-direction by an amount corresponding to one-half of the width (dimension in the X-direction in FIG. 17) of the conductive wire 180.

The coil layers 111BA and 111BB are shifted from the first front coil 111A in the X-direction. In plan view, the coil layers 111BA and 111BB partially overlap the first front coil 111A. In the example shown in FIG. 17, the coil layer 111BA is shifted toward the first chip side surface 63 (refer to FIG. 10) from the first front coil 111A (refer to FIG. 15). The coil layer 111BB is shifted toward the second chip side surface 64 (refer to FIG. 10) from the first front coil 111A.

The coil layers 111BA and 111 have an equal number of turns. The number of turns of each of the coil layers 111BA and 111BB is less than that of the first front coil 111A. In an example, the number of turns of the coil layer 111BA is one-half of the number of turns of the first front coil 111A. The number of turns of the coil layer 111BB is one-half of the number of turns of the first front coil 111A. That is, the sum of the number of turns of the coil layer 111BA and the number of turns of the coil layer 111BB is equal to the number of turns of the first front coil 111A. Thus, the first back coil 111B and the first front coil 111A have an equal number of turns.

Conductive wires 180 having an identical shape are spirally formed in plan view to form the coil layer 111BA and the coil layer 111BB. The conductive wire 180 includes a coil front surface 181, a coil back surface 182 opposite to the coil front surface 181, and two coil side surfaces 183 joining the coil front surface 181 and the coil back surface 182. The coil front surface 181 and the layer front surface 151 of the element insulation layer 150 face the same direction. The coil back surface 182 and the layer back surface 152 face the same direction. The two coil side surfaces 183 extend in the Z-direction. The coil front surface 181, the coil back surface 182, and the two coil side surfaces 183 are in contact with the element insulation layer 150.

As shown in FIG. 17, the conductive wire 180 includes a back barrier layer 184, a metal layer 185 formed on the back barrier layer 184, and a front barrier layer 186 formed on the metal layer 185.

The back barrier layer 184 defines the coil back surface 182 of the conductive wire 180. The back barrier layer 184 is a thin film arranged between the back surface of the metal layer 185 and the element insulation layer 150 in the Z-direction.

The front barrier layer 186 defines the coil front surface 181 of the conductive wire 180. The front barrier layer 186 is a thin film arranged between the front surface of the metal layer 185 and the element insulation layer 150 in the Z-direction.

The metal layer 185 is greater in thickness than the back barrier layer 184 and the front barrier layer 186. The two side surfaces of the metal layer 185 are not covered by the back barrier layer 184 and the front barrier layer 186 and are in contact with the element insulation layer 150. The two side surfaces of the metal layer 185 define portions of the two coil side surfaces 183 in the Z-direction.

The metal layer 185 is formed from a material including, for example, aluminum. The back barrier layer 184 and the front barrier layer 186 may each include titanium or titanium nitride. As described above, the first back coil 111B and the first front coil 111A may be formed from different materials.

The material forming the first front coil 111A and the material forming the first back coil 111B may be changed in any manner. In an example, the material forming the first front coil 111A and the material forming the first back coil 111B may be the same.

As shown in FIG. 15, the thickness of the conductive wire 180 of the first back coil 111B is smaller than the thickness of the protection film 162. The thickness of the conductive wire 180 is smaller than the thickness of the conductive wire 170. In an example, the thickness of the conductive wire 180 is less than or equal to one-half of the thickness of the conductive wire 170. In an example, the thickness of the conductive wire 180 is approximately one-third of the thickness of the conductive wire 170. The thickness of the conductive wire 180 is smaller than the thickness of the passivation film 161. The thickness of the conductive wire 180 is greater than or equal to one-half of the thickness of the passivation film 161. The thickness of the conductive wire 180 is defined by the distance between the coil front surface 181 and the coil back surface 182 (refer to FIG. 17) in the Z-direction.

The width (dimension in the X-direction in FIG. 15) of the conductive wire 180 is greater than the thickness of the conductive wire 180. In an example, the width of the conductive wire 180 is greater than or equal to twice the thickness of the conductive wire 180. In an example, the width of the conductive wire 180 is greater than or equal to five times the thickness of the conductive wire 180. In an example, the width of the conductive wire 180 is greater than or equal to ten times the thickness of the conductive wire 180. In an example, the width of the conductive wire 180 is greater than or equal to twelve times the thickness of the conductive wire 180. In an example, the width of the conductive wire 180 is greater than or equal to fifteen times the thickness of the conductive wire 180. In an example, the width of the conductive wire 180 is greater than or equal to sixteen times the thickness of the conductive wire 180. In an example, the width of the conductive wire 180 is approximately seventeenth times the thickness of the conductive wire 180.

In an example, the width of the conductive wire 180 is greater than the width of the conductive wire 170. The width of the conductive wire 180 is greater than or equal to twice the width of the conductive wire 170. The width of the conductive wire 180 is less than or equal to three times the width of the conductive wire 170. In the example of FIG. 15, the width of the conductive wire 180 is approximately 15.8 μm. The width of the conductive wire 170 is defined as the dimension of the conductive wire 170 in a direction orthogonal to the direction in which the conductive wire 170 extends in plan view. The width of the conductive wire 180 is defined as the dimension of the conductive wire 180 in a direction orthogonal to the direction in which the conductive wire 180 extends in plan view.

In the coil layers 111BA and 111BB, the element insulation layer 150 is arranged between portions of the conductive wire 180 located adjacent to each other in the X-direction. Thus, in the coil layers 111BA and 111BB, the portions of the conductive wire 180 are spaced apart from each other in the X-direction. The distance between portions of the conductive wire 180 located adjacent to each other in the X-direction (hereinafter, referred to as “inter-wire distance”) is constant from the coil front surface 181 toward the coil back surface 182. The inter-wire distance is less than the width of the conductive wire 180. In an example, the inter-wire distance is less than or equal to one-half of the width of the conductive wire 180. In an example, the inter-wire distance is less than or equal to one-fifth of the width of the conductive wire 180. In an example, the inter-wire distance is less than or equal to one-tenth of the width of the conductive wire 180. In an example, the inter-wire distance is less than or equal to one-fifteenth of the width of the conductive wire 180. In an example, the inter-wire distance is less than or equal to one-sixteenth of the width of the conductive wire 180. In an example, the inter-wire distance is less than or equal to one-seventeenth of the width of the conductive wire 180. In an example, the inter-wire distance is less than or equal to one-eighteenth of the width of the conductive wire 180. In an example, the inter-wire distance is less than or equal to one-nineteenth of the width of the conductive wire 180. In an example, the inter-wire distance is greater than or equal to one-twentieth of the width of the conductive wire 180. The inter-wire distance is less than the thickness of the conductive wire 180. The inter-wire distance is greater than or equal to one-half the thickness of the conductive wire 180. The inter-wire distance of each of the coil layers 111BA and 111BB is less than the inter-wire distance of the first front coil 111A. In the example of FIG. 15, the inter-wire distance is approximately 0.8 μm.

The distance between the first front coil 111A and the first back coil 111B in the Z-direction is greater than the distance between the layer back surface 152 of the element insulation layer 150 and the first back coil 111B in the Z-direction. In an example, the distance between the first front coil 111A and the first back coil 111B in the Z-direction is less than the width of the conductive wire 180. The distance between the first front coil 111A and the first back coil 111B in the Z-direction is, for example, approximately 12.8 μm. The distance between the first front coil 111A and the first back coil 111B in the Z-direction is defined by the distance between the coil back surface 172 of the conductive wire 170 and the coil front surface 181 of the conductive wire 180 of the coil layer 111BA in the Z-direction. The distance between the first front coil 111A and the first back coil 111B in the Z-direction is set in accordance with a desired breakdown voltage and the electric field strength of each of the first front coil 111A and the first back coil 111B.

In the first embodiment, the conductive wire 170 of the first front coil 111A is formed so that the coil front surface 171 is exposed from the element insulation layer 150 in the Z-direction. However, there is no limit to such a configuration. The conductive wire 170 of the first front coil 111A may be embedded in the element insulation layer 150. That is, the element insulation layer 150 may be in contact with the coil front surface 171 of the conductive wire 170. In other words, the conductive wire 170 may be arranged closer to the layer back surface 152 of the element insulation layer 150 than the layer front surface 151 is.

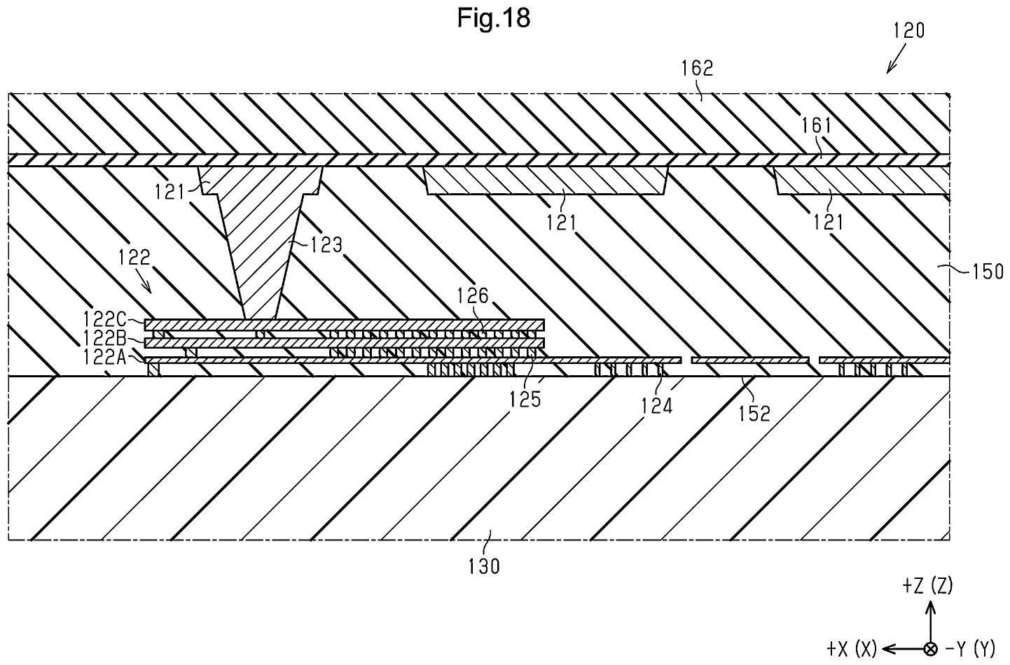

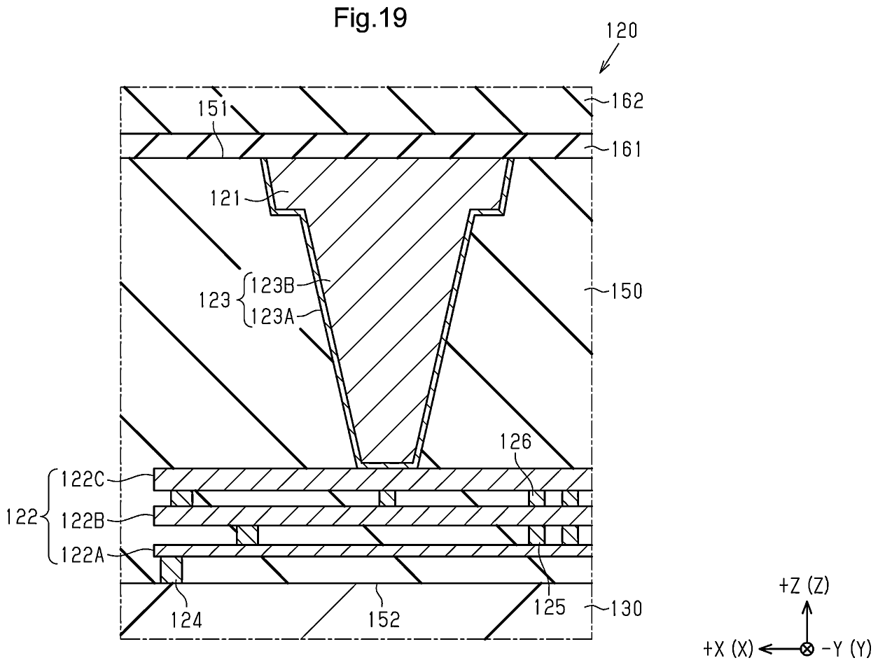

With reference to FIGS. 18 and 19, an example of the wiring configuration of the circuit region 120 will now be described.

The circuit region 120 includes an interconnect layer 121 and a substrate-side interconnect layer 122 located closer to the substrate 130 than the interconnect layer 121 is.

In an example, the interconnect layer 121 and the first front coil 111A of the first transformer 111 are located at the same position in the Z-direction. More specifically, the front surface of the interconnect layer 121 is exposed from the layer front surface 151 of the element insulation layer 150 and covered by the passivation film 161. In the example shown in FIG. 18, the thickness of the interconnect layer 121 is 2.8 μm.

The substrate-side interconnect layer 122 is embedded in the element insulation layer 150. In an example, the substrate-side interconnect layer 122 includes a first interconnect layer 122A, a second interconnect layer 122B, and a third interconnect layer 122C. The first interconnect layer 122A is located closer, in the Z-direction, to the substrate 130 than the second interconnect layer 122B and the third interconnect layer 122C are. The first interconnect layer 122A is separated from the layer back surface 152 of the element insulation layer 150 in the Z-direction. In other words, the first interconnect layer 122A is separated from the substrate 130 in the Z-direction. The element insulation layer 150 is arranged between the first interconnect layer 122A and the substrate 130 in the Z-direction.

The circuit region 120 includes a first via 123 connecting the interconnect layer 121 and the substrate-side interconnect layer 122. In the example shown in FIG. 18, the first via 123 connects the interconnect layer 121 and the first interconnect layer 122A. The first via 123 and the interconnect layer 121 are formed from, for example, the same material.

As shown in FIG. 19, the first via 123 includes, for example, a barrier layer 123A and a metal layer 123B in the same manner as the conductive wire 170. The material forming the barrier layer 123A and the metal layer 123B is, for example, the same as the material forming the barrier layer 174 and the metal layer 175 of the conductive wire 170 (refer to FIG. 16).

As shown in FIG. 18, the circuit region 120 includes second vias 124 connecting the first interconnect layer 122A and the substrate 130, third vias 125 connecting the first interconnect layer 122A and the second interconnect layer 122B, and fourth vias 126 connecting the second interconnect layer 122B and the third interconnect layer 122C. Thus, in the example shown in FIG. 18, the substrate-side interconnect layer 122 is electrically connected to the substrate 130. The first to fourth vias 123 to 126 are formed from a material including, for example, tungsten.

As shown in FIG. 19, the first interconnect layer 122A, the second interconnect layer 122B, and the third interconnect layer 122C differ from one another in thickness. The first interconnect layer 122A is smaller in thickness than each of the second interconnect layer 122B and the third interconnect layer 122C. The second interconnect layer 122B and the third interconnect layer 122C have the same thickness. That is, the thickness of the first to third interconnect layers 122A to 122C is decreased in the vicinity of the substrate 130 in the Z-direction. In other words, the first to third interconnect layers 122A to 122C have a thickness that is increased as the substrate 130 becomes farther in the Z-direction. In an example, the thickness of each of the second interconnect layer 122B and the third interconnect layer 122C is less than or equal to twice the thickness of the first interconnect layer 122A. In the example shown in FIG. 19, the first interconnect layer 122A has a thickness of, for example, 0.52 μm, and the second interconnect layer 122B and the third interconnect layer 122C each have a thickness of, for example, 0.93 μm. In an example, the second interconnect layer 122B and the coil layer 111BB of the first back coil 111B are located at the same position in the Z-direction. The third interconnect layer 122C and the coil layer 111BA are located at the same position in the Z-direction.

### Advantages

The signal transmission device 10 of the first embodiment obtains the following advantages.

(1-1) The signal transmission device 10 includes the inter-chip wires WA, which electrically connect the first chip 60 and the second chip 70, and the first terminal wires WB, which separately connect the first chip 60 to the first terminals 12 to 17. The inter-chip wire WA is formed from a material including gold. The first terminal wire WB is formed from a material including copper or aluminum.

From the viewpoint of the insulation reliability of the signal transmission device 10, the inter-chip wire WA is relatively important, and the height and the shape of the inter-chip wire WA need to be inspected accurately. In this regard, in the first embodiment, the inter-chip wire WA is formed from a material including gold. For example, when the height of the inter-chip wire WA is checked through X-ray inspection, the inter-chip wire WA is shown clearly as compared to when the inter-chip wire WA is formed from a material including copper or aluminum. Thus, the height of the inter-chip wire WA is inspected accurately. The shape of the inter-chip wire WA is also inspected accurately.

The first terminal wire WB is less important than the inter-chip wire WA from the viewpoint of the insulation reliability of the signal transmission device 10. In the first embodiment, the first terminal wire WB is formed from a material including copper or aluminum. Thus, the cost is reduced as compared to when the first terminal wire WB is formed from a material including gold. Therefore, both quality improvement and cost reduction are achieved in the signal transmission device 10.

(1-2) The first terminal wire WB includes a copper wire having a surface coated with palladium.

With this configuration, the coating of palladium on the surface of the copper wire increases the area where each of the first terminals 12 to 17 is bonded to the first terminal wire WB, which is the second bonding portion of the first terminal wire WB. This increases the bonding strength between the first terminal wires WB and the first terminals 12 to 17, thereby limiting formation of cracks in the bonding portions of the first terminal wires WB to the first terminals 12 to 17.

(1-3) The signal transmission device 10 further includes the second terminal wires WD separately connecting the second chip 70 to the second terminals 42 and 43. The signal transmission device 10 further includes the third terminal wires WF separately connecting the third chip 80 to the third terminals 45 and 46. The second terminal wire WD and the third terminal wire WF are each formed from a material including copper or aluminum.

With this configuration, the second terminal wire WD and the third terminal wire WF, which are less important than the inter-chip wire WA from the viewpoint of the insulation reliability of the signal transmission device 10, are formed from a material including copper or aluminum. Thus, the cost is reduced as compared to a configuration in which the second terminal wire WD and the third terminal wire WF are formed from a material including gold.

(1-4) The second terminal wire WD includes a copper wire having a surface coated with palladium. The third terminal wire WF includes a copper wire having a surface coated with palladium. With this configuration, the advantage (1-2) described above is obtained.

(1-5) The signal transmission device 10 further includes the first die pad wire WC connecting the first chip 60 and the first die pad 30. The first die pad wire WC is formed from a material including copper or aluminum. With this configuration, the advantage (1-3) described above is obtained.

(1-6) The first die pad wire WC includes a copper wire having a surface coated with palladium.

With this configuration, the advantage (1-2) described above is obtained.

(1-7) The signal transmission device 10 further includes the second die pad wire WE connecting the second chip 70 to the second die pad 50A. The second die pad wire WE is formed from a material including copper or aluminum. With this configuration, the advantage (1-3) described above is obtained.

(1-8) The second die pad wire WE includes a copper wire having a surface coated with palladium.

With this configuration, the advantage (1-2) described above is obtained.

(1-9) The signal transmission device 10 further includes the third die pad wire WG connecting the third chip 80 to the third die pad 50B. The third die pad wire WG is formed from a material including copper or aluminum. With this configuration, the advantage (1-3) described above is obtained.

(1-10) The third die pad wire WG includes a copper wire having a surface coated with palladium.

With this configuration, the advantage (1-2) described above is obtained.

(1-11) The first electrode pads 67, the second electrode pads 68, and the third electrode pads 69 of the first chip 60 each have a thickness of 2 μm or greater.

With this configuration, when the inter-chip wire WA is bonded to the first electrode pad 67, cracks are less likely to be formed in the element insulation layer 150 located immediately below the first electrode pad 67. Also, when the first terminal wire WB is bonded to the second electrode pad 68, cracks are less likely to be formed in the element insulation layer 150. Also, when the first die pad wire WC is bonded to the third electrode pad 69, cracks are less likely to be formed in the element insulation layer 150.

(1-12) The encapsulation resin 90 includes sulfur as an additive. The additive concentration of sulfur is less than or equal to 300 μg/g.

This configuration inhibits corrosion of a copper wire having a palladium-coated surface such as the first terminal wire WB, the second terminal wire WD, the third terminal wire WF, the first die pad wire WC, the second die pad wire WE, and the third die pad wire WG.

(1-13) The plating layer 25 is formed on the inner terminal front surface 21 of the first inner terminal portion 12B of the first terminal 12. The end of the inner terminal front surface 21 of the first inner terminal portion 12B located toward the distal surface 24 is free of the plating layer 25 and is in contact with the encapsulation resin 90.

This structure avoids delamination of the plating layer 25 from the encapsulation resin 90 at the end of the inner terminal front surface 21 of the first inner terminal portion 12B located toward the distal surface 24. The first inner terminal portions 12B to 17B of the first terminals 12 to 17 have the same structure and thus obtain the same advantage.

(1-14) The plating layer 25 is formed on the inner terminal front surfaces 21 of the second inner terminal portions 42B and 43B of the second terminals 42 and 43. The ends of the inner terminal front surfaces 21 of the second inner terminal portions 42B and 43B located toward the distal surface 24 are free of the plating layer 25 and are in contact with the encapsulation resin 90. This structure avoids delamination of the plating layer 25 from the encapsulation resin 90 at the ends of the inner terminal front surfaces 21 of the second inner terminal portions 42B and 43B located toward the distal surface 24.

(1-15) The plating layer 25 is formed on the inner terminal front surfaces 21 of the third inner terminal portions 45B and 46B of the third terminals 45 and 46. The ends of the inner terminal front surfaces 21 of the third inner terminal portions 45B and 46B located toward the distal surface 24 are free of the plating layer 25 and are in contact with the encapsulation resin 90. This structure avoids delamination of the plating layer 25 from the encapsulation resin 90 at the ends of the inner terminal front surfaces 21 of the third inner terminal portions 45B and 46B located toward the distal surface 24.

(1-16) The outer surface of the encapsulation resin 90 is formed to have the surface roughness Rz of 8 μm or greater.

This structure increases the creepage distance from the first terminals 11 to 17 to the second terminals 41 to 43 and the third terminals 44 to 46 along the encapsulation resin 90. Thus, the breakdown voltage between the first terminals 11 to 17 and the second terminals 41 to 43 and between the first terminals 11 to 17 and the third terminals 44 to 46 is improved.

(1-17) The distance in the Y-direction between the second terminal 43 and the third terminal 44, which corresponds to the shortest one of the distances between the second terminals 41 to 43 and the third terminals 44 to 46, is greater than the distance in the Y-direction between the second terminal 41 and the second terminal 42, which corresponds to the distance between ones of the second terminals 41 to 43 adjacent to each other in the second direction.

This structure increases the creepage distance from the second terminals 41 to 43 to the third terminals 44 to 46. Thus, the breakdown voltage between the second chip 70 and the third chip 80 is improved.

### Second Embodiment

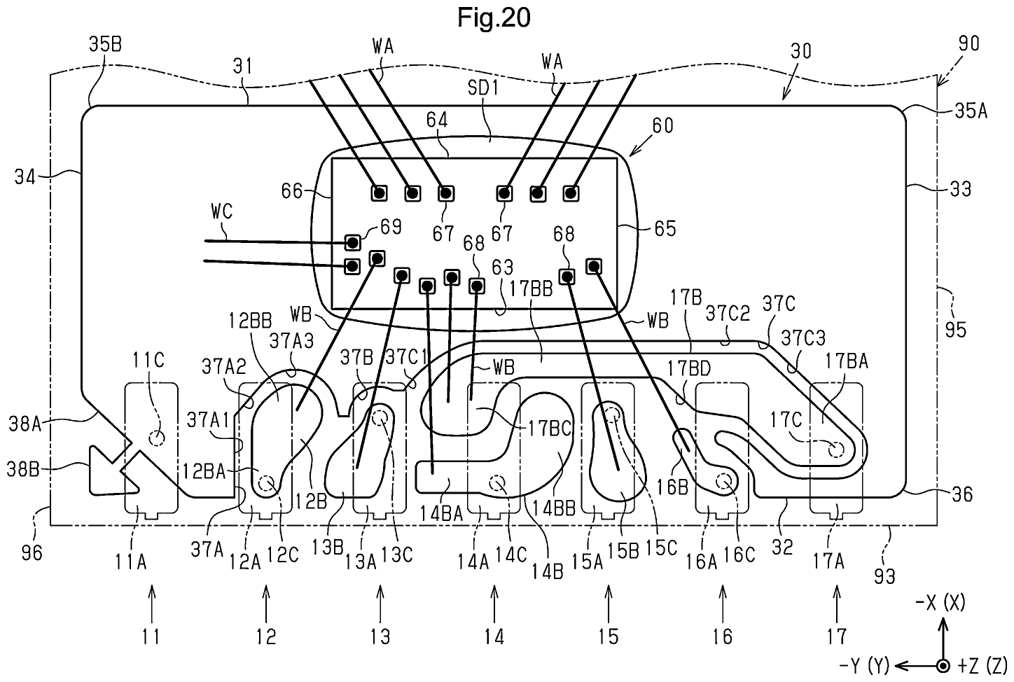

A second embodiment of a signal transmission device 10 will now be described with reference to FIG. 20. The signal transmission device 10 of the second embodiment differs from the signal transmission device 10 of the first embodiment in part of the structure of the first terminals 11 to 17. In the following description, the differences from the first embodiment will be described in detail. The same reference characters are given to those components that are the same as the corresponding components of the first embodiment. Such components will not be described in detail.

As shown in FIG. 20, of the first terminals 12 to 17, the shape of the first terminal 16 differs from that of the first embodiment. More specifically, the first inner terminal portion 16B of the first terminal 16 extends toward the second electrode pad 68, which serves as the first bonding portion of the first terminal wire WB that is connected to the first inner terminal portion 16B. Thus, in plan view, the first terminal wire WB connected to the first inner terminal portion 16B extends parallel to the first inner terminal portion 16B. When the absolute value of the difference between the direction in which the first terminal wire WB connected to the first inner terminal portion 16B extends and the direction in which the first inner terminal portion 16B extends is less than or equal to 5°, it is considered that in plan view, the first terminal wire WB connected to the first inner terminal portion 16B extends parallel to the first inner terminal portion 16B.

In plan view, the first terminal wire WB connected to the first inner terminal portion 16B extends over the distal surface of the first inner terminal portion 16B. The first terminal wire WB, which extends over the distal surface of the first inner terminal portion 16B in plan view, is bonded to the first inner terminal portion 16B. The distal surface of the first inner terminal portion 16B is the side surface of the first inner terminal portion 16B that is opposed to the first die pad 30 and faces the first chip 60. In the second embodiment, the distal surface of the first inner terminal portion 16B corresponds to a “side surface intersecting the first terminal wire WB that is connected to the first inner terminal portion 16B in plan view.”

### Advantages

The signal transmission device 10 of the second embodiment obtains the following advantages.

(2-1) In plan view, the first inner terminal portion 16B of the first terminal 16 extends parallel to the first terminal wire WB that is connected to the first inner terminal portion 16B. With this structure, the first terminal wire WB is stably bonded to the first inner terminal portion 16B of the first terminal 16.

### Third Embodiment

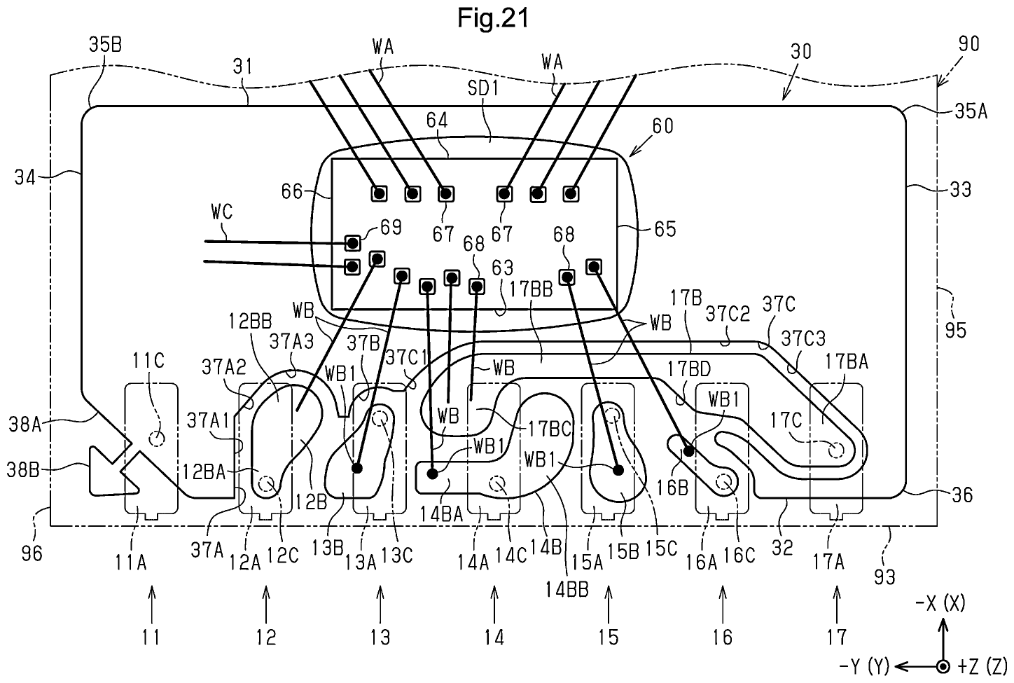

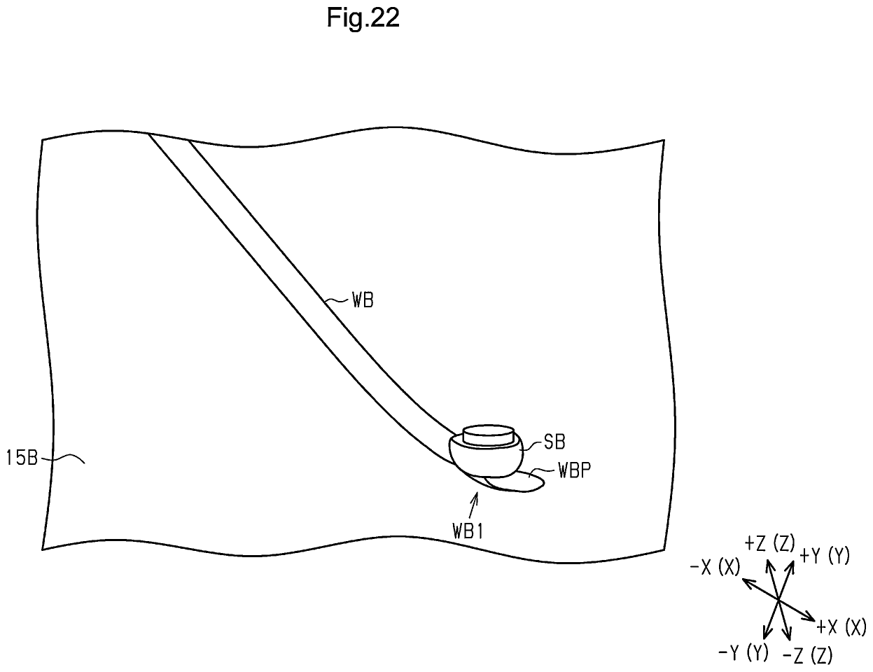

A third embodiment of a signal transmission device 10 will now be described with reference to FIGS. 21 and 22. The signal transmission device 10 of the third embodiment differs from the signal transmission device 10 of the first embodiment in the structure of the second bonding portion of some of the first terminal wires WB. In the following description, the differences from the first embodiment will be described in detail. The same reference characters are given to those components that are the same as the corresponding components of the first embodiment. Such components will not be described in detail.

As shown in FIG. 21, in the third embodiment, the second bonding portions of the first terminal wires WB connected to the first inner terminal portions 13B to 16B each include security bonding WB1. The second bonding portions of the first terminal wires WB connected to the first inner terminal portions 12B and 17B do not include security bonding WB1.

More specifically, the first terminal wires WB include a first specified wire including a portion that is bonded with security bonding WB1 to the first inner terminal portion (in the third embodiment, first inner terminal portions 13B to 16B) and a second specified wire including a portion that is bonded without security bonding WB1 to the first inner terminal portion (in the third embodiment, first inner terminal portions 12B and 17B).

FIG. 22 is a perspective view including the second bonding portion of the first terminal wire WB bonded to the first inner terminal portion 15B. The second bonding portions of the first terminal wires WB bonded to the first inner terminal portions 13B, 14B, and 16B have the same structure as the second bonding portion of the first terminal wire WB bonded to the first inner terminal portion 15B. Thus, the structure of the second bonding portion of the first terminal wire WB bonded to the first inner terminal portion 15B will be described in detail. The structure of the second bonding portions of the first terminal wires WB bonded to the first inner terminal portions 13B, 14B, and 16B will not be described in detail.

As shown in FIG. 22, the second bonding portion of the first terminal wire WB includes a bonding portion WBP bonded to the first inner terminal portion 15B. The bonding portion WBP is a portion pressed against the first inner terminal portion 15B and flattened by a wire bonder. The thickness of the bonding portion WBP is less than the diameter of the first terminal wire WB.

The security bonding WB1 is formed by, for example, mounting a stud bump SB on the bonding portion WBP. In an example, the stud bump SB is formed by ball bonding using the wire bonder. The bonding portion WBP is sandwiched between the first inner terminal portion 15B and the stud bump SB.

### Advantages

The signal transmission device 10 of the third embodiment obtains the following advantages.

(3-1) The security bonding WB1 is formed in the second bonding portions of the first terminal wires WB connected to the first inner terminal portions 13B to 16B.

With this structure, for example, even when force is applied to the first terminal wires WB during the manufacturing process, the security bonding WB1 limits separation of the first terminal wires WB from the first inner terminal portions 13B to 16B. The security bonding WB1 is not formed on the second bonding portions of the first terminal wires WB connected to the first inner terminal portions 12B and 17B. This simplifies the manufacturing process. Thus, the manufacturing cost of the signal transmission device 10 is reduced.

### Fourth Embodiment

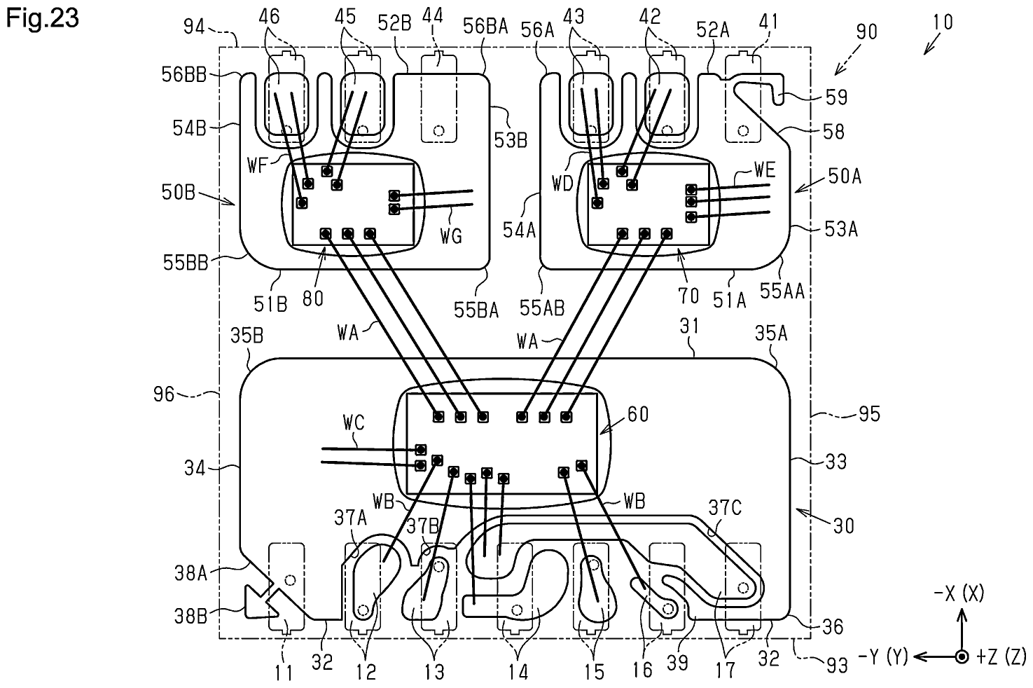

A fourth embodiment of the signal transmission device 10 will now be described with reference to FIG. 23. The signal transmission device 10 of the fourth embodiment differs from the signal transmission device 10 of the first embodiment in the structures of the first die pad 30, the second die pad 50A, and the third die pad 50B. In the following description, the differences from the first embodiment will be described in detail. The same reference characters are given to those components that are the same as the corresponding components of the first embodiment. Such components will not be described in detail.

As shown in FIG. 23, the first die pad 30 of the fourth embodiment differs from that of the first embodiment in the first distal curved surface 35A and the second distal curved surface 35B. More specifically, in plan view, each of the first distal curved surface 35A and the second distal curved surface 35B is greater in arc length than the basal curved surface 36. In other words, in plan view, the first distal curved surface 35A and the second distal curved surface 35B are greater in radius of curvature than the basal curved surface 36. In an example, in plan view, the arc length of each of the first distal curved surface 35A and the second distal curved surface 35B is greater than or equal to twice the arc length of the basal curved surface 36.

In the fourth embodiment, in plan view, the first distal curved surface 35A is equal in arc length to the second distal curved surface 35B. When the difference in arc length between the first distal curved surface 35A and the second distal curved surface 35B is, for example, less than or equal to 10% of the arc length of the first distal curved surface 35A, it is considered that the first distal curved surface 35A is equal in arc length to the second distal curved surface 35B. In other words, in plan view, the first distal curved surface 35A is equal in radius of curvature to the second distal curved surface 35B.

The second die pad 50A of the fourth embodiment differs from that of the first embodiment in the third distal curved surface 55AA. More specifically, in plan view, the third distal curved surface 55AA is greater in arc length than the basal curved surface 56A. In other words, in plan view, the third distal curved surface 55AA is greater in radius of curvature than the basal curved surface 56A. In plan view, the third distal curved surface 55AA is greater in arc length than the fourth distal curved surface 55AB. In other words, in plan view, the third distal curved surface 55AA is greater in radius of curvature than the fourth distal curved surface 55AB.

In an example, in plan view, the arc length of the third distal curved surface 55AA is greater than or equal to twice the arc length of the basal curved surface 56A. In an example, in plan view, the arc length of the third distal curved surface 55AA is greater than or equal to twice the arc length of the fourth distal curved surface 55AB.

The third die pad 50B of the fourth embodiment differs from that of the first embodiment in the sixth distal curved surface 55BB. More specifically, in plan view, the sixth distal curved surface 55BB is greater in arc length than the basal curved surface 56BA. In other words, in plan view, the sixth distal curved surface 55BB is greater in radius of curvature than the basal curved surface 56BA. In plan view, the sixth distal curved surface 55BB is greater in arc length than the basal curved surface 56BB. In other words, in plan view, the sixth distal curved surface 55BB is greater in radius of curvature than the basal curved surface 56BB. In plan view, the sixth distal curved surface 55BB is greater in arc length than the fifth distal curved surface 55BA. In other words, in plan view, the sixth distal curved surface 55BB is greater in radius of curvature than the fifth distal curved surface 55BA.

In an example, in plan view, the arc length of the sixth distal curved surface 55BB is greater than or equal to twice the arc length of the basal curved surface 56BA. In an example, the arc length of the sixth distal curved surface 55BB is greater than or equal to twice the arc length of the fifth distal curved surface 55BA.

In the fourth embodiment, in plan view, the sixth distal curved surface 55BB of the third die pad 50B is equal in arc length to the third distal curved surface 55AA of the second die pad 50A. When the difference in arc length between the sixth distal curved surface 55BB and the third distal curved surface 55AA is, for example, less than or equal to 10% of the arc length of the sixth distal curved surface 55BB, it is considered that the sixth distal curved surface 55BB is equal in arc length to the third distal curved surface 55AA. In other words, in plan view, the sixth distal curved surface 55BB is equal in radius of curvature to the third distal curved surface 55AA.

As shown in FIG. 23, the first distal curved surface 35A of the first die pad 30 is opposed to the third distal curved surface 55AA of the second die pad 50A in the X-direction. The second distal curved surface 35B of the first die pad 30 is opposed to the sixth distal curved surface 55BB of the third die pad 50B in the X-direction.

### Advantages

The signal transmission device 10 of the fourth embodiment obtains the following advantages.

(4-1) The first die pad 30 includes the first distal curved surface 35A formed between the first distal surface 31 and the first side surface 33, the second distal curved surface 35B formed between the first distal surface 31 and the second side surface 34, and the basal curved surface 36 formed between the first basal surface 32 and the first side surface 33. In plan view, each of the first distal curved surface 35A and the second distal curved surface 35B is greater in arc length than the basal curved surface 36.

With this structure, the first distal curved surface 35A mitigates electric field concentration on the corner of the distal end of the first die pad 30 located in the vicinity of the second die pad 50A. Also, the second distal curved surface 35B mitigates electric field concentration on the corner of the distal end of the first die pad 30 located in the vicinity of the third die pad 50B. This limits insulation breakdown of the first die pad 30 with the second die pad 50A and the third die pad 50B, thereby improving the breakdown voltage of the signal transmission device 10.

(4-2) The second die pad 50A includes the third distal curved surface 55AA formed between the second distal surface 51A and the third side surface 53A and the basal curved surface 56A formed between the second basal surface 52A and the fourth side surface 54A. In plan view, the third distal curved surface 55AA is greater in arc length than the basal curved surface 56A.

With this structure, the third distal curved surface 55AA mitigates electric field concentration on the corner of the distal end of the second die pad 50A located in the vicinity of the first die pad 30. This limits insulation breakdown between the first die pad 30 and the second die pad 50A, thereby improving the breakdown voltage of the signal transmission device 10.

(4-3) The third die pad 50B includes the sixth distal curved surface 55BB formed between the third distal surface 51B and the sixth side surface 54B and the basal curved surface 56BB formed between the third basal surface 52B and the sixth side surface 54B. In plan view, the sixth distal curved surface 55BB is greater in arc length to the basal curved surface 56BB.

With this structure, the sixth distal curved surface 55BB mitigates electric field concentration on the corner of the distal end of the third die pad 50B located in the vicinity of the first die pad 30. This limits insulation breakdown between the first die pad 30 and the third die pad 50B, thereby improving the breakdown voltage of the signal transmission device 10.

### Fifth Embodiment

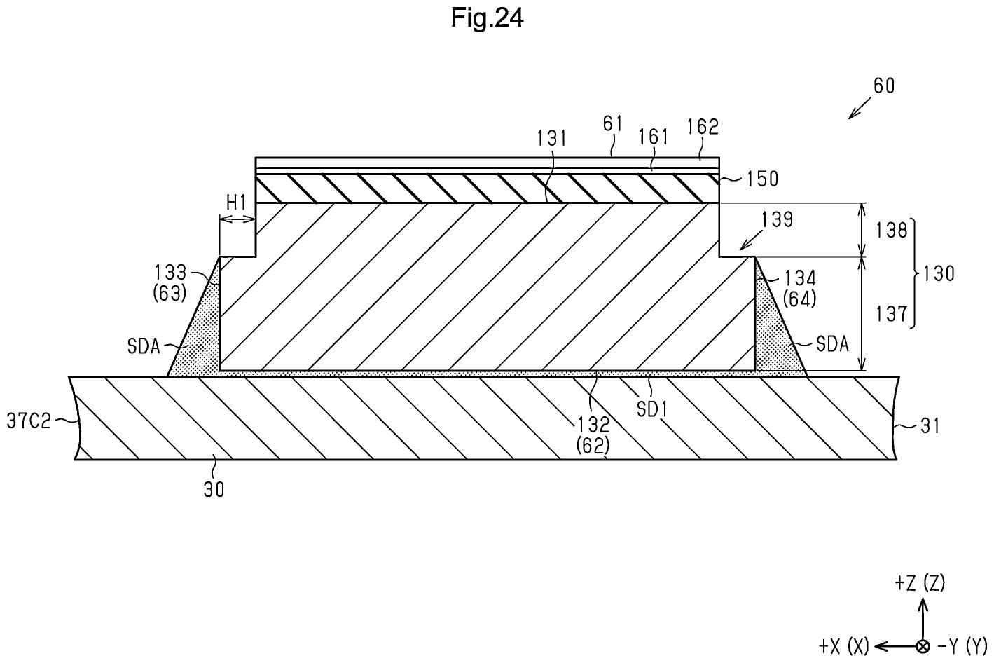

A fifth embodiment of a signal transmission device 10 will now be described with reference to FIGS. 24 to 33. The fifth embodiment of the signal transmission device 10 differs from the first embodiment of the signal transmission device 10 in the structures of the first chip 60, the second chip 70, and the third chip 80. In the following description, the differences from the first embodiment will be described in detail. The same reference characters are given to those components that are the same as the corresponding components of the first embodiment. Such components will not be described in detail.

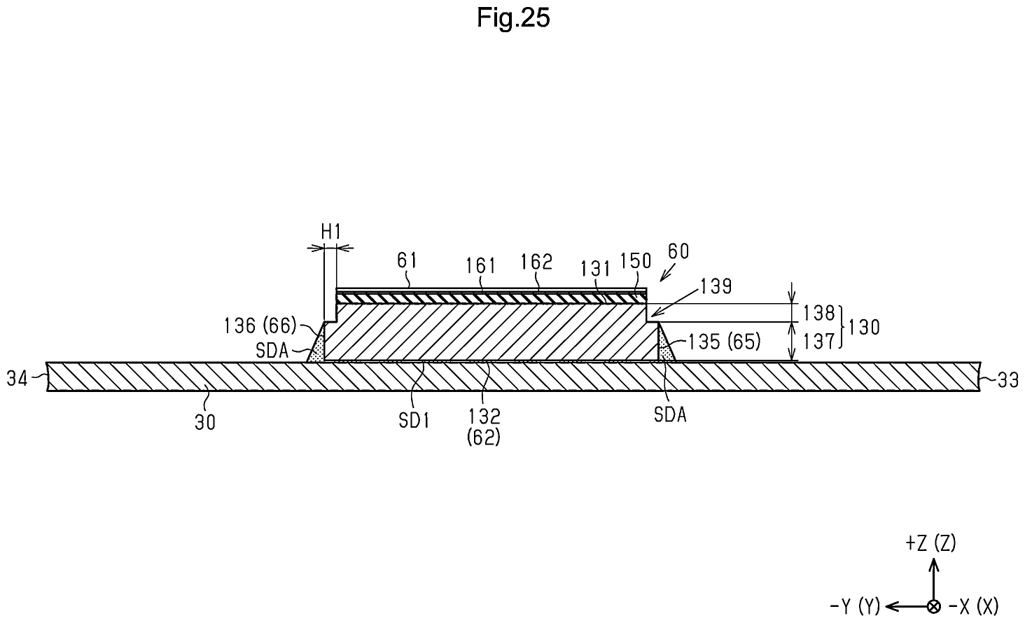

FIG. 24 is a schematic cross-sectional view of the first die pad 30 and the first chip 60 taken along an XZ-plane. FIG. 25 is a schematic cross-sectional view of the first die pad 30 and the first chip 60 taken along a YZ-plane. The wires WA to WC and the encapsulation resin 90 are not shown in the cross-sectional structures shown in FIGS. 24 and 25.

As shown in FIGS. 24 and 25, the substrate 130 of the first chip 60 includes first to fourth substrate side surfaces 133 to 136 joining the substrate front surface 131 to the substrate back surface 132. The first substrate side surface 133 defines a portion of the first chip side surface 63 of the first chip 60. The second substrate side surface 134 defines a portion of the second chip side surface 64. The third substrate side surface 135 defines a portion of the third chip side surface 65. The fourth substrate side surface 136 defines a portion of the fourth chip side surface 66.

The substrate 130 is divided into a first part 137 and a second part 138 by a step 139. The first part 137 is a part of the substrate 130 located toward the first die pad 30. The second part 138 is arranged on the first part 137. As shown in FIGS. 24 and 25, the step 139 is formed along the entire perimeter of the substrate 130.

In an example, the thickness (dimension in the Z-direction) of the first part 137 is greater than the thickness (dimension in the Z-direction) of the second part 138. In an example, the thickness of the first part 137 is greater than or equal to twice the thickness of the second part 138. In an example, the thickness of the first part 137 is greater than or equal to three times the thickness of the second part 138. In an example, the thickness of the first part 137 is less than or equal to four times the thickness of the second part 138.

As shown in FIGS. 24 and 25, the first conductive bonding material SD1 is applied between the first part 137 and the first die pad 30 in the Z-direction and includes a portion extending out of the first chip 60 in a direction orthogonal to the Z-direction. The extended portion forms a first fillet SDA between the first part 137 and the first die pad 30. The first fillet SDA is not formed on the second part 138 because of the step 139. In the example shown in FIGS. 24 and 25, the first fillet SDA is formed on the entirety of the first part 137 in the Z-direction.

The height (dimension in the Z-direction) of the first fillet SDA may be changed in any manner within a range lower than the height of the step 139. In an example, the height of the first fillet SDA may be approximately one-half of the thickness of the first part 137.

The position of the step 139 in the first chip 60 in the Z-direction may be changed in any manner. That is, the relationship of the thickness of the first part 137 and the thickness of the second part 138 may be changed in any manner. In an example, the thickness of the first part 137 may be equal to the thickness of the second part 138. In an example, the thickness of the first part 137 is less than or equal to one-half of the thickness of the second part 138. In an example, the thickness of the first part 137 is less than or equal to one-third of the thickness of the second part 138. In an example, the thickness of the first part 137 is greater than or equal to one-fourth of the thickness of the second part 138. In an example, the thickness of the first part 137 is greater than or equal to one-fourth and less than or equal to three-fourths of the thickness (dimension in the Z-direction) of the first chip 60.

The step 139 has a constant width H1 in the first to fourth substrate side surfaces 133 to 136. The width H1 of the step 139 is, for example, approximately 3 μm. The width H1 of the step 139 is defined by, for example, the distance between a portion of the first substrate side surface 133 corresponding to the first part 137 and a portion of the first substrate side surface 133 corresponding to the second part 138.

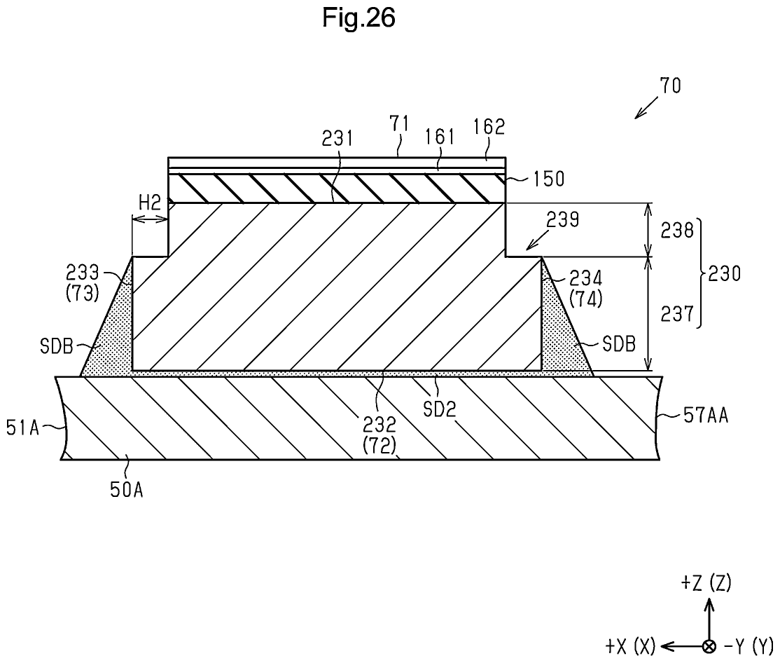

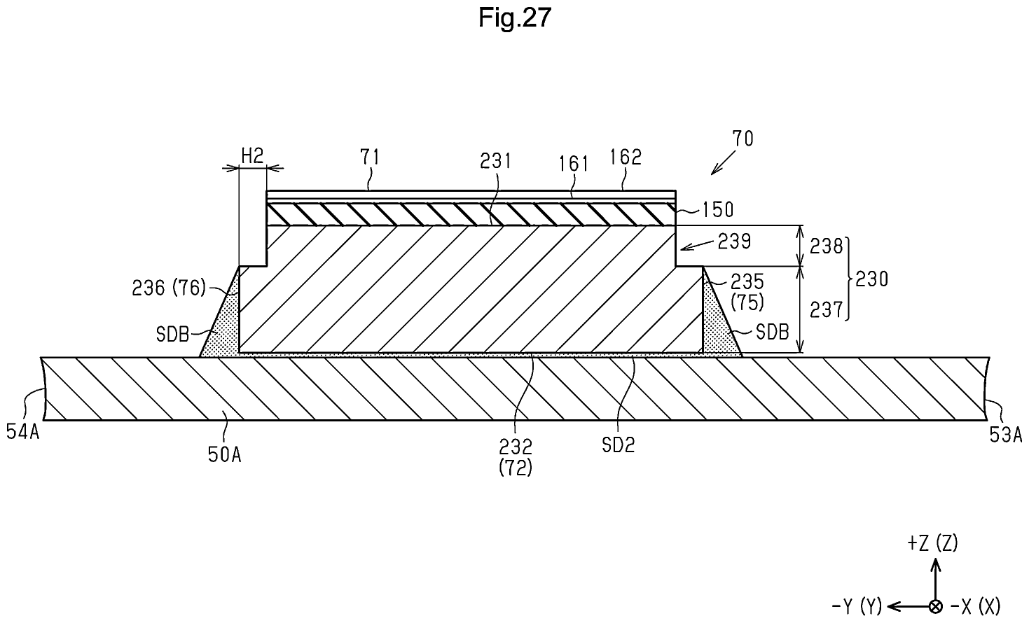

FIG. 26 is a schematic cross-sectional view of the second die pad 50A and the second chip 70 taken along an XZ-plane. FIG. 27 is a schematic cross-sectional view of the second die pad 50A and the second chip 70 taken along a YZ-plane. The wires WD and WE and the encapsulation resin 90 are not shown in the cross-sectional structures shown in FIGS. 26 and 27.

As shown in FIGS. 26 and 27, the second chip 70 is mounted on the second die pad 50A and includes a substrate 230.

The substrate 230 is formed of, for example, a semiconductor substrate. The substrate 230 is a semiconductor substrate formed from a material including silicon. As the semiconductor substrate, a wide-bandgap semiconductor or a compound semiconductor may be used for the substrate 230. The substrate 230 may be an insulating substrate that is formed from a material including glass or an insulating substrate that is formed from a material including ceramics such as alumina instead of a semiconductor substrate.

The wide-bandgap semiconductor is a semiconductor substrate having a band gap that is greater than or equal to 2.0 eV. The wide-bandgap semiconductor may be any one of silicon carbide, gallium nitride, and gallium oxide. The compound semiconductor may be a group III-V compound semiconductor. The compound semiconductor may include at least one of aluminum nitride, indium nitride, gallium nitride, and gallium arsenide.

The substrate 230 of the second chip 70 includes first to fourth substrate side surfaces 233 to 236 joining a substrate front surface 231 and a substrate back surface 232. The first substrate side surface 233 defines a portion of the first chip side surface 73 of the second chip 70. The second substrate side surface 234 defines a portion of the second chip side surface 74. The third substrate side surface 235 defines a portion of the third chip side surface 75. The fourth substrate side surface 236 defines a portion of the fourth chip side surface 76. The substrate back surface 232 defines the chip back surface 72 of the second chip 70.

The substrate 230 is divided into a first part 237 and a second part 238 by a step 239. The first part 237 is a portion of the substrate 230 located toward the second die pad 50A. The second part 238 is arranged on the first part 237. As shown in FIGS. 26 and 27, the step 239 is formed along the entire perimeter of the substrate 230.

In an example, the thickness (dimension in the Z-direction) of the first part 237 is greater than the thickness (dimension in the Z-direction) of the second part 238. In an example, the thickness of the first part 237 is greater than or equal to twice the thickness of the second part 238. In an example, the thickness of the first part 237 is greater than or equal to three times the thickness of the second part 238. In an example, the thickness of the first part 237 is less than or equal to four times the thickness of the second part 238.

As shown in FIGS. 26 and 27, the second conductive bonding material SD2 is applied between the first part 237 and the second die pad 50A in the Z-direction and includes a portion extending out of the second chip 70 in a direction orthogonal to the Z-direction. The extended portion forms a second fillet SDB between the first part 237 and the second die pad 50A. The second fillet SDB is not formed on the second part 238 because of the step 239. In the example shown in FIGS. 26 and 27, the second fillet SDB is formed on the entirety of the first part 237 in the Z-direction.

The height (dimension in the Z-direction) of the second fillet SDB may be changed in any manner within a range lower than the height of the step 239. In an example, the height of the second fillet SDB may be approximately one-half of the thickness of the first part 237.

The position of the step 239 in the second chip 70 in the Z-direction may be changed in any manner. That is, the relationship of the thickness of the first part 237 and the thickness of the second part 238 may be changed in any manner. In an example, the thickness of the first part 237 may be equal to the thickness of the second part 238. In an example, the thickness of the first part 237 is less than or equal to one-half of the thickness of the second part 238. In an example, the thickness of the first part 237 is less than or equal to one-third of the thickness of the second part 238. In an example, the thickness of the first part 237 is greater than or equal to one-fourth of the thickness of the second part 238. In an example, the thickness of the first part 237 is greater than or equal to one-fourth and less than or equal to three-fourths of the thickness (dimension in the Z-direction) of the second chip 70.

The step 239 has a constant width H2 in the first to fourth substrate side surfaces 233 to 236. The width H2 of the step 239 is, for example, approximately 3 μm. The width H2 of the step 239 is defined by, for example, the distance between a portion of the first substrate side surface 233 corresponding to the first part 237 and a portion of the first substrate side surface 233 corresponding to the second part 238.

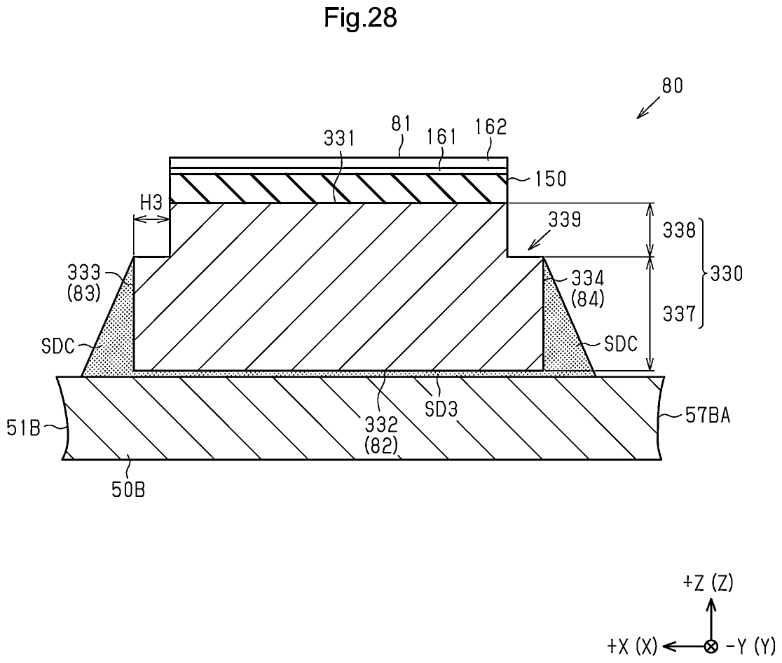

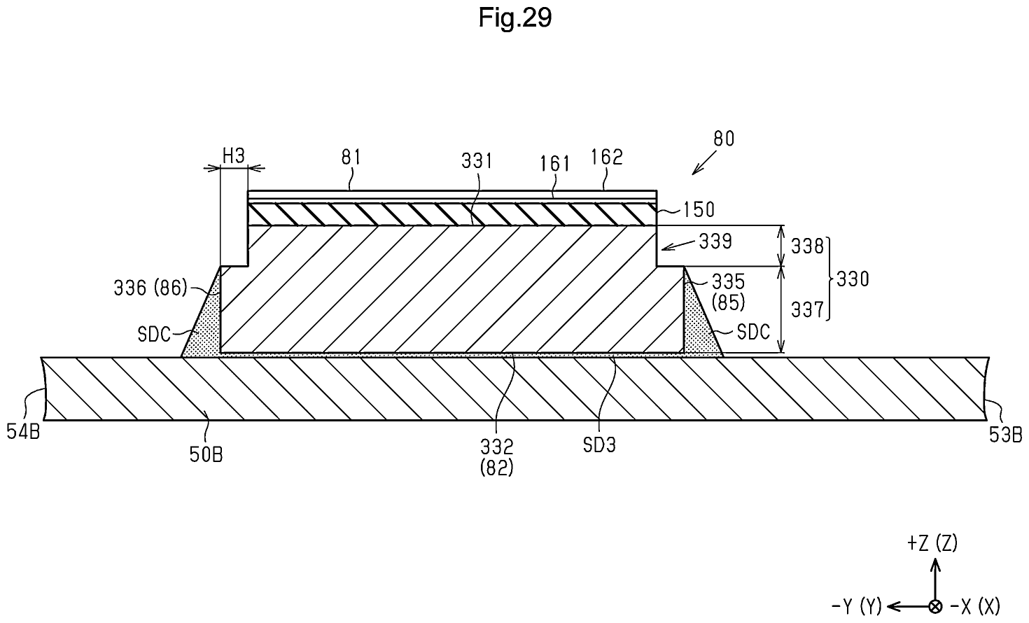

FIG. 28 is a schematic cross-sectional view of the third die pad 50B and the third chip 80 taken along an XZ-plane. FIG. 29 is a schematic cross-sectional view of the third die pad 50B and the third chip 80 taken along a YZ-plane. Thus, the wires WF and WG and the encapsulation resin 90 are not shown in the cross-sectional structures shown in FIGS. 28 and 29.

As shown in FIGS. 28 and 29, the third chip 80 is mounted on the third die pad 50B and includes a substrate 330.

The substrate 330 is formed of, for example, a semiconductor substrate. The substrate 330 is a semiconductor substrate formed from a material including silicon. As the semiconductor substrate, a wide-bandgap semiconductor or a compound semiconductor may be used for the substrate 330. The substrate 330 may be an insulating substrate that is formed from a material including glass or an insulating substrate that is formed from a material including ceramics such as alumina instead of a semiconductor substrate.

The wide-bandgap semiconductor is a semiconductor substrate having a band gap that is greater than or equal to 2.0 eV The wide-bandgap semiconductor may be any one of silicon carbide, gallium nitride, and gallium oxide. The compound semiconductor may be a group III-V compound semiconductor. The compound semiconductor may include at least one of aluminum nitride, indium nitride, gallium nitride, and gallium arsenide.

The substrate 330 of the third chip 80 includes first to fourth substrate side surfaces 333 to 336 joining a substrate front surface 331 and a substrate back surface 332. The first substrate side surface 333 defines a portion of the first chip side surface 83 of the third chip 80. The second substrate side surface 334 defines a portion of the second chip side surface 84. The third substrate side surface 335 defines a portion of the third chip side surface 85. The fourth substrate side surface 336 defines a portion of the fourth chip side surface 86. The substrate back surface 332 defines the chip back surface 82 of the third chip 80.

The substrate 330 is divided into a first part 337 and a second part 338 by a step 339. The first part 337 is a portion of the substrate 330 located toward the third die pad 50B. The second part 338 is arranged on the first part 337. As shown in FIGS. 28 and 29, the step 339 is formed along the entire perimeter of the substrate 330.

In an example, the thickness (dimension in the Z-direction) of the first part 337 is greater than the thickness (dimension in the Z-direction) of the second part 338. In an example, the thickness of the first part 337 is greater than or equal to twice the thickness of the second part 338. In an example, the thickness of the first part 337 is greater than or equal to three times the thickness of the second part 338. In an example, the thickness of the first part 337 is less than or equal to four times the thickness of the second part 338.

As shown in FIGS. 28 and 29, the third conductive bonding material SD3 is applied between the first part 337 and the third die pad 50B in the Z-direction and includes a portion extending out of the third chip 80 in a direction orthogonal to the Z-direction. The extended portion forms a third fillet SDC between the first part 337 and the third die pad 50B. The third fillet SDC is not formed on the second part 338 because of the step 339. In the example shown in FIGS. 28 and 29, the third fillet SDC is formed on the entirety of the first part 337 in the Z-direction.

The height (dimension in the Z-direction) of the third fillet SDC may be changed in any manner within a range lower than the height of the step 339. In an example, the height of the third fillet SDC may be approximately one-half of the thickness of the first part 337.

The position of the step 339 in the third chip 80 in the Z-direction may be changed in any manner. That is, the relationship of the thickness of the first part 337 and the thickness of the second part 338 may be changed in any manner. In an example, the thickness of the first part 337 may be equal to the thickness of the second part 338. In an example, the thickness of the first part 337 is less than or equal to one-half of the thickness of the second part 338. In an example, the thickness of the first part 337 is less than or equal to one-third of the thickness of the second part 338. In an example, the thickness of the first part 337 is greater than or equal to one-fourth of the thickness of the second part 338. In an example, the thickness of the first part 337 is greater than or equal to one-fourth and less than or equal to three-fourths of the thickness (dimension in the Z-direction) of the third chip 80.

The step 339 has a constant width H3 in the first to fourth substrate side surfaces 333 to 336. The width H3 of the step 339 is, for example, approximately 3 μm. The width H3 of the step 339 is defined by, for example, the distance between a portion of the first substrate side surface 333 corresponding to the first part 337 and a portion of the first substrate side surface 333 corresponding to the second part 338.

As described above, the positions of the steps 139, 239, and 339 in the Z-direction are separately determined in the first chip 60, the second chip 70, and the third chip 80. Hence, the distance between the first die pad 30 and the step 139 in the Z-direction, the distance between the second die pad 50A and the step 239 in the Z-direction, and the distance between the third die pad 50B and the step 339 in the Z-direction may differ from each other.

The ratio of the thickness of the second part 138 to the thickness of the first part 137 of the first chip 60, the ratio of the thickness of the second part 238 to the thickness of the first part 237 of the second chip 70, and the ratio of the thickness of the second part 338 to the thickness of the first part 337 of the third chip 80 may differ from each other. In an example, the ratio of the thickness of the second part 138 to the thickness of the first part 137 of the first chip 60 may be ⅓. The ratio of the thickness of the second part 238 to the thickness of the first part 237 of the second chip 70 and the ratio of the thickness of the second part 338 to the thickness of the first part 337 of the third chip 80 may be 1.

### Method for Manufacturing First Chip

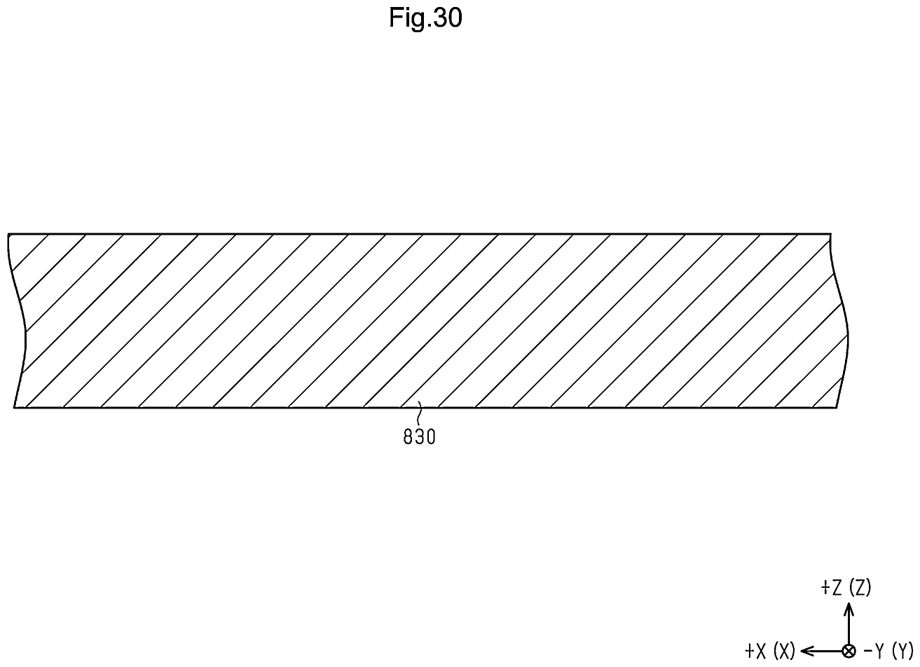

An example of steps of manufacturing the first chip 60 will now be described with reference to FIGS. 30 to 33.

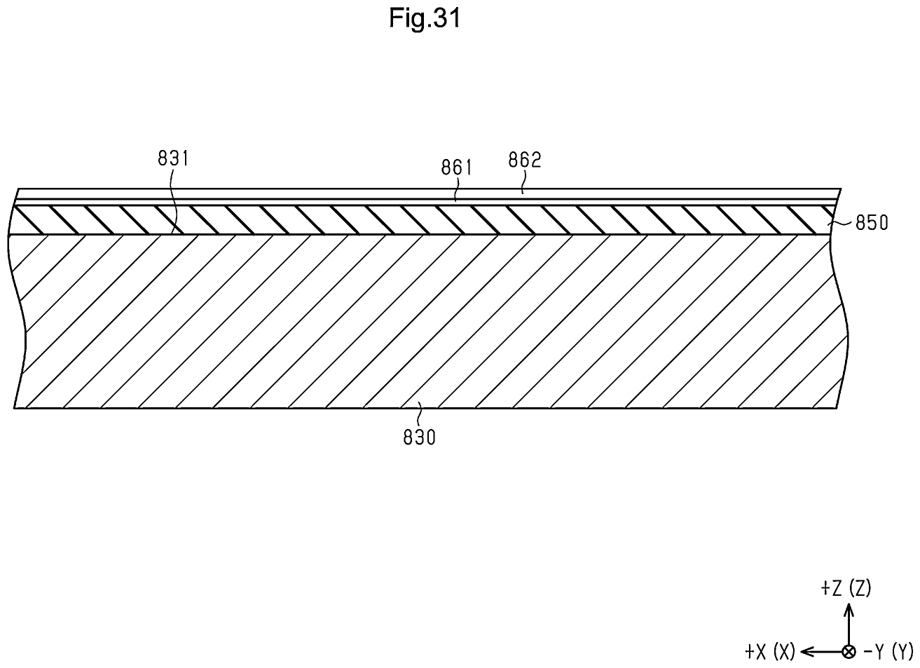

The method for manufacturing the first chip 60 includes a step of preparing a substrate 830, a step of forming an element insulation layer 850 on the substrate 830, a step of forming a passivation film 861, a step of forming a protection film 862, and a singulating step. Each step will now be described. FIGS. 30 to 33 are each a schematic view showing a cross-sectional structure of the first chip 60. In FIGS. 31 to 33, hatching lines of the passivation film 861 and the protection film 862 are not shown to facilitate understanding. The second chip 70 and the third chip 80 are manufactured in the same manner as the first chip 60. Thus, the example of steps of manufacturing the second chip 70 and the third chip 80 will not be described.

As shown in FIG. 30, in the step of preparing the substrate 830, the substrate 830 including multiple substrates 130 (refer to FIG. 24) is prepared. Referring to FIG. 9, the first transmitter 501, the second transmitter 502, the logic unit 503, the LDO unit 504, the UVLO unit 505, the delay unit 506, the Schmitt triggers 507 and 508, and the resistors 509 and 510 are formed in a region of the substrate 830 corresponding to each substrate 130.

As shown in FIG. 31, in the step of forming the element insulation layer 850 on the substrate 830, for example, chemical vapor deposition (CVD) is performed to form a SiO₂ film on a substrate front surface 831 of the substrate 830. The SiO₂ film forms the element insulation layer 850. The element insulation layer 850 has, for example, a layered structure of multiple SiO₂ films.

Although not shown, during the step of forming the element insulation layer 850 on the substrate 830, for example, sputtering and etching are performed to form the first to fourth back coils 111B to 114B. Subsequent to the step of forming the first to fourth back coils 111B to 114B, the step of forming the element insulation layer 850 on the substrate 830 is again performed.

Although not shown, after the element insulation layer 850 is formed, sputtering and etching are performed to form the first to fourth front coils 111A to 114A and the first to third electrode pads 67 to 69.

In the step of forming the passivation film 861, for example, CVD is performed to form the passivation film 861 on the element insulation layer 850. Although not shown, the passivation film 861 also covers the second to fourth front coils 112A to 114A and the first to third electrode pads 67 to 69.

In the step of forming the protection film 862, for example, CVD is performed to form the protection film 862 on the passivation film 861. The protection film 862 is formed, for example, on the entire surface of the passivation film 861.

Although not shown, for example, etching is performed to form openings in the protection film 862 and the passivation film 861 at positions overlapping a portion of each of the first to third electrode pads 67 to 69. As a result, the first to third electrode pads 67 to 69 are partially exposed from the protection film 862 and the passivation film 861 in the Z-direction.

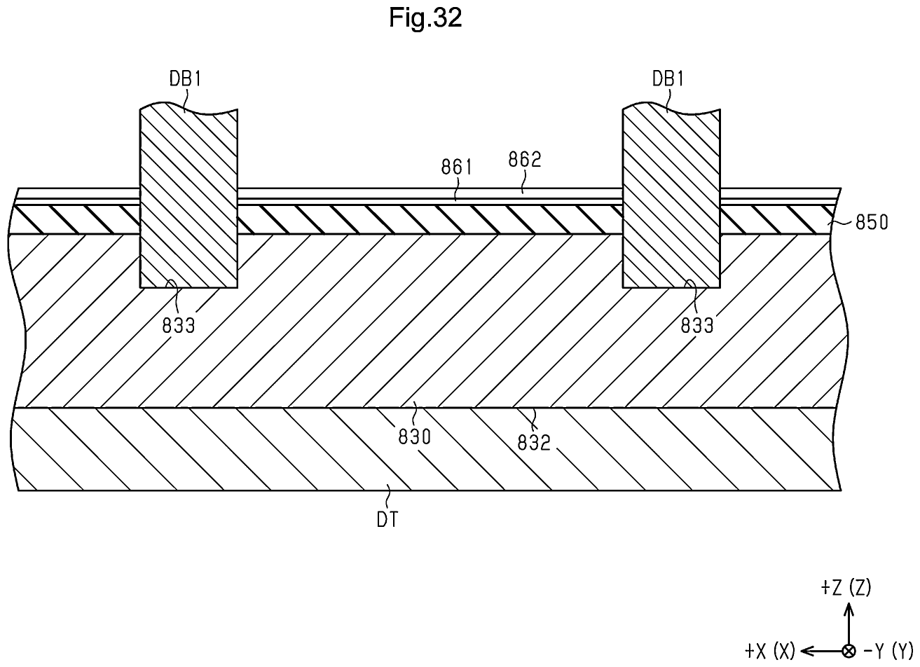

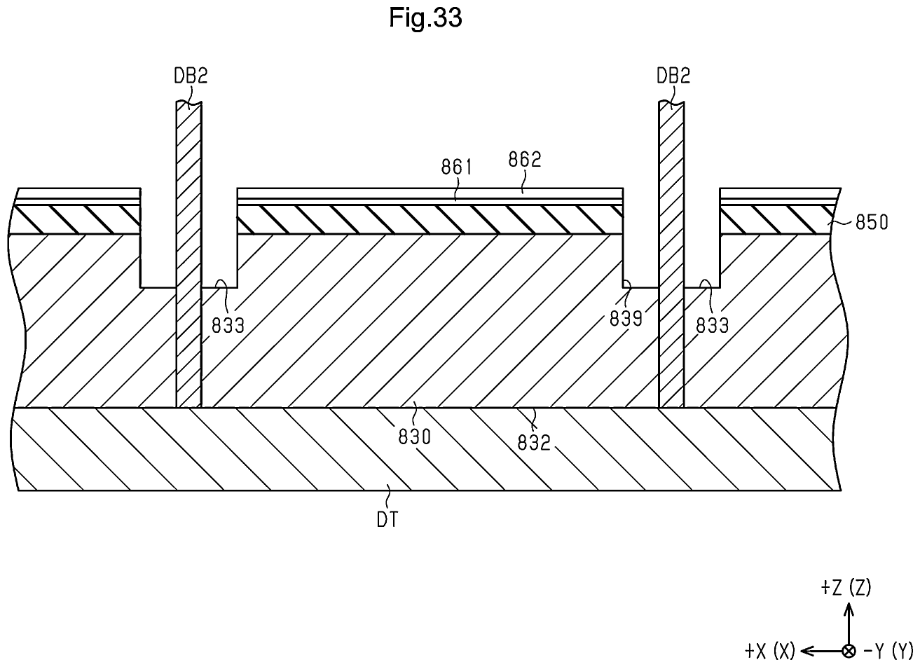

As shown in FIGS. 32 and 33, the singulating step includes a first dicing step and a second dicing step.

As shown in FIG. 32, in the first dicing step, the substrate 830 is set on dicing tape DT. The substrate back surface 832 of the substrate 830 is in contact with the dicing tape DT. A first dicing blade DB1 is used to cut the protection film 862, the passivation film 861, and the element insulation layer 850 and partially cut away the substrate 830 in the Z-direction. As a result, recesses 833 are formed in the substrate 830.

As shown in FIG. 33, in the second dicing step, a second dicing blade DB2 is used to cut the substrate 830. The second dicing blade DB2 has a smaller width than the first dicing blade DB1. The second dicing blade DB2 cuts the substrate 830 from the recesses 833 in the substrate 830. As a result, the steps 839 are formed on the substrate 830. The dicing tape DT is removed. The steps described above manufacture the first chip 60.

### Advantages

The signal transmission device 10 of the fifth embodiment obtains the following advantages.

(5-1) The substrate 130 of the first chip 60 includes the first part 137 including the substrate back surface 132, the second part 138 arranged on the first part 137, and the step 139 formed so that the second part 138 is located at an inner side of the substrate 130 from the first part 137.

With this structure, when the first chip 60 is mounted on the first die pad 30 with the first conductive bonding material SD1, the step 139 hampers an upward flow of the first conductive bonding material SD1 to the chip front surface 61 of the first chip 60.

(5-2) The substrate 230 of the second chip 70 includes the first part 237 including the substrate back surface 232, the second part 238 arranged on the first part 237, and the step 239 formed so that the second part 238 is located at an inner side of the substrate 230 from the first part 237.

With this structure, when the second chip 70 is mounted on the second die pad 50A with the second conductive bonding material SD2, the step 239 hampers an upward flow of the second conductive bonding material SD2 to the chip front surface 71 of the second chip 70.

(5-3) The substrate 330 of the third chip 80 includes the first part 337 including the substrate back surface 332, the second part 338 arranged on the first part 337, and the step 339 formed so that the second part 338 is located at an inner side of the substrate 330 from the first part 337.

With this structure, when the third chip 80 is mounted on the third die pad 50B by the third conductive bonding material SD3, the step 339 hampers an upward flow of the third conductive bonding material SD3 to the chip front surface 81 of the third chip 80.

### Sixth Embodiment

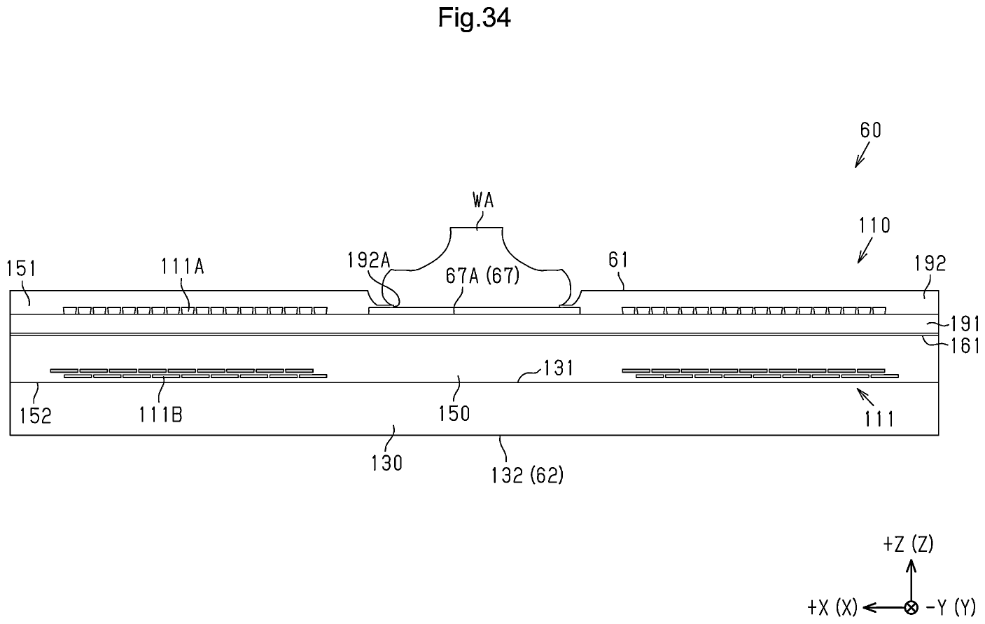

A sixth embodiment of a signal transmission device 10 will now be described with reference to FIGS. 34 to 38. The signal transmission device 10 of the sixth embodiment differs from the signal transmission device 10 of the first embodiment in the structure of the first chip 60. The differences in the structure of the first chip 60 from the first embodiment will be described in detail. The same reference characters are given to those components that are the same as the corresponding components of the first embodiment. Such components will not be described in detail.

As shown in FIG. 34, while the passivation film 161 is formed on the layer front surface 151 of the element insulation layer 150, the first electrode pads 67 are not formed on the layer front surface 151. That is, the passivation film 161 is in contact with the layer front surface 151. The first electrode pads 67 are separated from the layer front surface 151 in the Z-direction. The passivation film 161 is formed on the entirety of the layer front surface 151 of the element insulation layer 150.

The first chip 60 further includes a first organic insulation layer 191 formed on the passivation film 161 and a second organic insulation layer 192 formed on the first organic insulation layer 191. The first organic insulation layer 191 corresponds to a “first resin layer.” The second organic insulation layer 192 corresponds to a “second resin layer.”

The first organic insulation layer 191 and the second organic insulation layer 192 are formed from an insulating material having a relative permittivity differing from that of the element insulation layer 150. The first organic insulation layer 191 and the second organic insulation layer 192 may include at least one of polyimide, phenol resin, and epoxy resin. The first organic insulation layer 191 and the second organic insulation layer 192 may be formed from the same resin material or different resin materials.

The first front coil 111A and the first electrode pads 67 are formed on the first organic insulation layer 191. Thus, the first front coil 111A and the first electrode pads 67 are arranged outside the element insulation layer 150. In other words, the first front coil 111A and the first electrode pads 67 are separated from the element insulation layer 150 in the Z-direction. The first front coil 111A and the first electrode pads 67 are located at the same position in the Z-direction. Although not shown, the second to fourth front coils 112A to 114A are also formed on the first organic insulation layer 191. Thus, the first to fourth front coils 111A to 114A each correspond to a “front coil.”

The first front coil 111A and the first electrode pads 67 are covered by the second organic insulation layer 192. The second organic insulation layer 192 includes openings 192A partially exposing surfaces of the first electrode pads 67 in the Z-direction. The second organic insulation layer 192 is a protection film that protects the first chip 60 and defines the chip front surface 61.

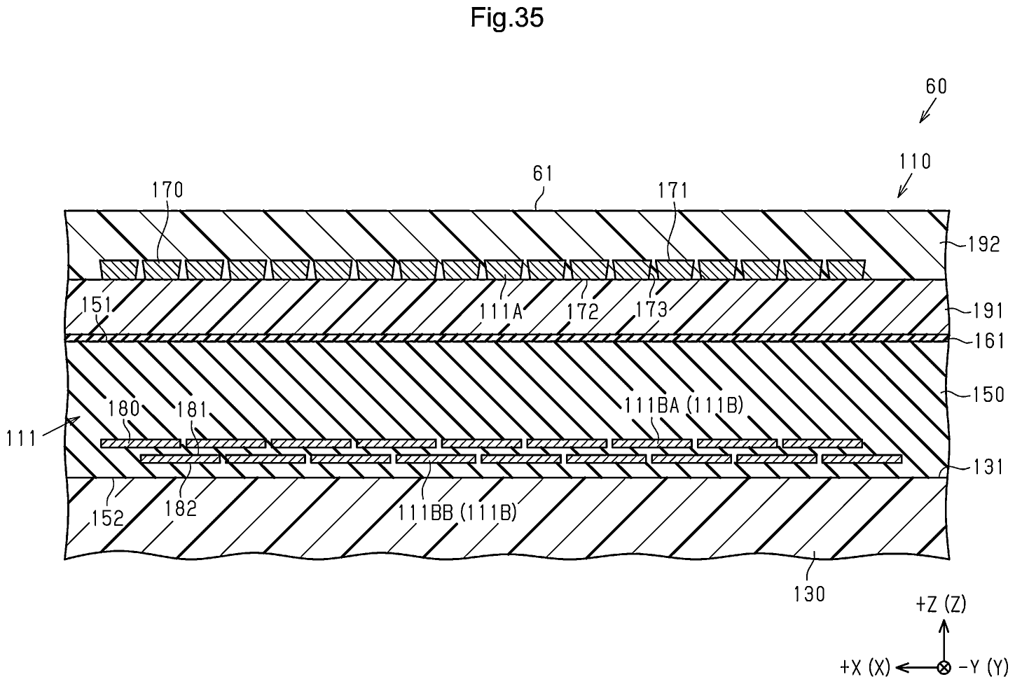

As shown in FIG. 35, the coil back surface 172 of the conductive wire 170 of the first front coil 111A is in contact with the first organic insulation layer 191. The first front coil 111A is covered by the first organic insulation layer 191 and the second organic insulation layer 192. The second organic insulation layer 192 is in contact with the coil front surface 171 and the two coil side surfaces 173 of the conductive wire 170. The second organic insulation layer 192 is arranged between portions of the conductive wire 170 in the first front coil 111A located adjacent to each other in the Y-direction.

The second organic insulation layer 192 is smaller in thickness than the element insulation layer 150. The thickness of the second organic insulation layer 192 is less than the distance in the Z-direction between the layer front surface 151 of the element insulation layer 150 and the coil front surface 181 of the conductive wire 180 in the coil layer 111BA of the first back coil 111B. The second organic insulation layer 192 is greater in thickness than the conductive wire 180. The second organic insulation layer 192 is greater in thickness than the conductive wire 170. The thickness of the second organic insulation layer 192 is greater than the thickness of the first electrode pad 67A (dimension of the first electrode pad 67A in the Z-direction).

In the same manner as the first embodiment, the first back coil 111B is embedded in the element insulation layer 150. The first back coil 111B is located toward the layer back surface 152 of the element insulation layer 150. Although not shown, the second to fourth back coils 112B to 114B are also embedded in the element insulation layer 150. The first to fourth back coils 111B to 114B each correspond to a “back coil.”

As described above, the element insulation layer 150 and the first organic insulation layer 191 are arranged between the first front coil 111A and the first back coil 111B in the Z-direction. That is, an inorganic insulation layer and an organic insulation layer are arranged between the first front coil 111A and the first back coil 111B in the Z-direction. In the example shown in FIG. 35, three different layers, namely, the element insulation layer 150, the passivation film 161, and the first organic insulation layer 191, are arranged between the first front coil 111A and the first back coil 111B in the Z-direction.

Although not shown, the front guard ring 115 (refer to FIG. 11) is formed on the first organic insulation layer 191. Thus, the front guard ring 115 is located at the same position as the first front coil 111A and the first electrode pads 67A in the Z-direction. In an example, the via 117 has a layered structure of a first part, a second part, and a third part. The first part extends from the back guard ring 116 (refer to FIG. 13) to the layer front surface 151 of the element insulation layer 150 in the Z-direction. The first part is in contact with the back guard ring 116. The second part extends through the passivation film 161 in the Z-direction to connect with the first part. The second part is formed on the passivation film 161 and covered by the first organic insulation layer 191. The third part extends in the Z-direction through a portion of the first organic insulation layer 191 that covers the second part. The third part is connected to the second part and the front guard ring 115.

In the example shown in FIGS. 34 and 35, the first chip 60 has a two-layer structure including the first organic insulation layer 191 and the second organic insulation layer 192. However, there is no limit to such a configuration. The first chip 60 may have a structure in which three or more organic insulation layers are stacked.

### Method for Manufacturing First Chip

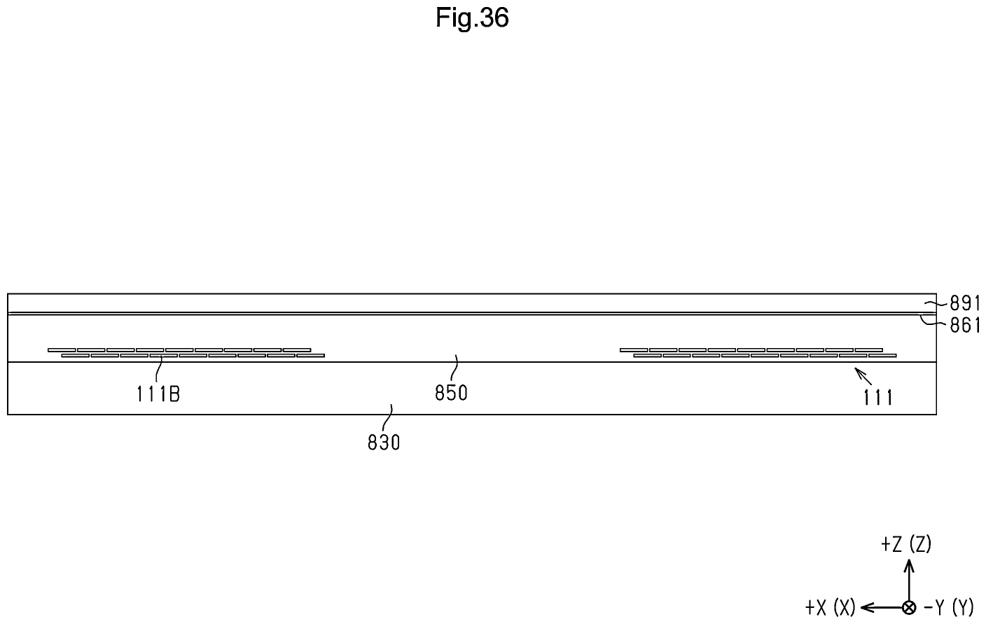

A method for manufacturing the first chip 60, particularly, a method for manufacturing the first front coil 111A, will now be described with reference to FIGS. 36 to 38. FIGS. 36 to 38 mainly show steps of forming portions of the first front coil 111A on the element insulation layer 850.

Although not shown, the method for manufacturing the first chip 60 includes a step of preparing the substrate 830, a step of forming the element insulation layer 850 on the substrate 830, a step of forming the first back coil 111B on the element insulation layer 850, and a step of forming the passivation film 861 on the element insulation layer 850. The second to fourth back coils 112B to 114B are formed at the same time in the step of forming the first back coil 111B.

The substrate 830 includes multiple substrates 130. The element insulation layer 850 is formed in a region corresponding to the multiple substrates 130. The element insulation layer 850 corresponds to the element insulation layer 150 of the first chip 60. The passivation film 861 is formed on the entirety of the layer front surface of the element insulation layer 850. The passivation film 861 corresponds to the passivation film 161 of the first chip 60.

As shown in FIG. 36, the method for manufacturing the first chip 60 includes a step of forming a first organic insulation layer 891. More specifically, for example, spin coating is performed to form the first organic insulation layer 891 on the passivation film 861. The first organic insulation layer 891 may include at least one of polyimide, phenol resin, and epoxy resin. The first organic insulation layer 891 corresponds to the first organic insulation layer 191 of the first chip 60.

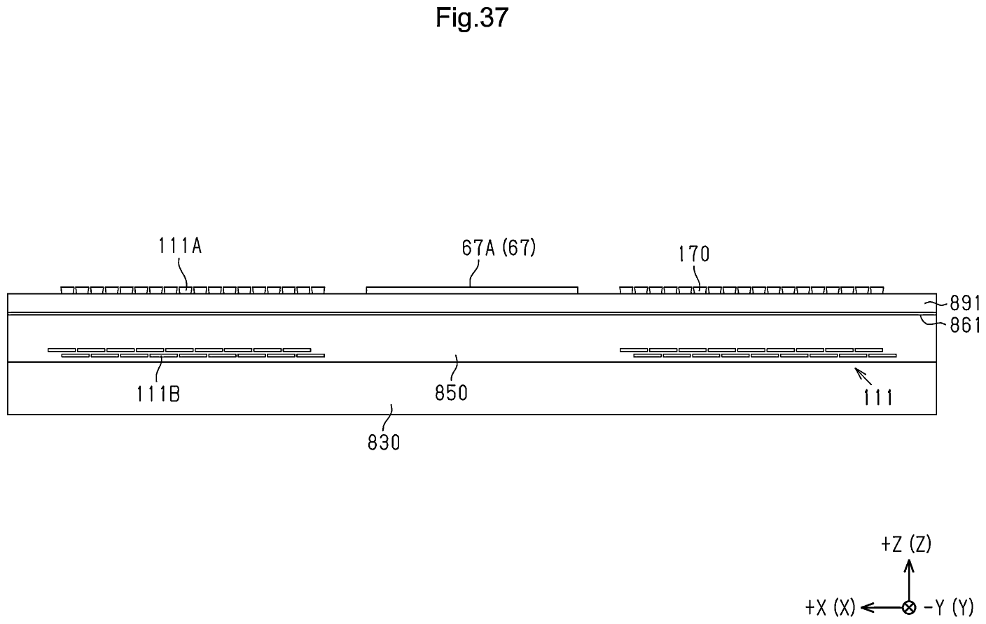

As shown in FIG. 37, the method for manufacturing the first chip 60 includes a step of forming the first front coil 111A and the first electrode pad 67A. More specifically, for example, sputtering is performed to form a barrier layer (not shown), which includes the first front coil 111A and the first electrode pad 67A, on the first organic insulation layer 191. The barrier layer is a base conductive layer for the plating growth of the conductive wire 170 and the first electrode pad 67. The barrier layer may include, for example, at least one of titanium, titanium nitride, tantalum, and tantalum nitride. Subsequently, the barrier layer is removed by, for example, lithography or etching, from positions excluding where the conductive wire 170 and the first electrode pad 67 of the first front coil 111A are formed. Then, plating of a conductive material forming the conductive wire 170 and the first electrode pad 67 is grown on the barrier layer. The conductive material is, for example, copper. The steps described above manufacture the first front coil 111A and the first electrode pad 67. Although not shown, the second to fourth front coils 112A to 114A and the other first electrode pads 67 are manufactured at the same time in this step.

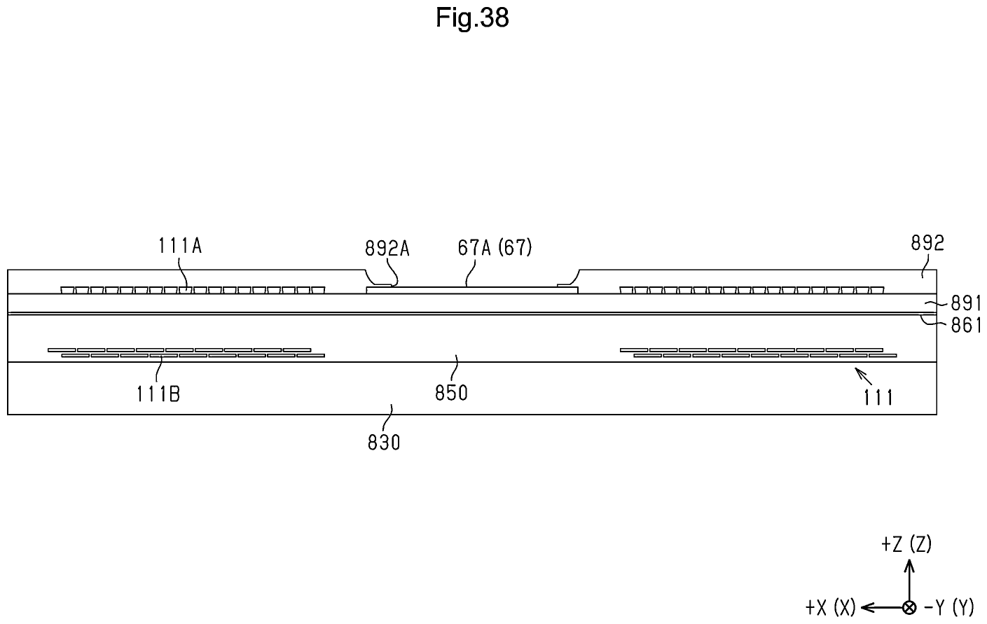

As shown in FIG. 38, the method for manufacturing the first chip 60 includes a step of forming a second organic insulation layer 892. More specifically, for example, spin coating is performed to form the second organic insulation layer 892 on the first organic insulation layer 891. The second organic insulation layer 892 covers the first front coil 111A and the first electrode pad 67. Although not shown, the second organic insulation layer 892 covers the second to fourth front coils 112A to 114A and the other first electrode pads 67. Then, lithography and etching are performed to form an opening 892A in the second organic insulation layer 892 to partially expose the first electrode pad 67A in the Z-direction. Other openings that partially expose other first electrode pads 67 in the Z-direction are formed at the same time.

The method for manufacturing the first chip 60 includes a singulating step. In the singulating step, the substrate 830, the passivation film 861, the first organic insulation layer 891, and the second organic insulation layer 892 are cut by dicing. The steps described above manufacture the first chip 60.

### Advantages

The signal transmission device 10 of the sixth embodiment obtains the following advantages.

(6-1) The first chip 60 includes the first organic insulation layer 191 arranged on the element insulation layer 150 and the second organic insulation layer 192 arranged on the first organic insulation layer 191. The first transformer 111 includes the first to fourth front coils 111A to 114A, which are arranged on the first organic insulation layer 191 and covered by the second organic insulation layer 192, and the first to fourth back coils 111B to 114B, which are opposed to the first to fourth front coils 111A to 114A in the Z-direction and embedded in the element insulation layer 150.

With this structure, the distance from the first to fourth front coils 111A to 114A to the first to fourth back coils 111B to 114B may be increased as the thickness of the first organic insulation layer 191 is increased in the Z-direction. More specifically, the breakdown voltage between the first to fourth front coils 111A to 114A and the first to fourth back coils 111B to 114B is increased as the thickness of the first organic insulation layer 191 is increased. This eliminates the need for the element insulation layer 150 to have a layered structure obtained by, for example, alternately stacking an etching stopper film formed of a silicon nitride film and an interlayer insulation film formed of a silicon oxide film in order to increase the thickness of the element insulation layer 150. Thus, the structure of the element insulation layer 150 is simplified. In addition, the thickness of the first organic insulation layer 191 may be readily increased by spin coating. This shortens the lead time as compared to when the thickness of the element insulation layer 150 is increased. Thus, the manufacturing cost is reduced.

### Seventh Embodiment

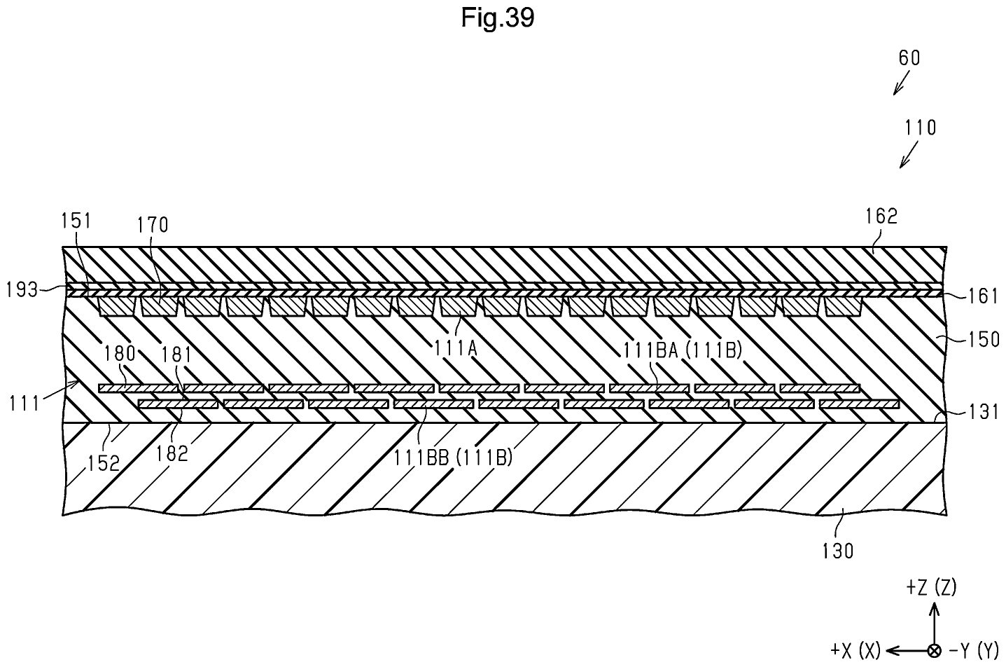

A seventh embodiment of a signal transmission device 10 will now be described with reference to FIG. 39. The signal transmission device 10 of the seventh embodiment differs from the signal transmission device 10 of the first embodiment in the structure of the first chip 60. The differences in the structure of the first chip 60 from the first embodiment will be described in detail. The same reference characters are given to those components that are the same as the corresponding components of the first embodiment. Such components will not be described in detail.

Referring to FIG. 39, in the seventh embodiment, the first chip 60 includes a low dielectric layer 193 having a lower relative permittivity than the passivation film 161. The low dielectric layer 193 is formed on the passivation film 161. In the seventh embodiment, the low dielectric layer 193 is formed on the entire surface of the passivation film 161. The low dielectric layer 193 is in contact with the front surface of the passivation film 161. In other words, the low dielectric layer 193 is arranged between the passivation film 161 and the encapsulation resin 90 in the Z-direction so that the passivation film 161 does not contact the encapsulation resin 90.

The thickness of the low dielectric layer 193 (dimension of the low dielectric layer 193 in the Z-direction) is less than or equal to the thickness of the passivation film 161. In an example, the low dielectric layer 193 is smaller in thickness than the passivation film 161. The thickness of the low dielectric layer 193 may be changed in any manner. In an example, the low dielectric layer 193 may be greater in thickness than the passivation film 161.

The protection film 162 is formed on the low dielectric layer 193. The protection film 162 is in contact with the front surface of the low dielectric layer 193. That is, the low dielectric layer 193 is sandwiched between the passivation film 161 and the protection film 162 in the Z-direction. The protection film 162 is in contact with the encapsulation resin 90. The protection film 162 is greater in thickness than the low dielectric layer 193. In other words, the low dielectric layer 193 is smaller in thickness than the protection film 162.

The relationship of the permittivity among the element insulation layer 150, the passivation film 161, the low dielectric layer 193, the protection film 162, and the encapsulation resin 90 will now be described.

In the seventh embodiment, the element insulation layer 150 is formed from a material including silicon oxide (SiO₂). Thus, the relative permittivity of the element insulation layer 150 is approximately 4.1. The passivation film 161 is formed from a material including silicon nitride (SiN). Thus, the relative permittivity of the passivation film 161 is approximately 7.0. The relative permittivity of the passivation film 161 is greater than the relative permittivity of the element insulation layer 150.

In the seventh embodiment, the protection film 162 is formed from a material including polyimide. Thus, the relative permittivity of the protection film 162 is approximately 2.9.

In the seventh embodiment, the encapsulation resin 90 is formed from a material including an epoxy resin. Thus, the relative permittivity of the encapsulation resin 90 is approximately 3.9. Thus, the relative permittivity of the encapsulation resin 90 is less than the relative permittivity of the passivation film 161. The relative permittivity of the encapsulation resin 90 is greater than the relative permittivity of the protection film 162.

The low dielectric layer 193 has a lower relative permittivity than the passivation film 161. In an example, the relative permittivity of the low dielectric layer 193 is less than or equal to that of the element insulation layer 150. More specifically, the relative permittivity of the low dielectric layer 193 is less than that of the element insulation layer 150. The relative permittivity of the low dielectric layer 193 may be less than or equal to that of the encapsulation resin 90.

The low dielectric layer 193 may be formed from a material including, for example, silicon oxide (SiO₂). That is, the low dielectric layer 193 and the element insulation layer 150 may be formed from the same material. The low dielectric layer 193 may have a lower relative permittivity than the element insulation layer 150. The low dielectric layer 193 may be formed from a low-K film. The low-K film is selected from, for example, a silicon oxycarbide (SiOC) film, a fluorine-added silicon oxide (SiOF) film, a porous film, and the like. When the low dielectric layer 193 is formed of a silicon oxycarbide film, the relative permittivity of the low dielectric layer 193 is greater than or equal to 2.5 and less than or equal to 3.0. When the low dielectric layer 193 is formed of a fluorine-added silicon oxide film, the relative permittivity of the low dielectric layer 193 is greater than or equal to 3.4 and less than or equal to 3.8. When the low dielectric layer 193 is formed from a porous film, the relative permittivity of the low dielectric layer 193 is less than 2.5. As described above, when a low-K film is used as the low dielectric layer 193, the relative permittivity of the low dielectric layer 193 is less than that of the element insulation layer 150 and the encapsulation resin 90.

### Advantages

The signal transmission device 10 of the seventh embodiment obtains the following advantages.

(7-1) The first chip 60 includes the element insulation layer 150, the passivation film 161 formed on the element insulation layer 150 to cover the element insulation layer 150, and the low dielectric layer 193 formed on the front surface of the passivation film 161 and having a lower relative permittivity than the passivation film 161. The encapsulation resin 90 covers the low dielectric layer 193.

In this structure, the low dielectric layer 193 is arranged between the passivation film 161 and the encapsulation resin 90 to limit contact of the passivation film 161 with the encapsulation resin 90. This limits occurrence of partial discharge caused by a void present in the interface between the encapsulation resin 90 and the passivation film 161 and ultimately limits occurrence of creepage discharge. Thus, the reliability of the first chip 60 is increased.

(7-2) The relative permittivity of the low dielectric layer 193 is less than or equal to that of the encapsulation resin 90.

This structure increases the voltage at which partial discharge starts to occur in the interface between the low dielectric layer 193 and the encapsulation resin 90, thereby limiting occurrence of partial discharge caused by a void present in the interface between the low dielectric layer 193 and the encapsulation resin 90 and ultimately limiting occurrence of creepage discharge.

(7-3) The thickness of the low dielectric layer 193 is smaller than or equal to the thickness of the passivation film 161. This structure limits increases in the size of the first chip 60 in the Z-direction. Thus, the height of the first chip 60 is decreased.

### Eighth Embodiment

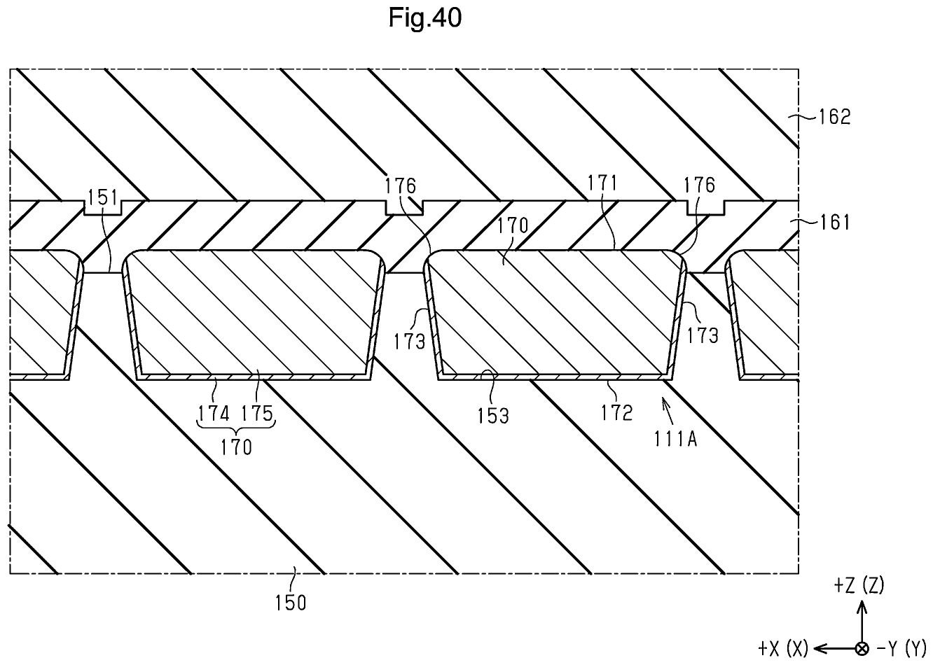

An eighth embodiment of a signal transmission device 10 will now be described with reference to FIGS. 40 to 46. The signal transmission device 10 of the eighth embodiment differs from the signal transmission device 10 of the first embodiment in the structure of the first chip 60. The differences in the structure of the first chip 60 from the first embodiment will be described in detail. The same reference characters are given to those components that are the same as the corresponding components of the first embodiment. Such components will not be described in detail.

### Structure of First Chip

FIG. 40 shows an enlarged cross-sectional structure of the first chip 60 including a portion of the first front coil 111A. In FIG. 40, hatching lines of some components of the first chip 60 are not shown to facilitate understanding.

As shown in FIG. 40, the conductive wire 170 of the first front coil 111A includes front corners 176 formed of the coil front surface 171 and the two coil side surfaces 173. The front corners 176 are round, which differs from the first embodiment. In other words, the front corners 176 each include a round surface (curved surface). In the eighth embodiment, the round surface (curved surface) is formed on the conductive wire 170 between the coil front surface 171 and each of the two coil side surfaces 173. More specifically, the round surface (curved surface) is formed of the barrier layer 174 and the metal layer 175, which form the front corner 176.

The coil front surface 171 of the conductive wire 170 is located above the layer front surface 151 of the element insulation layer 150. More specifically, the conductive wire 170 projects from the layer front surface 151 of the element insulation layer 150. The passivation film 161 covers the front corner 176 and the coil front surface 171 of the conductive wire 170. Thus, the front corner 176 is in contact with the passivation film 161 without contacting the element insulation layer 150. The two coil side surfaces 173 of the conductive wire 170 are in contact with the element insulation layer 150 at locations closer to the coil back surface 172 than the front corner 176 is.

The relationship between the conductive wire 170 and the element insulation layer 150 may be changed in any manner. In an example, the conductive wire 170 may be embedded in the element insulation layer 150. More specifically, the element insulation layer 150 may be arranged so that the front corners 176 and the coil front surface 171 of the conductive wire 170 are in contact with the element insulation layer 150. In this case, the passivation film 161 is formed on the entirety of the layer front surface 151 of the element insulation layer 150.

Although not shown, in the second to fourth front coil 112A to 114A, the conductive wire 170 also includes the front corners 176, which are round and are formed of the coil front surface 171 and the two coil side surfaces 173. The structure of the first to fourth front coils 111A to 114A may be changed in any manner. More specifically, in the eighth embodiment, at least one of the front corners 176 of the first to fourth front coils 111A to 114A may be round.

### Method for Manufacturing First Chip

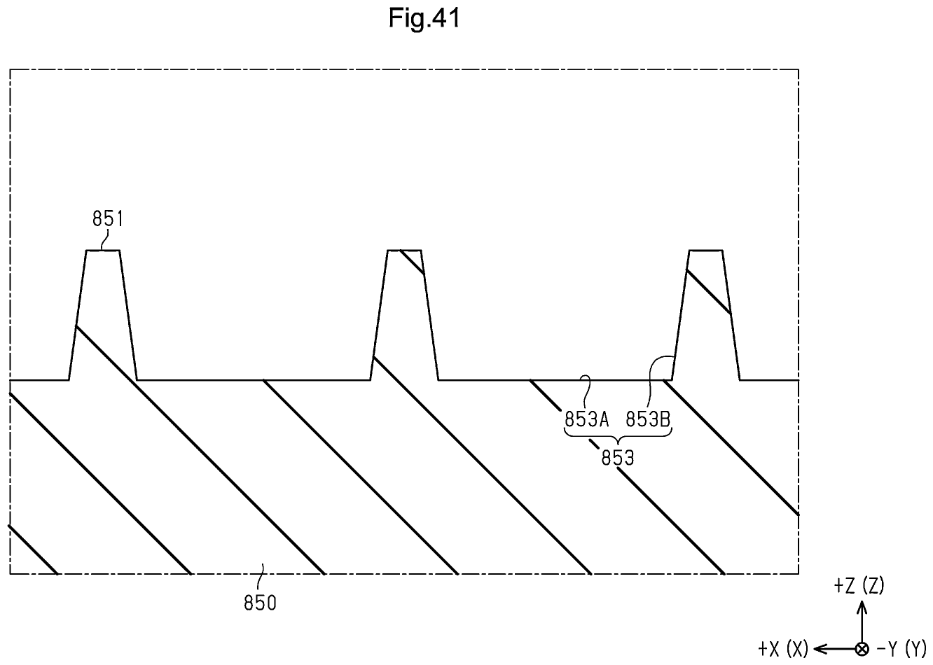

A method for manufacturing the first chip 60, particularly, a method for manufacturing the first front coil 111A, will now be described with reference to FIGS. 41 to 46. FIGS. 41 to 46 mainly show steps of forming portions of the first front coil 111A on the element insulation layer 850.

Although not shown, the method for manufacturing the first chip 60 includes a step of preparing the substrate 830, a step of forming the element insulation layer 850 on the substrate 830 (for example, refer to FIG. 30), and a step of forming the first back coil 111B (refer to FIG. 35) on the element insulation layer 850. The second to fourth back coils 112B to 114B are formed at the same time in the step of forming the first back coil 111B.

As shown in FIG. 41, the method for manufacturing the first chip 60 includes a step of forming recesses 853 in the element insulation layer 850. More specifically, in this step, the recesses 853 are formed by selectively etching a layer front surface 851 of the element insulation layer 850. The recesses 853 each include a bottom surface 853A and two side surfaces 853B joining the bottom surface 853A and the layer front surface 851. The two side surfaces 853B are tapered so as to approach each other in the Y-direction from the layer front surface 851 toward the bottom surface 853A.

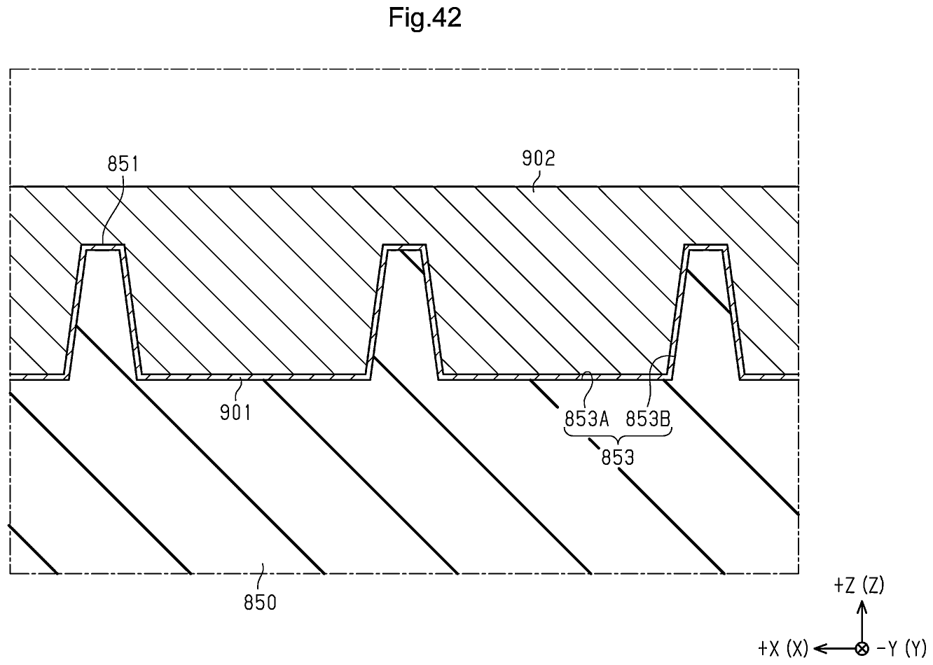

As shown in FIG. 42, the method for manufacturing the first chip 60 includes a step of forming a barrier layer 901. More specifically, for example, sputtering is performed to form the barrier layer 901 on the layer front surface 851 of the element insulation layer 850 and the two side surfaces 853B and the bottom surface 853A of the recess 853. The barrier layer 901 may include tantalum or tantalum nitride. In an example, the barrier layer 901 is formed of a layered structure (Ta/TaN/Ta) of a first layer including tantalum, a second layer arranged on the first layer and including tantalum nitride, and a third layer arranged on the second layer and including tantalum.

The method for manufacturing the first chip 60 includes a step of forming a metal layer 902. More specifically, plating of a conductive material forming the conductive wire 170 is grown on the barrier layer 901. In an example, copper plating is grown on the barrier layer 901. This forms the metal layer 902 in the recesses 853 and on the element insulation layer 850. In an example, the metal layer 902 is formed from a material including copper.

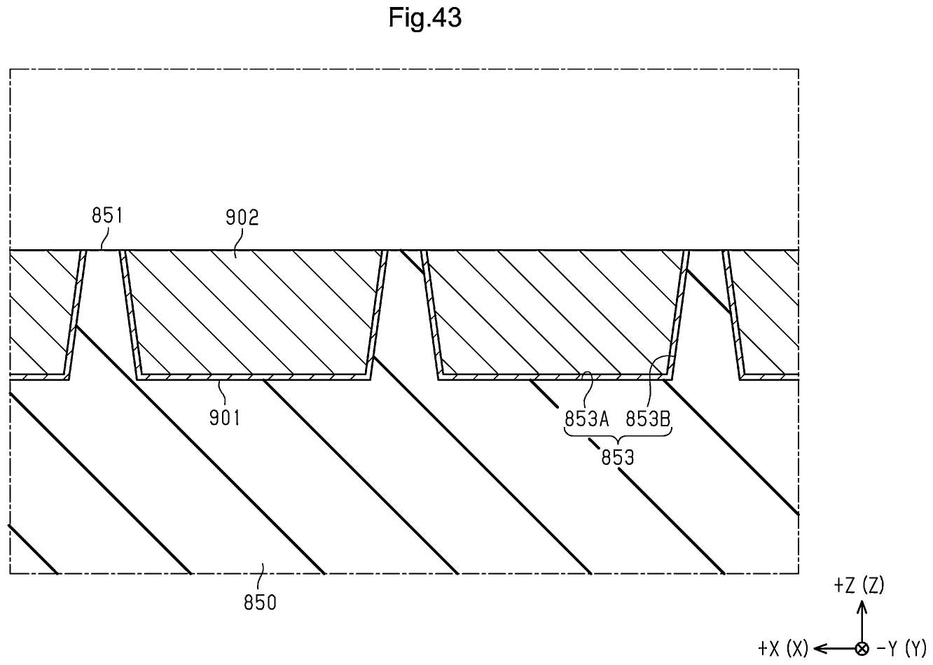

As shown in FIG. 43, the method for manufacturing the first chip 60 includes a step of removing the barrier layer 901 and the metal layer 902 from the element insulation layer 850. More specifically, the barrier layer 901 and the metal layer 902 are removed from the element insulation layer 850 by chemical mechanical polishing (CMP). As a result, the layer front surface 851 of the element insulation layer 850 is exposed.

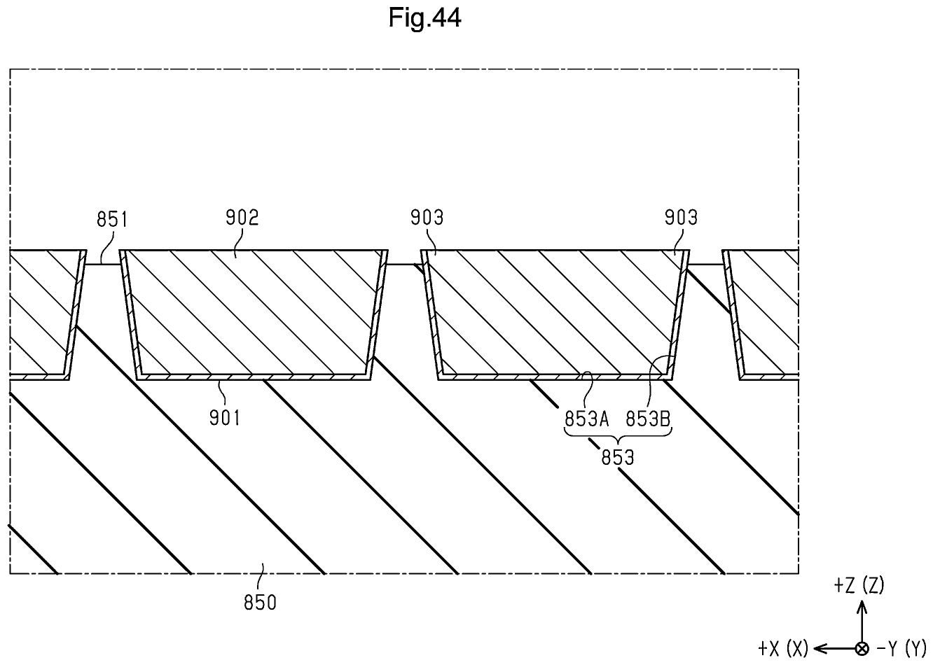

As shown in FIG. 44, the method for manufacturing the first chip 60 includes a step of removing upper end portions of the element insulation layer 850. More specifically, dry etching or wet etching is performed to entirely remove the upper end portions from the element insulation layer 850. As a result of removal of the upper end portions of the element insulation layer 850, the layer front surface 851 is located at a position lower (toward the bottom surface 853A of the recess 853) than the upper end surface of the barrier layer 901 and the upper end surface of the metal layer 902. In other words, the upper end of the barrier layer 901 and the upper end of the metal layer 902 project from the layer front surface 851.

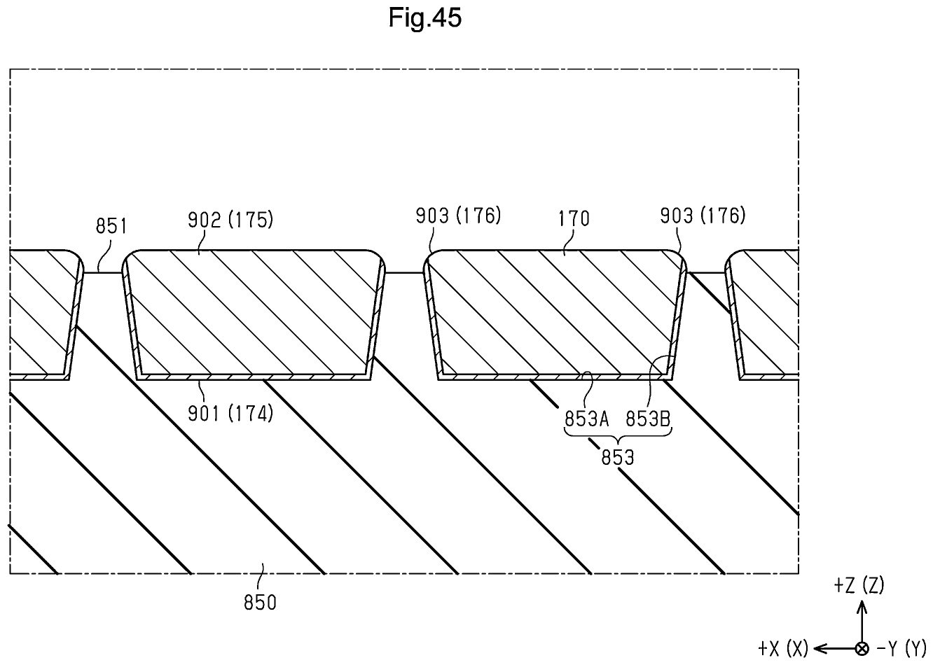

As shown in FIG. 45, the method for manufacturing the first chip 60 includes a step of forming a curved surface in two upper ends (front corners 903 in FIG. 44) of the barrier layer 901 and the metal layer 902 in the Y-direction. More specifically, a resist (not shown) is formed on the upper end surface of the metal layer 902. The resist is formed so that the front corners 903 are exposed in plan view. Subsequently, dry etching or wet etching is performed to remove the barrier layer 901 and the metal layer 902 that form the front corners 903. As a result, the front corners 903 are curved. The steps described above form the conductive wire 170. This forms the first to fourth front coils 111A to 114A. Although not shown, the first electrode pads 67 are formed simultaneously with the step of forming the conductive wire 170 shown in FIGS. 41 to 45.

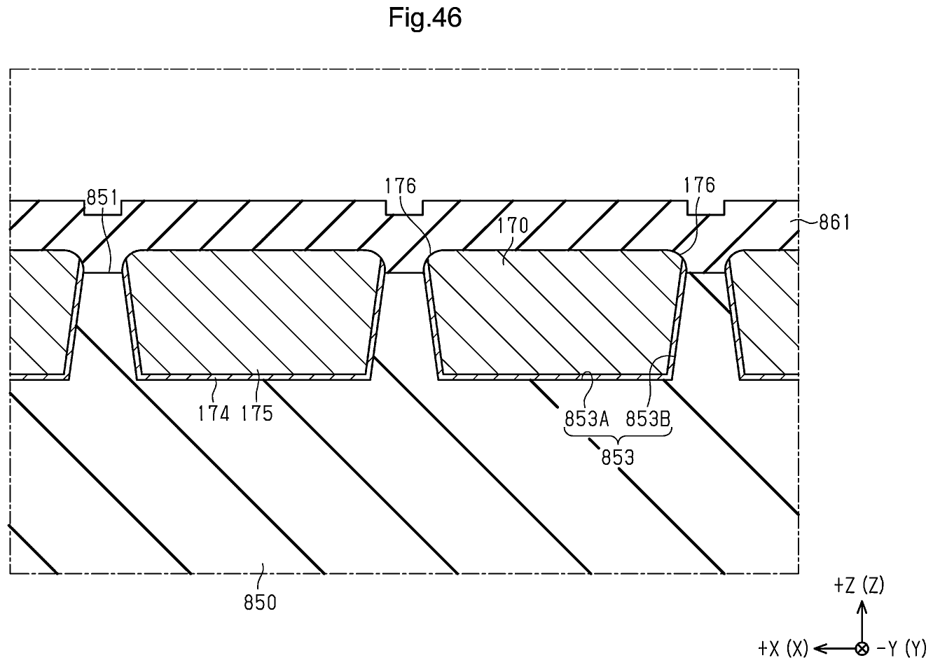

As shown in FIG. 46, the method for manufacturing the first chip 60 includes a step of forming the passivation film 861. More specifically, the passivation film 861 is formed by, for example, chemical vapor deposition (CVD) or sputtering to cover the coil front surface 171 and the front corner 176 of the conductive wire 170 and the layer front surface 851 of the element insulation layer 850. The passivation film 861 is formed from a material including, for example, silicon nitride.

Although not shown, the method for manufacturing the first chip 60 includes a step of forming the protection film 862 (refer to FIG. 31). For example, CVD or sputtering is performed to form the protection film 862 on the passivation film 861. The protection film 862 is formed from, for example, a material including silicon oxide. In addition, etching is performed to form openings in the protection film 862 and the passivation film 861 that partially expose the first electrode pads 67. Then, the protection film 862, the passivation film 861, the element insulation layer 850, and the substrate 830 are cut and singulated by dicing. The steps described above manufacture the first chip 60.

### Advantages

The signal transmission device 10 of the eighth embodiment obtains the following advantages.

(8-1) The first to fourth front coils 111A to 114A of the first transformer 111 each include the coil front surface 171, the coil back surface 172 opposite to the coil front surface 171, and the coil side surfaces 173 joining the coil front surface 171 and the coil back surface 172. The curved surface is formed between the coil front surface 171 and each coil side surface 173.

This structure mitigates electric field concentration on the front corners 176, which are formed of the coil front surface 171 and the coil side surfaces 173. This limits a situation in which insulation breakdown starts from the front corner 176, thereby improving the breakdown voltage of the first chip 60.

### Ninth Embodiment

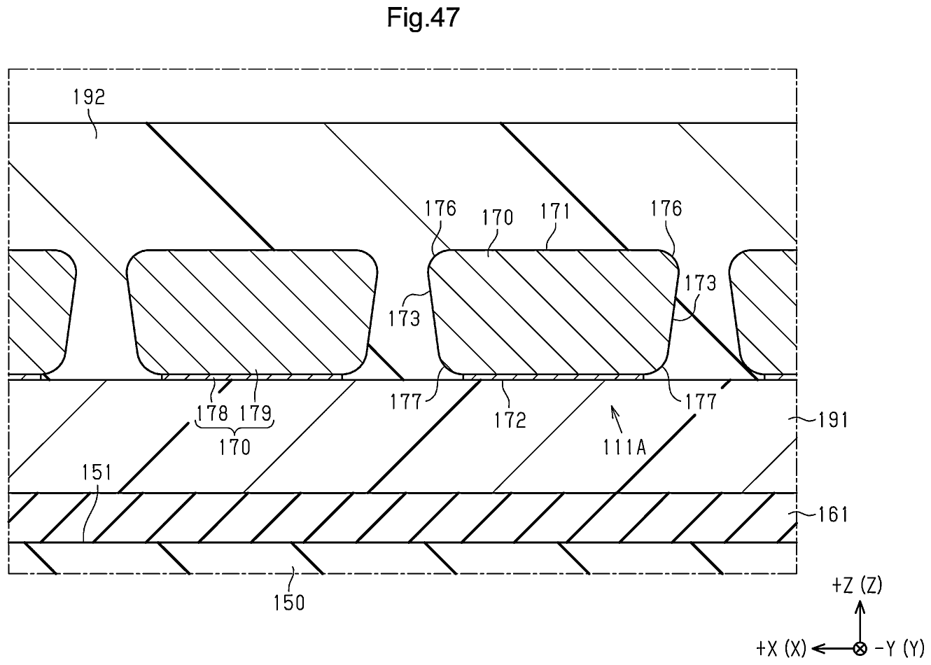

A ninth embodiment of a signal transmission device 10 will now be described with reference to FIGS. 47 to 52. The signal transmission device 10 of the ninth embodiment differs from the signal transmission device 10 of the sixth embodiment in the structure of the first chip 60. The differences in the structure of the first chip 60 from the sixth embodiment will be described in detail. The same reference characters are given to those components that are the same as the corresponding components of the sixth embodiment. Such components will not be described in detail.

### Structure of First Chip

FIG. 47 shows an enlarged cross-sectional structure of the first chip 60 including a portion of the first front coil 111A.

In the same manner as the sixth embodiment, the first chip 60 of the ninth embodiment includes a first organic insulation layer 191 formed on the layer front surface 151 of the element insulation layer 150 and a second organic insulation layer 192 formed on the first organic insulation layer 191. In the same manner as the sixth embodiment, the first front coil 111A and the first electrode pad 67A are formed on the first organic insulation layer 191.

The conductive wire 170 of the first front coil 111A includes front corners 176 formed of the coil front surface 171 and the two coil side surfaces 173. The front corners 176 are round, which differs from the first embodiment. In other words, the front corners 176 each include a round surface (curved surface). In the ninth embodiment, the round surface (curved surface) is formed on the conductive wire 170 between the coil front surface 171 and each of the two coil side surfaces 173.

The coil front surface 171 of the conductive wire 170 is located above the layer front surface 151 of the element insulation layer 150. More specifically, the conductive wire 170 projects from the layer front surface 151 of the element insulation layer 150. The passivation film 161 covers the front corner 176 and the coil front surface 171 of the conductive wire 170. Thus, the front corner 176 is in contact with the passivation film 161 without contacting the element insulation layer 150. The two coil side surfaces 173 of the conductive wire 170 are in contact with the element insulation layer 150 at locations closer to the coil back surface 172 than the front corner 176 is.

The conductive wire 170 includes back corners 177 formed of the coil back surface 172 and the two coil side surfaces 173. The back corners 177 are round, which differs from the first embodiment. In other words, the back corners 177 each include a round surface (curved surface). In the ninth embodiment, the round surface (curved surface) is formed on the conductive wire 170 between the coil back surface 172 and each of the two coil side surfaces 173.

The conductive wire 170 is covered by the second organic insulation layer 192. More specifically, the second organic insulation layer 192 is in contact with the coil front surface 171, the two coil side surfaces 173, the front corners 176, and the back corners 177 of the conductive wire 170.

The conductive wire 170 is formed of a layered structure including a seed layer 178 and a metal layer 179 formed on the seed layer 178.

The seed layer 178 defines the coil back surface 172. That is, the seed layer 178 is in contact with the first organic insulation layer 191. The seed layer 178 may include, for example, at least one of titanium, titanium nitride, and copper. In an example, the seed layer 178 is formed of a layered structure of a first layer including titanium and a second layer including copper arranged on the first layer.

Since the seed layer 178 is located between the metal layer 179 and the first organic insulation layer 191 in the Z-direction, the metal layer 179 is separated from the first organic insulation layer 191 in the Z-direction. The metal layer 179 includes the coil front surface 171, the two coil side surfaces 173, the front corner 176, and the back corner 177. The metal layer 179 is covered by the second organic insulation layer 192.

### Method for Manufacturing First Chip

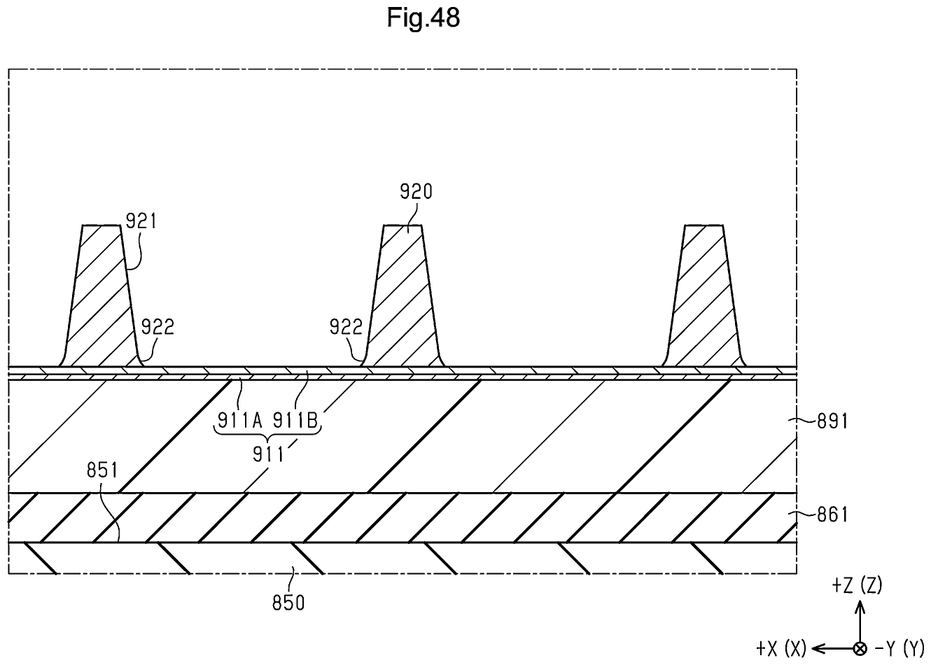

A method for manufacturing the first chip 60, particularly, a method for manufacturing the first front coil 111A, will now be described with reference to FIGS. 48 to 52.

Although not shown, the method for manufacturing the first chip 60 includes a step of preparing the substrate 830 (for example, refer to FIG. 30), a step of forming the element insulation layer 850 on the substrate 130, a step of forming the first back coil 111B (refer to FIG. 31) on the element insulation layer 850, a step of forming the passivation film 861, and a step of forming the first organic insulation layer 891. The second to fourth back coils 112B to 114B are formed at the same time in the step of forming the first back coil 111B. For example, CVD or sputtering is performed to form the passivation film 861 on the layer front surface 851 of the element insulation layer 850. For example, spin coating is performed to form the first organic insulation layer 891 on the passivation film 161.

As shown in FIG. 48, the method for manufacturing the first chip 60 includes a step of forming a seed layer 911. More specifically, for example, sputtering is performed to form the seed layer 911 on the first organic insulation layer 891. The seed layer 911 may include titanium and copper. In an example, the seed layer 911 is formed of a layered structure (Ti/Cu) of a first seed layer 911A including titanium and a second seed layer 911B including copper and arranged on the first seed layer 911A.

The method for manufacturing the first chip 60 includes a step of forming a resist 920. More specifically, the resist 920 is formed on the seed layer 911. Then, the resist 920 is selectively exposed and developed to form openings 921 that expose portions where the conductive wire 170 (refer to FIG. 47) and the first electrode pads 67 (refer to FIG. 34) will be formed.

FIG. 48 shows openings 921 for the portions for formation of the conductive wire 170. The walls of the resist 920 defining the openings 921 are tapered so as to approach each other as the seed layer 911 becomes closer. The walls of the resist 920 defining the openings 921 and contacting the seed layer 911 each include inward projections 922 that are curved inward.

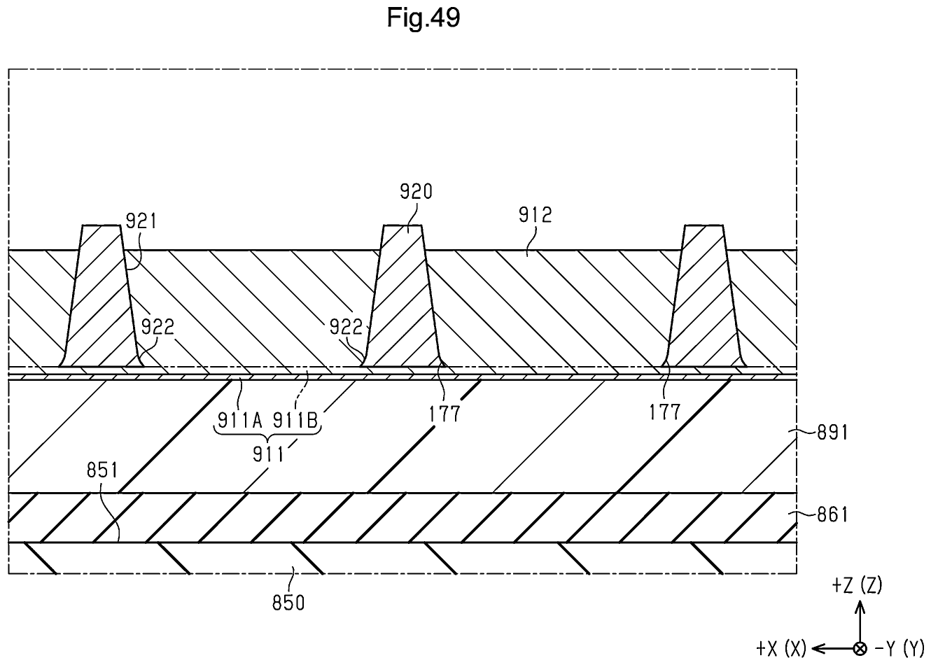

As shown in FIG. 49, the method for manufacturing the first chip 60 includes a step of forming a metal layer 912. More specifically, plating of a conductive material forming the conductive wire 170 is grown on the seed layer 911. In an example, copper plating is grown on the seed layer 911. As a result, the metal layer 912 is formed in the openings 921. The metal layer 912 is formed from a material including, for example, copper. The metal layer 912 is integrated with the second seed layer 911B. To facilitate understanding, the interface between the metal layer 912 and the second seed layer 911B is indicated by the double-dashed lines in FIG. 49. However, the interface may not be formed in an actual case. In addition, although not shown, the metal layer 912 is formed in an opening 921 where the first electrode pad 67 will be formed. Thus, the first electrode pad 67 is manufactured.

The end of the metal layer 912 located toward the seed layer 911 includes a corner having a round surface (curved surface) due to the inward projections 922 of the resist 920. That is, in this step, a round surface (curved surface) corresponding to the back corner 177 of the conductive wire 170 is formed in the metal layer 912.

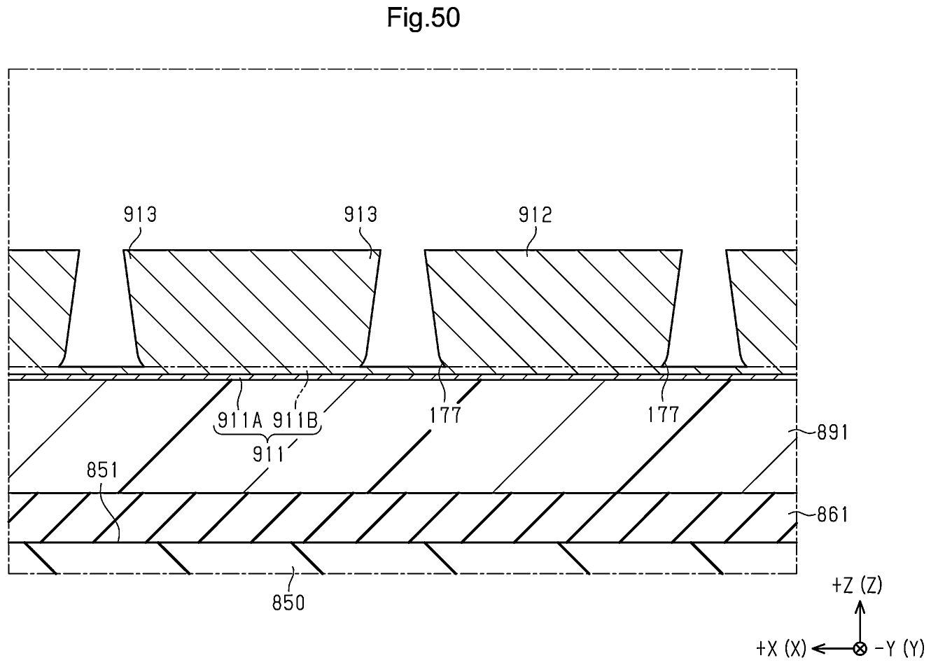

As shown in FIG. 50, the method for manufacturing the first chip 60 includes a step of removing the resist 920 (refer to FIG. 49). As a result, the seed layer 911 and the metal layer 912 are exposed.

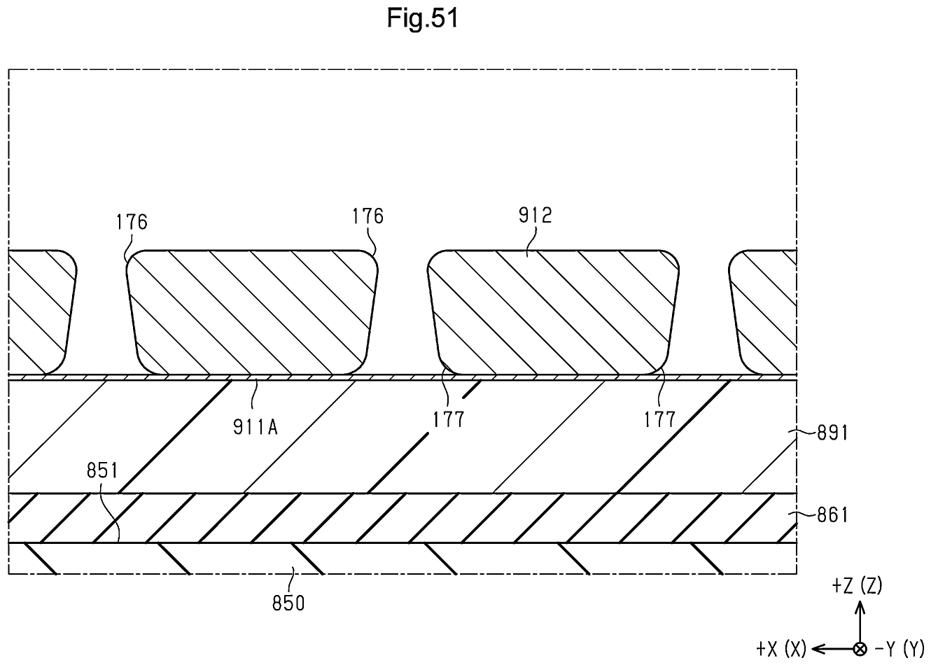

As shown in FIG. 51, the method for manufacturing the first chip 60 includes a step of etching the seed layer 911 and the metal layer 912. In an example, this step includes a step of forming a curved surface in two upper ends (front corners 913 in FIG. 50) of the metal layer 912 in the Y-direction and a step of removing the second seed layer 911B from the seed layer 911. More specifically, a resist (not shown) is formed on the upper end surface of the metal layer 912. The resist is formed so that the front corners 913 are exposed in plan view. Subsequently, dry etching or wet etching is performed to remove the metal layer 912, which forms the front corners 913. As a result, the front corners 913 have round surfaces (curved surfaces). That is, in this step, a round surface (curved surface) corresponding to the front corner 176 of the conductive wire 170 is formed in the metal layer 912. The dry etching or wet etching also removes the second seed layer 911B.

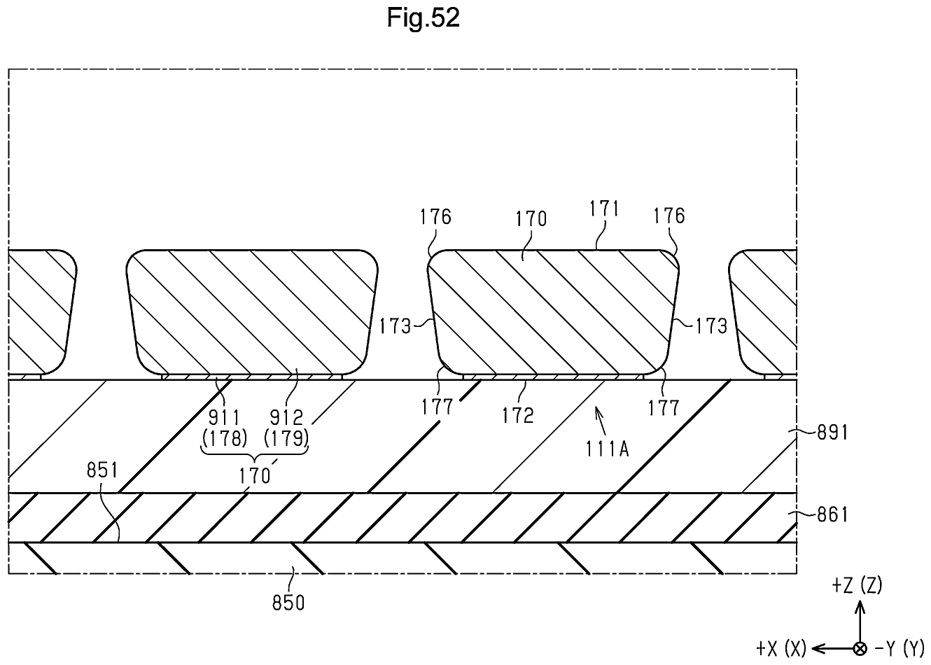

As shown in FIG. 52, the method for manufacturing the first chip 60 includes a step of removing the seed layer 911 excluding the portion where the metal layer 912 is formed. More specifically, for example, etching is performed to remove the seed layer 911 excluding the portion where the metal layer 912 is formed. The steps described above form the conductive wire 170. As a result, the first front coil 111A is formed. The second to fourth front coils 112A to 114A are also formed in the same manner.

Although not shown, the method for manufacturing the first chip 60 includes a step of forming the second organic insulation layer 192. The second organic insulation layer 192 is formed on the first organic insulation layer 191 through spin coating. The second organic insulation layer 192 covers the conductive wire 170 and the first electrode pads 67A to 67F. In addition, etching is performed to form openings in the second organic insulation layer 192 to partially expose the first electrode pads 67A to 67F. The steps described above manufacture the first chip 60.

### Advantages

The signal transmission device 10 of the ninth embodiment obtains the following advantages.

(9-1) The first to fourth front coils 111A to 114A of the first transformer 111 include the coil front surface 171, the coil back surface 172 opposite to the coil front surface 171, and the coil side surfaces 173 joining the coil front surface 171 and the coil back surface 172. The curved surface is formed between the coil front surface 171 and each coil side surface 173. The curved surface is formed between the coil back surface 172 and the coil side surface 173.

This structure mitigates electric field concentration on the front corners 176, which are formed of the coil front surface 171 and the coil side surfaces 173, and on the back corners 177, which are formed of the coil back surface 172 and the coil side surfaces 173. This limits situations in which insulation breakdown starts from the front corners 176 and the back corners 177, thereby improving the breakdown voltage of the first chip 60.

### MODIFIED EXAMPLES

The above embodiments may be modified as described below. The embodiments described above and the modified examples described below can be combined as long as the combined modifications remain technically consistent with each other.

### COMBINATIONS OF EMBODIMENTS

Examples of combinations of the first to ninth embodiments will now be described.

The signal transmission device 10 of the first embodiment may further include a configuration of at least one of the second to fifth embodiments.

The signal transmission device 10 of the first embodiment may further include a configuration of at least one of the sixth and ninth embodiments.

The signal transmission device 10 of the first embodiment may further include a configuration of at least one of the seventh and eighth embodiments.

The signal transmission device 10 of the first embodiment may include a configuration of at least one of the second to fifth embodiments and further include a configuration of at least one of the sixth and ninth embodiments.

The signal transmission device 10 of the first embodiment may include a configuration of at least one of the second to fifth embodiments and further include a configuration of at least one of the seventh and eighth embodiments.

### Modified Examples of First Die Pad and Second Die Pad

In each embodiment, one or more through holes may extend through the first die pad 30 in the thickness-wise direction (Z-direction) of the first die pad 30. Each through hole is filled with the encapsulation resin 90.

In each embodiment, one or more through holes may extend through the second die pad 50A in the thickness-wise direction (Z-direction) of the second die pad 50A. Each through hole is filled with the encapsulation resin 90.

In each embodiment, one or more through holes may extend through the third die pad 50B in the thickness-wise direction (Z-direction) of the third die pad 50B. Each through hole is filled with the encapsulation resin 90.

### Modified Examples of First Terminal, Second Terminal, and Third Terminal

In each embodiment, the regions of the first inner terminal portions 12B to 17B of the first terminals 12 to 17 that are covered by the plating layer 25 may be changed in any manner. In an example, the plating layer 25 may cover the entirety of the inner terminal front surface 21 of each of the first inner terminal portions 12B to 17B. In this case, the plating layer 25 may partially cover the distal surface 24 of each of the first inner terminal portions 12B to 17B.

In each embodiment, the regions of the second inner terminal portions 42B and 43B of the second terminals 42 and 43 that are covered by the plating layer 25 may be changed in any manner. In an example, the plating layer 25 may cover the entirety of the inner terminal front surface 21 of each of the second inner terminal portions 42B and 43B. In this case, the plating layer 25 may partially cover the distal surface 24 of each of the second inner terminal portions 42B and 43B.

In each embodiment, the regions of the third inner terminal portions 45B and 46B of the third terminals 45 and 46 that are covered by the plating layer 25 may be changed in any manner. In an example, the plating layer 25 may cover the entirety of the inner terminal front surface 21 of each of the third inner terminal portions 45B and 46B. In this case, the plating layer 25 may partially cover the distal surface 24 of each of the third inner terminal portions 45B and 46B.

In each embodiment, the distance between the second terminal 43 and the third terminal 44 in the Y-direction may be, for example, less than or equal to the distance between the second terminal 42 and the second terminal 43 in the Y-direction. The distance between the second terminal 43 and the third terminal 44 in the Y-direction may be, for example, less than or equal to the distance between the third terminal 44 and the third terminal 45 in the Y-direction. That is, the shortest distance from the second terminals 41 to 43 to the third terminals 44 to 46 may be less than or equal to the distance between two of the second terminals 41 to 43 adjacent to each other in the Y-direction (second direction). The shortest distance from the second terminals 41 to 43 to the third terminals 44 to 46 may be less than or equal to the distance between two of the third terminals 44 to 46 adjacent to each other in the Y-direction (second direction).

### Modified Examples of First Chip and Second Chip

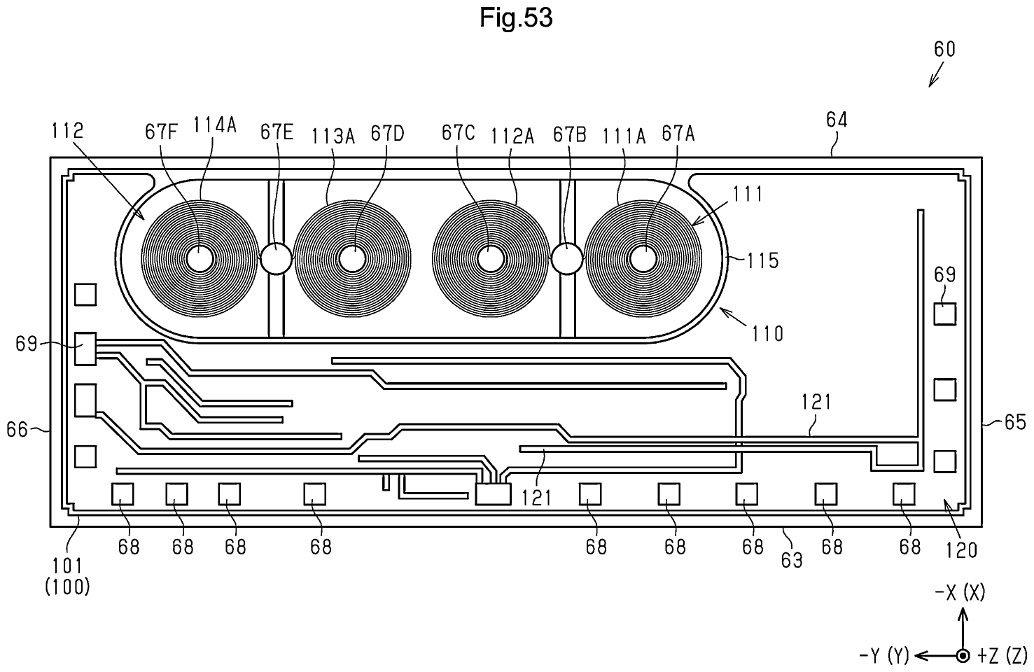

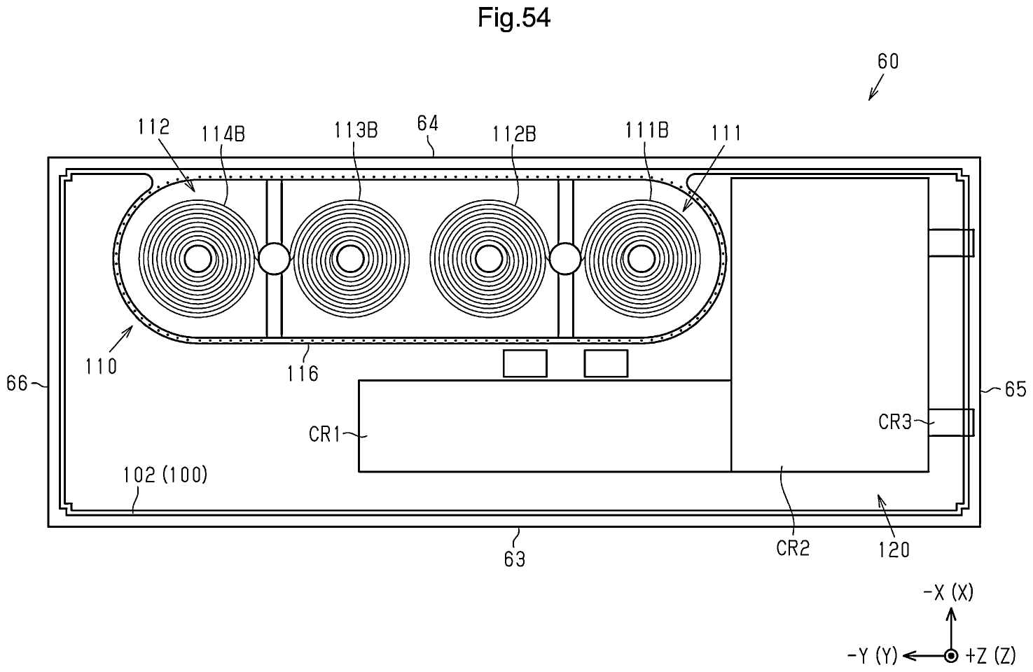

In each embodiment, the structure of the first chip 60 may be changed to that of the first chip 60 shown in FIGS. 53 and 54. In the first chip 60 shown in FIGS. 53 and 54, the ratio of the longitudinal dimension of the first chip 60 to the lateral dimension of the first chip 60 is greater than that of the first chip 60 of the first embodiment.

As shown in FIG. 53, the front peripheral guard ring 101 has the form of a loop extending around the peripheral edge of the first chip 60. In plan view, a portion of the front peripheral guard ring 101 that is adjacent to the second chip side surface 64 in the X-direction and extends in the Y-direction is connected to the front guard ring 115.

As shown in FIGS. 53 and 54, the first transformer 111 and the second transformer 112 in the isolation transformer region 110 have the same structure as the first transformer 111 and the second transformer 112 of the first embodiment.

The circuit region 120 includes multiple functional portions and multiple circuit elements of the first chip 60. The functional portions and the circuit elements are the same as the functional portions and the circuit elements of the circuit region 120 in the first embodiment. As shown in FIG. 54, the circuit region 120 includes a first circuit portion CR1, a second circuit portion CR2, and a third circuit portion CR3. The first circuit portion CR1 and the second circuit portion CR2 each include, for example, a MOSFET. In an example, the first circuit portion CR1 includes the first transmitter 501 and the second transmitter 502 shown in FIG. 9. The second circuit portion CR2 includes the logic unit 503, the UVLO unit 505, the LDO unit 504, and the delay unit 506 shown in FIG. 9. The third circuit portion CR3 includes, for example, a protection element.

In the fifth embodiment, the step 139 of the first chip 60 is not limited to a structure extending around the entire perimeter of the substrate 130 in plan view. The step 139 may be partially arranged on the first to fourth side surfaces 133 to 136 of the substrate 130.

In the fifth embodiment, the step 239 of the second chip 70 is not limited to a structure extending around the entire perimeter of the substrate 230 in plan view. The step 239 may be partially provided on the first to fourth substrate side surfaces 233 to 236 of the substrate 230.

In the fifth embodiment, the step 339 of the third chip 80 is not limited to a structure extending around the entire perimeter of the substrate 330 in plan view. The step 339 may be partially provided on the first to fourth substrate side surfaces 333 to 336 of the substrate 330.

In the fifth embodiment, one or two of the step 139 of the first chip 60, the step 239 of the second chip 70, and the step 339 of the third chip 80 may be omitted. In other words, in the sixth embodiment, at least one of the substrate 130 of the first chip 60, the substrate 230 of the second chip 70, and the substrate 330 of the third chip 80 may include a step.

In each embodiment, the first chip 60 is configured to transmit a signal to the second chip 70 and the third chip 80. However, there is no limit to such a configuration. In an example, the second chip 70 may be configured to transmit signal to the first chip 60. Alternatively, the first chip 60 may be configured to transmit signals to the second chip 70, and the second chip 70 may be configured to transmit signals to the first chip 60. In an example, the third chip 80 may be configured to transmit signal to the first chip 60. Alternatively, the first chip 60 may be configured to transmit signals to the third chip 80, and the third chip 80 may be configured to transmit signals to the first chip 60. More specifically, the second chip 70 may be configured to perform at least one of reception of a signal from the first chip 60 and transmission of a signal to the first chip 60. The third chip 80 may be configured to perform at least one of reception of a signal from the first chip 60 and transmission of a signal to the first chip 60.

### Modified Examples of Wire

In each embodiment, the arrangement of the inter-chip wire WA in plan view may be changed in any manner. In an example, in plan view, three inter-chip wires WA may be arranged so that, for example, the distance between adjacent ones of the inter-chip wires WA increases from the first chip 60 toward the second chip 70. In an example, in plan view, three inter-chip wires WA may be arranged so that, for example, the distance between adjacent ones of the inter-chip wires WA increases from the first chip 60 toward the third chip 80.

In the first embodiment, when the surface roughness Rz of each of the encapsulation front surface 91, the encapsulation back surface 92, and the first to fourth encapsulation side surfaces 93 to 96 of the encapsulation resin 90 is greater than or equal to 8 μm, the material forming the inter-chip wire WA is not limited to gold and may be changed in any manner.

In the first embodiment, when the ends of the inner terminal front surfaces 21 of the first inner terminal portions 12B to 17B of the first terminals 12 to 17 that are located toward the distal surface 24 are not covered by the plating layer 25 and are in contact with the encapsulation resin 90, the material forming the inter-chip wire WA is not limited to gold and may be changed in any manner.

In the first embodiment, when the ends of the inner terminal front surfaces 21 of the second inner terminal portions 42B and 43B of the second terminals 42 and 43 that are located toward the distal surface 24 are not covered by the plating layer 25 and are in contact with the encapsulation resin 90, the material forming the inter-chip wire WA is not limited to gold and may be changed in any manner.

In the first embodiment, when the ends of the inner terminal front surfaces 21 of the third inner terminal portions 45B and 46B of the third terminals 45 and 46 that are located toward the distal surface 24 are not covered by the plating layer 25 and are in contact with the encapsulation resin 90, the material forming the inter-chip wire WA is not limited to gold and may be changed in any manner.

In the second to ninth embodiments, the material forming the inter-chip wire WA is not limited to gold and may be changed in any manner.

In each embodiment, the first terminal wire WB is not limited to copper or aluminum and may be changed in any manner. When the first terminal wire WB is formed of a copper wire, the palladium coating on the surface of the copper wire may be omitted. The same modification may apply to the first die pad wire WC, the second terminal wire WD, the second die pad wire WE, the third terminal wire WF, and the third die pad wire WG.

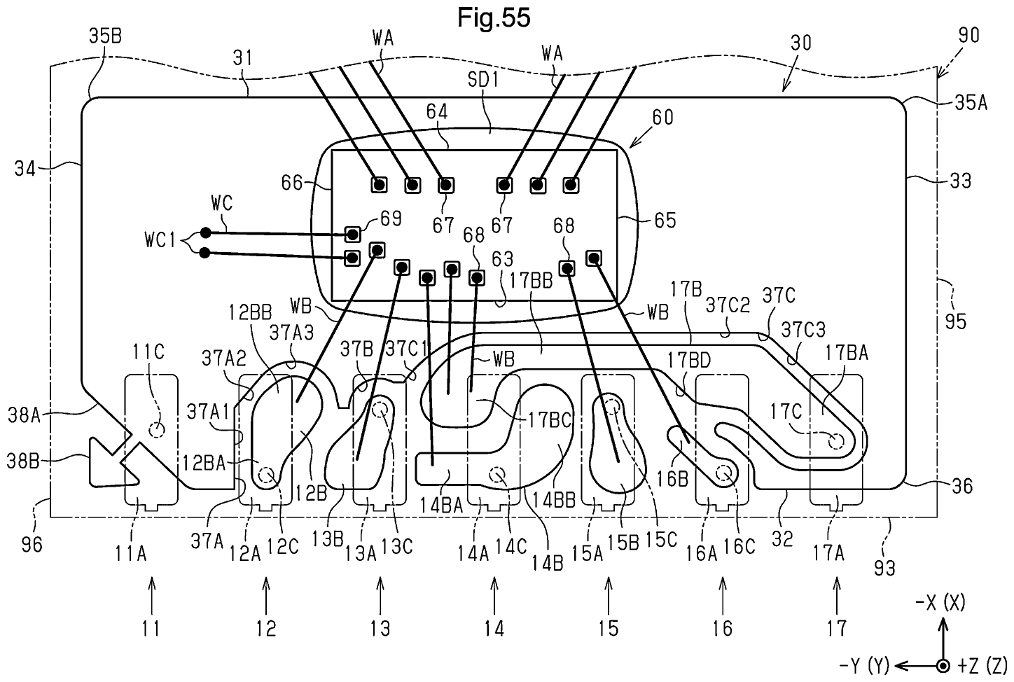

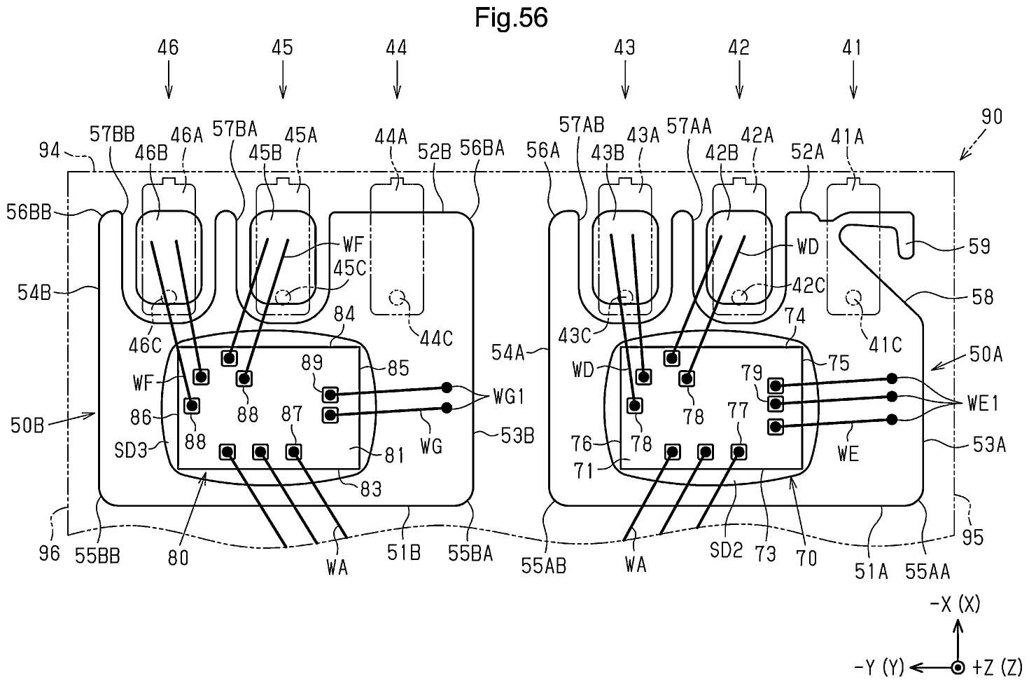

In each embodiment, the structure of the second bonding portion of each of the first die pad wire WC, the second die pad wire WE, and the third die pad wire WG may be changed in any manner. In an example, as shown in FIG. 55, security bonding WC1 may be formed on the second bonding portion of each first die pad wire WC. As shown in FIG. 56, security bonding WE1 may be formed on the second bonding portion of each second die pad wire WE. Security bonding WG1 may be formed on the second bonding portion of each third die pad wire WG. The security bonding WC1, WE1, and WG1 has the same structure as, for example, the security bonding WB1 (refer to FIG. 22) of the first terminal wire WB.

In each embodiment, the number of first die pad wires WC may be changed in any manner. The number of second die pad wires WE may be changed in any manner. The number of third die pad wires WG may be changed in any manner.

In the first, second, and fourth to ninth embodiments, the configuration of the second bonding portions of the first terminal wire WB, the second terminal wire WD, and the third terminal wire WF may be changed in any manner. In an example, security bonding may be formed on the second bonding portion of at least one of the first terminal wire WB, the second terminal wire WD, and the third terminal wire WF. The security bonding has the same structure as, for example, the security bonding WB1 (refer to FIG. 22) of the first terminal wire WB.

In the third embodiment, the first specified wire, which is one of the first terminal wires WB on which the security bonding WB1 is formed, and the second specified wire, which is one of the first terminal wires WB on which the security bonding WB1 is not formed, may be changed in any manner. In an example, the security bonding WB1 may be formed on the second bonding portions of the first terminal wires WB that are bonded to the first inner terminal portions 12B, 13B, 15B, and 17B, while the security bonding WB1 is not formed on the second bonding portions of the first terminal wires WB that are bonded to the first inner terminal portions 14B and 16B. More specifically, the first terminal wires WB bonded to the first inner terminal portions 12B, 13B, 15B, and 17B may serve as the first specified wire, while the first terminal wires WB bonded to the first inner terminal portions 14B and 16B may serve as the second specified wire. As described above, in the third embodiment, the first terminal wires WB may include the first specified wire, which includes the security bonding WB1, and the second specified wire, which does not include the security bonding WB1.

In the third embodiment, the second terminal wires WD may include a third specified wire in which security bonding is formed on the second bonding portion and a fourth specified wire in which security bonding is not formed on the second bonding portion. In an example, security bonding is formed on the second bonding portion of the second terminal wire WD that is bonded to the second inner terminal portion 42B, and security bonding is not formed on the second bonding portion of the second terminal wire WD that is bonded to the second inner terminal portion 43B.

In the third embodiment, the third terminal wires WF may include a fifth specified wire in which security bonding is formed on the second bonding portion and a sixth specified wire in which security bonding is not formed on the second bonding portion. In an example, security bonding is formed on the second bonding portion of the third terminal wire WF that is bonded to the third inner terminal portion 45B, and security bonding is not formed on the second bonding portion of the third terminal wire WF that is bonded to the third inner terminal portion 46B.

In the first, second, and fourth to ninth embodiments, security bonding may be formed on the second bonding portion of each of the first terminal wire WB, the second terminal wire WD, the third terminal wire WF, the first die pad wire WC, the second die pad wire WE, and the third die pad wire WG.

### Modified Examples of Encapsulation Resin

In each embodiment, the surface roughness Rz of each of the encapsulation front surface 91, the encapsulation back surface 92, and the first to fourth encapsulation side surfaces 93 to 96 of the encapsulation resin 90 may be less than 8 μm.

In each embodiment, the concentration of sulfur added to the encapsulation resin 90 may be changed in any manner. In an example, the concentration of sulfur added to the encapsulation resin 90 may be greater than 300 μg/g.

### Application Examples of Signal Transmission Device

The signal transmission device 10 of each embodiment may applicable to an isolated gate driver that performs, for example, switching of a power semiconductor element such as an insulated gate bipolar transistor (IGBT) that controls the driving of a motor. Such an isolated gate driver may be applicable to, for example, an inverter device for an electric vehicle or a hybrid vehicle. In this case, a power supply voltage supplied to the first chip 60 of the signal transmission device 10 is 5 V or 3.3 V referenced to the ground potential. In comparison to the ground potential of the first chip 60, for example, a voltage of 600 V or greater is transitionally applied to the second chip 70. More specifically, for example, in an inverter device for a hybrid vehicle, a motor driver circuit typically uses a half-bridge circuit where a low-side switching element and a high-side switching element are connected in a totem-pole configuration.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the embodiments and also that A may be disposed above B without contacting B in modified examples. In other words, the term “on” does not exclude a structure in which another member is formed between A and B.

In this specification, “at least one of A and B” should be understood to mean “only A, only B, or both A and B.”

The Z-direction as referred to in the present disclosure does not necessarily have to be the vertical direction and does not necessarily have to exactly coincide with the vertical direction. Accordingly, in the structures of the present disclosure, “up” and “down” in the z-direction as referred to in this specification is not limited to “up” and “down” in the vertical direction. For example, the X-direction may conform to the vertical direction. The Y-direction may conform to the vertical direction.

### CLAUSES

The technical aspects that are understood from the present disclosure will hereafter be described. To facilitate understanding without intention to limit, the reference signs of the elements in the embodiments are given to the corresponding elements in the clause with parentheses. The reference signs are used as examples to facilitate understanding, and the components in each reference sign are not limited to those components given with the reference signs.

[Clause A1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction);
inter-chip wires (WA) separately connecting the first chip (60) to each of the second chip (70) and the third chip (80);
first terminal wires (WB) separately electrically connecting the first chip (60) to the first terminals (12 to 17); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the inter-chip wires (WA), the first terminal wires (WB), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the inter-chip wires (WA) are formed from a material containing gold, and
the first terminal wires (WB) are formed from a material including copper or aluminum.

[Clause A2] The signal transmission device according to clause A1, where the first terminal wires (WB) are copper wires each having a surface coated with palladium.

[Clause A3] The signal transmission device according to clause A1 or A2, further including:
second terminal wires (WD) separately connecting the second chip (70) to the second terminals (41 to 43),
where the second terminal wires (WD) are formed from a material including copper or aluminum.

[Clause A4] The signal transmission device according to any one of clauses A1 to A3, further including:
a first die pad wire (WC) connecting the first chip (60) to the first die pad (30),
where the first die pad wire (WC) is formed from a material including copper or aluminum.

[Clause A5] The signal transmission device according to any one of clauses A1 to A4, further including:
a second die pad wire (WE) connecting the second chip (70) to the second die pad (50A),
where the second die pad wire (WE) is formed from a material including copper or aluminum.

[Clause A6] The signal transmission device according to clause A4, where
the first die pad wire (WC) includes a bonding wire, and
security bonding (WC1) is formed on a portion of the first die pad wire (WC), the portion being bonded to the first die pad (30).

[Clause A7] The signal transmission device according to clause A5, where
the second die pad wire (WE) includes a bonding wire, and
security bonding (WE1) is formed on a portion of the second die pad wire (WE), the portion being bonded to the second die pad (50A).

[Clause A8] The signal transmission device according to any one of clauses A1 to A7, where
the first terminals (12 to 17) each include a first inner terminal portion (12B to 17B) separated from the first die pad (30) and connected to one of the first terminal wires (WB),
in plan view, the first inner terminal portion (12B to 17B) includes a side surface that intersects the one of the first terminal wires (WB), which is connected to the first inner terminal portion (12B to 17B), and
the side surface is opposed to the first die pad (30) in plan view.

[Clause A9] The signal transmission device according to any one of clauses A1 to A8, where a shortest distance from the second terminals (41 to 43) to the third terminals (44 to 46) is greater than a distance between two of the second terminals (41 to 43) that are adjacent to each other in the second direction (Y-direction).

[Clause A10] The signal transmission device according to any one of clauses A1 to A7, where
the first terminals (12 to 17) include first inner terminal portions (12B to 17B) that are connected to the first terminal wires (WB),
the first inner terminal portions (12B to 17B) are separated from the first die pad (30), and
the first terminal wires (WB) include
   a first specified wire including a portion that is bonded to one of the first inner terminal portions (12B, 17B) without security bonding, and
   a second specified wire including a portion that is bonded to one of the first inner terminal portions (13B to 16B) with security bonding.

[Clause A11] The signal transmission device according to any one of clauses A1 to A10, where
the first chip (60) includes
   an element insulation layer (150),
   a first resin layer (191) formed on the element insulation layer, and
   a second resin layer (192) formed on the first resin layer, and the isolation transformer (111, 112) includes
   a front coil (111A to 114A) arranged on the first resin layer (191) and covered by the second resin layer (192), and
   a back coil (111B to 114B) opposed to the front coil (111A to 114A) in a thickness-wise direction (Z-direction) of the element insulation layer (150), the back coil (111B to 114B) being embedded in the element insulation layer (150).

[Clause A12] The signal transmission device according to any one of clauses A1 to A10, where
the first chip (60) includes
   an element insulation layer (150),
   a passivation film (161) formed on the element insulation layer (150) to cover the element insulation layer (150), and
   a low dielectric layer (193) formed on a surface of the passivation film (161) and having a lower relative permittivity than the passivation film (161), and the encapsulation resin (90) covers the low dielectric layer (193).

[Clause A13] The signal transmission device according to any one of clauses A1 to A12, where
the isolation transformer (111, 112) includes
   a front coil (111A to 114A) located toward a chip front surface (61) of the first chip (60), and
   a back coil (111B to 114B) opposed to the front coil (111A to 114A), and the front coil (111A to 114A) includes
   a coil front surface (171),
   a coil back surface (172) opposite to the coil front surface (171),
   a coil side surface (173) joining the coil front surface (171) and the coil back surface (172), and
   a curved surface formed between the coil front surface (171) and the coil side surface (173).

[Clause A14] The signal transmission device according to any one of clauses A1 to A13, where
the first chip (60) includes
   a flat substrate (130) mounted on the first die pad (30), and
   an element insulation layer (150) formed on the substrate (130), the isolation transformer (111, 112) being at least partially arranged on the element insulation layer (150), and
the substrate (130) includes
   a substrate back surface (132) facing the first die pad (30),
   a substrate front surface (131) opposite to the substrate back surface (132),
   a substrate side surface (133 to 136) connecting the substrate back surface (132) and the substrate front surface (131),
   a first part (137) including the substrate back surface (132),
   a second part (138) arranged on the first part (137) and including the substrate front surface (131), and
   a step (139) arranged so that the second part (138) is located at an inner side of the substrate (130) from the first part (137).

[Clause A15] The signal transmission device according to any one of clauses A1 to A14, where the first die pad (30) includes
a first distal surface (31) opposed to the second die pad (50A) in the first direction (X-direction) in plan view,
a first basal surface (32) opposite to the first distal surface (31) in plan view,
a first side surface (33) and a second side surface (34) defining two side surfaces in the second direction (Y-direction),
a first distal curved surface (35A) formed between the first distal surface (31) and the first side surface (33),
a second distal curved surface (35B) formed between the first distal surface (31) and the second side surface (34),
a basal curved surface (36) formed between the first basal surface (32) and the first side surface (33), and
in plan view, each of the first distal curved surface (35A) and the second distal curved surface (35B) is greater in arc length than the basal curved surface (36).

[Clause A16] The signal transmission device according to any one of clauses A1 to A15, where
the first terminals (12 to 17) each include a first inner terminal portion (12B to 17B) separated from the first die pad (30) and connected to one of the first terminal wires (WB),
the first inner terminal portions (12B to 17B) each include
   an inner terminal front surface (21) to which one of the first terminal wires (WB) is bonded,
   an inner terminal back surface (22) facing an opposite direction of the inner terminal front surface (21), and
   an inner terminal side surface (23) connecting the inner terminal front surface (21) and the inner terminal back surface (22),
the inner terminal side surface (23) includes a distal surface (24) opposed to the first die pad (30),
a plating layer (25) is formed on the inner terminal front surface (21), and
an end of the inner terminal front surface (21), the end being located at the distal surface (24) is free of the plating layer (25) and is in contact with the encapsulation resin (90).

[Clause A17] The signal transmission device according to any one of clauses A1 to A16, where the encapsulation resin (90) includes an outer surface (91 to 96) having a surface roughness Rz of 8 μm or greater.

[Clause A18] The signal transmission device according to clause A3, where the second terminal wires (WD) are copper wires each having a surface coated with palladium.

[Clause A19] The signal transmission device according to clause A1 or A2, further including:
third terminal wires (WF) separately connecting the third chip (80) to the third terminals (44 to 46),
where the third terminal wires (WF) are formed from a material including copper and aluminum.

[Clause A20] The signal transmission device according to clause A19, where the third terminal wires (WF) are copper wires each having a surface coated with palladium.

[Clause A21] The signal transmission device according to any one of clauses A1 to A17, further including:
a third die pad wire (WG) connecting the third chip (80) to the third die pad (50B),
where the third die pad wire (WG) is formed from a material including copper or aluminum.

[Clause A22] The signal transmission device according to clause A21, where
the third die pad wire (WG) includes a bonding wire, and
security bonding (WG1) is formed on a portion of the third die pad wire (WG) bonded to the third die pad.

[Clause A23] The signal transmission device according to clause A1 or A2, further including:
second terminal wires (WD) separately connecting the second chip (70) to the second terminals (42, 43), where
the second terminals (42, 43) include a second inner terminal portion (42B, 43B) separated from the second die pad (50A),
in plan view, the second inner terminal portion (42B, 43B) includes a side surface that intersects one of the second terminal wires (WD) that is connected to the second inner terminal portion (42B, 43B), and
the side surface is opposed to the second die pad (50A) in plan view.

[Clause A24] The signal transmission device according to clause A1 or A2, further including:
third terminal wires (WF) separately connecting the third chip (80) to the third terminals (45, 46), where
the third terminals (45, 46) include a third inner terminal portion (45B, 46B) separated from the third die pad (50B),
in plan view, the third inner terminal portion (45B, 46B) includes a side surface that intersects one of the third terminal wires (WF) that is connected to the third inner terminal portion (45B, 46B), and
the side surface is opposed to the third die pad (50B) in plan view.

[Clause A25] The signal transmission device according to any one of clauses A1 to A24, where
the second die pad (50A) includes
   a second distal surface (51A) opposed to the first die pad (30) in the first direction (X-direction) in plan view,
   a second basal surface (52A) opposite to the second distal surface (51A) in plan view,
   a third side surface (53A) and a fourth side surface (54A) defining two side surfaces in the second direction (Y-direction),
   a first distal curved surface (55AA) formed between the second distal surface (51A) and the third side surface (53A), and
   a basal curved surface (56A) formed between the second basal surface (52A) and the fourth side surface (54A), and
in plan view, the first distal curved surface (55AA) is greater in arc length than the basal curved surface (56A).

[Clause A26] The signal transmission device according to any one of clauses A1 to A25, where
the third die pad (50B) includes
   a third distal surface (51B) opposed to the first die pad (30) in the first direction (X-direction) in plan view,
   a third basal surface (52B) opposite to the third distal surface (51B) in plan view,
   a fifth side surface (53B) and a sixth side surface (54B) defining two side surfaces in the second direction (Y-direction),
   a second distal curved surface (55BB) formed between the third distal surface (51B) and the sixth side surface (54B), and
   a basal curved surface (56BB) formed between the third basal surface (52B) and the sixth side surface (54B), and
in plan view, the second distal curved surface (55BB) is greater in arc length than the basal curved surface (56BB).

[Clause A27] The signal transmission device according to any one of clauses A1 to A26, further including:
second terminal wires (WD) separately connecting the second terminals (42, 43) to the second chip (70), where
the second terminals (42, 43) include a second inner terminal portion (42B, 43B) arranged in the encapsulation resin (90),
the second inner terminal portion (42B, 43B) includes
   an inner terminal front surface (21) bonded to the second terminal wires (WD),
   an inner terminal back surface (22) facing an opposite direction of the inner terminal front surface (21), and
   an inner terminal side surface (23) connecting the inner terminal front surface (21) and the inner terminal back surface (22),
the inner terminal side surface (23) includes a distal surface (24) opposed to the second die pad (50A) in the first direction (X-direction),
a plating layer (25) is formed on the inner terminal front surface (21), and
an end of the inner terminal front surface (21) located at the distal surface (24) is free of the plating layer (25) and is in contact with the encapsulation resin (90).

[Clause A28] The signal transmission device according to any one of clauses A1 to A27, further including:
third terminal wires (WF) separately connecting the third terminals (45, 46) to the third chip (80), where
the third terminals (45, 46) each include a third inner terminal portion (45B, 46B) arranged in the encapsulation resin (90),
the third inner terminal portion (45B, 46B) includes
   an inner terminal front surface (21) to which one of the third terminal wires (WF) is bonded,
   an inner terminal back surface (22) facing an opposite direction of the inner terminal front surface (21), and
   an inner terminal side surface (23) connecting the inner terminal front surface (21) and the inner terminal back surface (22),
the inner terminal side surface (23) includes a distal surface (24) opposed to the third die pad (50B) in the first direction (X-direction),
a plating layer (25) is formed on the inner terminal front surface (21), and
an end of the inner terminal front surface (21) located at the distal surface (24) is free of the plating layer (25) and is in contact with the encapsulation resin (90).

[Clause A29] The signal transmission device according to any one of clauses A1 to A28, where
the second chip (70) includes a flat substrate (230) mounted on the second die pad (50A),
the substrate (230) includes
   a substrate back surface (232) facing the second die pad (50A),
   a substrate front surface (231) opposite to the substrate back surface (232),
   a substrate side surface (233 to 236) connecting the substrate back surface (232) and the substrate front surface (231),
   a first part (237) including the substrate back surface (232),
   a second part (238) arranged on the first part (237) and including the substrate front surface (231), and
   a step (239) arranged so that the second part (238) is located at an inner side of the substrate (230) from the first part (237).

[Clause A30] The signal transmission device according to any one of clauses A1 to A29, where
the third chip (80) includes a flat substrate (330) mounted on the third die pad (50B),
the substrate (330) includes
   a substrate back surface (332) facing the third die pad (50B),
   a substrate front surface (331) opposite to the substrate back surface (332),
   a substrate side surface (333 to 336) connecting the substrate back surface (332) and the substrate front surface (331),
   a first part (337) including the substrate back surface (332),
   a second part (338) arranged on the first part (337) and including the substrate front surface (331), and
   a step (339) arranged so that the second part (338) is located at an inner side of the substrate (330) from the first part (337).

[Clause B1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction);
first terminal wires (WB) separately electrically connecting the first chip (60) to the first terminals (11 to 17); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first terminals (11 to 17) include first inner terminal portions (12B to 17B) separated from the first die pad (30) and connected to the first terminal wires (WB),
in plan view, one of the first inner terminal portions (16B) includes a side surface intersecting one of the first terminal wires (WB) that is connected to the one of the first inner terminal portion (16B), and
the side surface is opposed to the first die pad (30) in plan view.

### Technical Problem to be Solved by Clause B1

When the first terminal wire extends along the side surface of the first terminal in plan view, the position of the first terminal wire relative to the first terminal is not readily recognized. Thus, the position of a portion of the first terminal wire bonded to the first terminal is not readily recognized.

### Advantage of Clause B1

The signal transmission device according to clause B1 allows for easy recognition of the position of the portion of the first terminal wire bonded to the first terminal.

[Clause C1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction);
first terminal wires (WB) separately electrically connecting the first chip (60) to the first terminals (11 to 17); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first terminals (11 to 17) include first inner terminal portions (12B to 17B) that are connected to the first terminal wires (WB),
the first inner terminal portions (12B to 17B) are separated from the first die pad (30), and
the first terminal wires (WB) include
   a first specified wire including a portion that is bonded to one of the first inner terminal portions (12B, 17B) without security bonding, and
   a second specified wire including a portion that is bonded to one of the first inner terminal portions (13B to 16B) with security bonding.

### Technical Problem to be Solved by Clause C1

In the manufacturing process of the signal transmission device, if force is applied to the first terminal wire, the first terminal wire may be separated from the first terminal.

### Advantage of Clause C1

The signal transmission device according to clause C1 limits separation of the first terminal wire from the first terminal.

[Clause D1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first chip (60) includes
   an element insulation layer (150),
   a first resin layer (191) formed on the element insulation layer (150), and
   a second resin layer (192) formed on the first resin layer (191), and the isolation transformer (321) includes
   a first coil (111A to 114A) arranged on the first resin layer (191) and covered by the second resin layer (192), and
   a second coil (111B to 114B) opposed to the first coil (111A to 114A) in a thickness-wise direction (Z-direction) of the element insulation layer (150), the second coil (111B to 114B) being embedded in the element insulation layer (150).

### Technical Problem to Be Solved by Clause D1

To improve the breakdown voltage of the signal transmission device, it is desirable that the distance between the first coil and the second coil of the isolation transformer is large.

### Advantage of Clause D1

With the signal transmission device according to clause D1, the distance between the first coil and the second coil of the isolation transformer is readily increased.

[Clause E1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first chip (60) includes
   an element insulation layer (150),
   a passivation film (161) formed on the element insulation layer (150) to cover the element insulation layer (150),
   a low dielectric layer (193) formed on a surface of the passivation film (161) and having a lower relative permittivity than the passivation film (161), and
   the encapsulation resin (90) covers the low dielectric layer (193).

### Technical Problem to Be Solved by Clause E1

In a structure in which the encapsulation resin is in contact with the passivation film, voids may be contained in the interface between the encapsulation resin and the passivation film. The voids may cause partial discharge and consequential surface discharge.

### Advantage of Clause E1

The signal transmission device according to clause E1 limits occurrence of partial discharge and consequential surface discharge. Thus, the reliability of the first chip is increased.

[Clause F1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the isolation transformer (321) includes
   a first coil (111A to 114A), and
   a second coil (111B to 114B) opposed to the first coil (111A to 114A), the first coil (111A to 114A) includes
   a coil front surface (171),
   a coil back surface (172) opposite to the coil front surface (171),
   a coil side surface (173) joining the coil front surface (171) and the coil back surface (172), and
   a curved surface (176) formed between the coil front surface (171) and the coil side surface (173).

### Technical Problem to Be Solved by Clause F1

In the first coil, an electric field tends to concentrate on a corner formed by the coil front surface and the coil side surface. Such electric field concentration may decrease the breakdown voltage of the first chip.

### Advantage of Clause F1

The signal transmission device according to clause F1 limits concentration of an electric field on the first coil, thereby limiting decreases in the breakdown voltage of the first chip.

[Clause G1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the substrate (130) includes
   a substrate back surface (132) facing the first die pad (30),
   a substrate front surface (131) opposite to the substrate back surface (132),
   a substrate side surface (133 to 136) connecting the substrate back surface (132) and the substrate front surface (131),
   a first part (137) including the substrate back surface (132),
   a second part (138) arranged on the first part (137) and including the substrate front surface (131), and
   a step (139) arranged so that the second part (138) is located at an inner side of the substrate (130) from the first part (137).

### Technical Problem to Be Solved by Clause G1

When the first chip is mounted on the first die pad using a first conductive bonding material, the first conductive bonding material may flow up to the front surface of the first chip.

### Advantage of Clause G1

The signal transmission device according to clause G1 limits an upward flow of the first conductive bonding material to the chip front surface of the first chip.

[Clause H1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first die pad (30) includes
   a first distal surface (31) opposed to the second die pad (50A) in the first direction (X-direction) in plan view,
   a first basal surface (32) opposite to the first distal surface (31) in plan view,
   a first side surface (33) and a second side surface (34) defining two side surfaces in the second direction (Y-direction),
   a first distal curved surface (35A) formed between the first distal surface (31) and the first side surface (33),
   a second distal curved surface (35B) formed between the first distal surface (31) and the second side surface (34), and
   a basal curved surface (36) formed between the first basal surface (32) and the first side surface (33), and
in plan view, each of the first distal curved surface (35A) and the second distal curved surface (35B) is greater in arc length than the basal curved surface (36).

### Technical Problem to Be Solved by Clause H1

When the first die pad and the second die pad each have a corner, an electric field tends to concentrate on the corners. If such corners are opposed to each other in the first direction, the electric field concentrated on the corners may cause insulation breakdown between the first die pad and the second die pad.

### Advantage of Clause H1

The signal transmission device according to clause H1 limits occurrence of insulation breakdown between the first die pad and the second die pad.

[Clause I1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92),
the first terminals (11 to 17) include first inner terminal portions (12B to 17B) separated from the first die pad (30) and connected to the first terminal wires (WB),
the first inner terminal portions (12B to 17B) each include
   an inner terminal front surface (21) to which one of the first terminal wires (WB) is bonded,
   an inner terminal back surface (22) facing an opposite direction of the inner terminal front surface (21), and
   an inner terminal side surface (23) connecting the inner terminal front surface (21) and the inner terminal back surface (22),
the inner terminal side surface (23) includes a distal surface (24) opposed to the first die pad (30),
a plating layer (25) is formed on the inner terminal front surface (21), and
an end of the inner terminal front surface (21) located at the distal surface (24) is free of the plating layer (25) and is in contact with the encapsulation resin (90).

### Technical Problem to Be Solved by Clause I1

A plating layer is formed on the inner terminal front surface of the first inner terminal portion to appropriately bond the first inner terminal portion to the first terminal wire. If the plating layer is separated from the inner terminal front surface, the first inner terminal portion may not be appropriately bonded to the first terminal wire.

### Advantage of Clause I1

With the signal transmission device according to clause I1, the first inner terminal portion is appropriately bonded to the first terminal wire.

[Clause J1] A signal transmission device (10), including:
a first chip (60) including an isolation transformer (111, 112);
a second chip (70) configured to perform at least one of reception of a signal from the first chip (60) and transmission of a signal to the first chip (60);
a third chip (80) configured to perform at least one of reception of a signal from the first chip (60) and transmission of a signal to the first chip (60);
a first die pad (30) on which the first chip (60) is mounted;
a second die pad (50A) separated from the first die pad (30) in a first direction (X-direction), the second chip (70) being mounted on the second die pad (50A);
a third die pad (50B) separated from the first die pad (30) in the first direction (X-direction) and separated from the second die pad (50A) in a second direction (Y-direction) that is orthogonal to the first direction (X-direction) in plan view, the third chip (80) being mounted on the third die pad (50B);
first terminals (11 to 17) arranged at a side of the first chip (60) opposite from the second chip (70) and the third chip (80) in the first direction (X-direction) in plan view, the first terminals (11 to 17) being arranged in the second direction (Y-direction);
second terminals (41 to 43) arranged at a side of the second chip (70) opposite from the first chip (60) in the first direction (X-direction), the second terminals (41 to 43) being arranged in the second direction (Y-direction);
third terminals (44 to 46) arranged at a side of the third chip (80) opposite from the first chip (60) in the first direction (X-direction), the third terminals (44 to 46) being arranged in the second direction (Y-direction); and
an encapsulation resin (90) including an encapsulation front surface (91) and an encapsulation back surface (92) that face opposite directions in a third direction (Z-direction) that is orthogonal to the first direction (X-direction) and the second direction (Y-direction), and encapsulating the first chip (60), the second chip (70), the third chip (80), the first die pad (30), the second die pad (50A), the third die pad (50B), the first terminals (11 to 17), the second terminals (41 to 43), and the third terminals (44 to 46), where
the first terminals (11 to 17), the second terminals (41 to 43), and the third terminals (44 to 46) are exposed from the encapsulation back surface (92), and
the encapsulation resin (90) includes an outer surface (91 to 96) having a surface roughness Rz of 8 μm or greater.

### Technical Problem to Be Solved by Clause J1

It is desirable that the insulation distance from the first terminals to the second terminals and the insulation distance from the first terminals to the third terminals be increased to improve the breakdown voltage of the signal transmission device.

### Advantage of Clause J1

The signal transmission device according to clause J1 improves the breakdown voltage of the signal transmission device.

The description above illustrates examples. One skilled in the art may recognize further possible combinations and replacements of the components and methods (manufacturing processes) in addition to those listed for purposes of describing the techniques of the present disclosure. The present disclosure is intended to include any substitute, modification, changes included in the scope of the disclosure including the claims.

What is claimed is:

1. A signal transmission device, comprising:
a first chip including an isolation transformer;
a second chip configured to perform at least one of reception of a signal from the first chip and transmission of a signal to the first chip;
a third chip configured to perform at least one of reception of a signal from the first chip and transmission of a signal to the first chip;
a first die pad on which the first chip is mounted;
a second die pad separated from the first die pad in a first direction, the second chip being mounted on the second die pad;
a third die pad separated from the first die pad in the first direction and separated from the second die pad in a second direction that is orthogonal to the first direction in plan view, the third chip being mounted on the third die pad;
first terminals arranged at a side of the first chip opposite from the second chip and the third chip in the first direction in plan view, the first terminals being arranged in the second direction;
second terminals arranged at a side of the second chip opposite from the first chip in the first direction, the second terminals being arranged in the second direction;
third terminals arranged at a side of the third chip opposite from the first chip in the first direction, the third terminals being arranged in the second direction;
inter-chip wires separately connecting the first chip to each of the second chip and the third chip;
first terminal wires separately electrically connecting the first chip to the first terminals; and
an encapsulation resin including an encapsulation front surface and an encapsulation back surface that face opposite directions in a third direction that is orthogonal to the first direction and the second direction, and encapsulating the first chip, the second chip, the third chip, the first die pad, the second die pad, the third die pad, the inter-chip wires, the first terminal wires, the first terminals, the second terminals, and the third terminals, wherein
the first terminals, the second terminals, and the third terminals are exposed from the encapsulation back surface,
the inter-chip wires are formed from a material containing gold, and
the first terminal wires are formed from a material including copper or aluminum.

2. The signal transmission device according to claim 1, wherein the first terminal wires are copper wires each having a surface coated with palladium.

3. The signal transmission device according to claim 1, further comprising:
second terminal wires separately connecting the second chip to the second terminals,
wherein the second terminal wires are formed from a material including copper or aluminum.

4. The signal transmission device according to claim 1, further comprising:
a first die pad wire connecting the first chip to the first die pad,
wherein the first die pad wire is formed from a material including copper or aluminum.

5. The signal transmission device according to claim 1, further comprising:
a second die pad wire connecting the second chip to the second die pad,
wherein the second die pad wire is formed from a material including copper or aluminum.

6. The signal transmission device according to claim 4, wherein
the first die pad wire includes a bonding wire, and
security bonding is formed on a portion of the first die pad wire, the portion being bonded to the first die pad.

7. The signal transmission device according to claim 5, wherein
the second die pad wire includes a bonding wire, and
security bonding is formed on a portion of the second die pad wire, the portion being bonded to the second die pad.

8. The signal transmission device according to claim 1, wherein
the first terminals each include a first inner terminal portion separated from the first die pad and connected to one of the first terminal wires,
in plan view, the first inner terminal portion includes a side surface that intersects the one of the first terminal wires, which is connected to the first inner terminal portion, and
the side surface is opposed to the first die pad in plan view.

9. The signal transmission device according to claim 1, wherein a shortest distance from the second terminals to the third terminals is greater than a distance between two of the second terminals that are adjacent to each other in the second direction.

10. The signal transmission device according to claim 1, wherein
the first terminals include first inner terminal portions that are connected to the first terminal wires,
the first inner terminal portions are separated from the first die pad, and
the first terminal wires include
a first specified wire including a portion that is bonded to one of the first inner terminal portions without security bonding, and
a second specified wire including a portion that is bonded to one of the first inner terminal portions with security bonding.

11. The signal transmission device according to claim 1, wherein
the first chip includes
an element insulation layer,
a first resin layer formed on the element insulation layer, and
a second resin layer formed on the first resin layer, and
the isolation transformer includes
a front coil arranged on the first resin layer and covered by the second resin layer, and
a back coil opposed to the front coil in a thickness-wise direction of the element insulation layer, the back coil being embedded in the element insulation layer.

12. The signal transmission device according to claim 1, wherein
the first chip includes
an element insulation layer,
a passivation film formed on the element insulation layer to cover the element insulation layer, and
a low dielectric layer formed on a surface of the passivation film and having a lower relative permittivity than the passivation film, and
the encapsulation resin covers the low dielectric layer.

13. The signal transmission device according to claim 1, wherein
the isolation transformer includes
a front coil located toward a chip front surface of the first chip, and
a back coil opposed to the front coil, and
the front coil includes
a coil front surface,
a coil back surface opposite to the coil front surface,
a coil side surface joining the coil front surface and the coil back surface, and
a curved surface formed between the coil front surface and the coil side surface.

14. The signal transmission device according to claim 1, wherein
the first chip includes
a flat substrate mounted on the first die pad, and
an element insulation layer formed on the substrate, the isolation transformer being at least partially arranged on the element insulation layer, and the substrate includes
a substrate back surface facing the first die pad,
a substrate front surface opposite to the substrate back surface,
a substrate side surface connecting the substrate back surface and the substrate front surface,
a first part including the substrate back surface,
a second part arranged on the first part and including the substrate front surface, and
a step arranged so that the second part is located at an inner side of the substrate from the first part.

15. The signal transmission device according to claim 1, wherein the first die pad includes
a first distal surface opposed to the second die pad in the first direction in plan view,
a first basal surface opposite to the first distal surface in plan view,
a first side surface and a second side surface defining two side surfaces in the second direction,
a first distal curved surface formed between the first distal surface and the first side surface,
a second distal curved surface formed between the first distal surface and the second side surface,
a basal curved surface formed between the first basal surface and the first side surface, and
in plan view, each of the first distal curved surface and the second distal curved surface is greater in arc length than the basal curved surface.

16. The signal transmission device according to claim 1, wherein
the first terminals each include a first inner terminal portion separated from the first die pad and connected to one of the first terminal wires,
the first inner terminal portions each include
an inner terminal front surface to which one of the first terminal wires is bonded,
an inner terminal back surface facing an opposite direction of the inner terminal front surface, and
an inner terminal side surface connecting the inner terminal front surface and the inner terminal back surface,
the inner terminal side surface includes a distal surface opposed to the first die pad,
a plating layer is formed on the inner terminal front surface, and
an end of the inner terminal front surface, the end being located at the distal surface is free of the plating layer and is in contact with the encapsulation resin.

17. The signal transmission device according to claim 1, wherein the encapsulation resin includes an outer surface having a surface roughness Rz of 8 μm or greater.
